(19) United States
(12) Patent Application Publication
(10) Pub. No.: US 2025/0306470 A1
(43) Pub. Date: Oct. 2, 2025

(54) PATTERN EXPOSURE DEVICE AND DEVICE MANUFACTURING METHOD

(71) Applicant: NIKON CORPORATION, Tokyo (JP)

(72) Inventor: Masaki KATO, Yokohama-shi (JP)

(73) Assignee: NIKON CORPORATION, Tokyo (JP)

(21) Appl. No.: 19/035,489

(22) Filed: Jan. 23, 2025

Related U.S. Application Data
(63) Continuation of application No. PCT/JP2022/028619, filed on Jul. 25, 2022.

(51) Int. Cl. G03F 7/00

(52) U.S. Cl. CPC G03F 7/70091; G03F 7/70141; G03F 7/70208; G03F 7/70291; G03F 7/70025

(57) ABSTRACT

An exposure device includes: a spatial light modulation element including micromirrors; an illumination unit that irradiates the spatial light modulation element with first light with a peak wavelength λ1 and second light with a peak wavelength λ2 (λ2≈λ1), so that the first light is diffracted by ON-state micromirrors of the spatial light modulation element as first diffraction light and the second light is diffracted by the ON-state micromirror as second diffraction light; and a projection unit, wherein the first diffraction light and the second diffraction light enter the projection unit, so that the first diffraction light and the second diffraction light are distributed with an optical axis of the projection unit interposed therebetween.

### CROSS-REFERENCE TO RELATED APPLICATION

The present application is a continuation application of International Application PCT/JP2022/028619, filed on Jul. 25, 2022. The contents of the above applications are incorporated herein.

### BACKGROUND

### Technical Field

The present invention relates to a pattern exposure device configured to expose a pattern for an electronic device, and a device manufacturing method of an electronic device using such a pattern exposure device.

### Background Art

In the related art, in a lithography process of manufacturing an electronic device (microdevice) such as liquid crystal or organic EL display panels, a semiconductor element (integrated circuit or the like), or the like, a step-and-repeat projection exposure device (so-called stepper), a step-and-scan projection exposure device (so-called scanning stepper (also referred to as a scanner)), or the like, is used. Such an exposure device involves projection exposure of a mask pattern for an electronic device onto a photosensitive layer applied to a surface of an exposed substrate (hereinafter simply referred to as a substrate), such as a glass substrate, a semiconductor wafer, a printed wiring board, a resin film, or the like.

Since creation of a mask substrate that fixedly forms a mask pattern requires time and expenditure, an exposure device that uses a spatial light modulation element (variable mask pattern generator) such as a digital mirror device (DMD) that has a large number of micromirrors that are displaced slightly in a regular layout instead of a mask substrate is known (for example, see PCT International Publication No. 2018/088550). In the exposure device disclosed in PCT International Publication No. 2018/088550, light from a light source 3 using a semiconductor laser with a wavelength of 405 nm or 365 nm is obliquely radiated to a digital mirror device (DMD) as a spatial light modulator 4 via an irradiation optical system 6 at an incidence angle of 22 to 26°, and reflection light from a pixel mirror in an ON-state in a number of pixel mirrors of the spatial light modulator 4 (DMD) is projected and exposed to an exposure area of an object W via a projection optical system 5.

In the case of PCT International Publication No. 2018/088550, a tilt angle of a pixel mirror (micromirror) of the DMD is set to an angle of ½ of the incidence angle of 22 to 26° of the illumination light. Since the number of pixel mirrors (micro mirrors) are arranged in a matrix with a constant pitch, it also functions as an optical diffraction grating (blazed diffraction grating). In particular, when a fine pattern for an electronic device is projected and exposed and the DMD is obliquely illuminated with illumination light, depending on the action of the diffraction grating of the DMD (a direction in which the diffraction light is generated or a state of an intensity distribution), it is possible for an imaging state of a pattern to become degraded or a light intensity (exposure amount) of the projected imaging light flux to be reduced.

### SUMMARY OF INVENTION

According to a first aspect of the present invention, provided is a pattern exposure device configured to irradiate a spatial light modulation element with illumination light, the spatial light modulation element having a number of micro mirrors that are two-dimensionally arranged at a predetermined pitch and that are selectively driven based on drawing data, configured to cause reflection light from a selected ON-state micromirror of the spatial light modulation element to incident on a projection unit, and configured to project and expose a pattern corresponding to the drawing data to a substrate, the pattern exposure device includes an illumination unit configured to irradiate the spatial light modulation element with first illumination light, having a wavelength λ1 and second illumination light, having a wavelength λ2 (λ2≈λ1), at an incidence angle corresponding to twice of a tilt angle of the ON-state micromirror, and provided that a diffraction angle of main diffraction light of an order j1, which is generated from the ON-state micromirror under the wavelength λ1 and which reaches the substrate via the projection unit, is θj1 and a diffraction angle of main diffraction light of an order j2, which is generated from the ON-state micromirror under the wavelength λ2 and which reaches the substrate via the projection unit, is θj2, a difference between the wavelength λ1 and the wavelength λ2 is set so that a difference angle between the diffraction angle θj1 and the diffraction angle θj2 is within a predetermined allowable range.

According to a second aspect of the present invention, provided is a pattern exposure device configured to irradiate a spatial light modulation element with illumination light, the spatial light modulation element having a number of micro mirrors that are two-dimensionally arranged at a predetermined pitch and that are selectively driven based on drawing data, configured to cause reflection light from a selected ON-state micromirror of the spatial light modulation element to incident on a projection unit, and configured to project and expose a pattern corresponding to the drawing data to a substrate, the pattern exposure device includes an illumination unit configured to irradiate the spatial light modulation element with first illumination light, having a wavelength λ1 allowed by chromatic aberration characteristics of the projection unit, and second illumination light, having a wavelength λ2 (λ2≈λ1) allowed by chromatic aberration characteristics of the projection unit, at an incidence angle corresponding to twice of a tilt angle of the ON-state micromirror, and provided that a diffraction angle of main diffraction light of an order j1, which is generated from the ON-state micromirror under the wavelength λ1 and which enters the projection unit, is θj1 and a diffraction angle of main diffraction light of an order j2, which is generated from the ON-state micromirror under the wavelength λ2 and which enters the projection unit, is θj2, a difference between the wavelength λ1 and the wavelength λ2 or the incidence angle is set so that the diffraction angle θj1 and the diffraction angle θj2 are distributed with an optical axis of the projection unit being interposed between the diffraction angle θj1 and the diffraction angle θj2.

According to a third aspect of the present invention, provided is a pattern exposure device configured to irradiate a spatial light modulation element with illumination light, the spatial light modulation element having a number of micro mirrors that are two-dimensionally arranged at a predetermined pitch and that are selectively driven based on drawing data, configured to cause reflection light from a selected ON-state micromirror of the spatial light modulation element to incident on a projection unit, and configured to project and expose a pattern corresponding to the drawing data to a substrate, the pattern exposure device includes an illumination unit configured to irradiate the spatial light modulation element with first illumination light, having a wavelength λ1 which is allowed by chromatic aberration characteristics of the projection unit, and second illumination light, having a wavelength λ2 (λ2≈λ1) which is allowed by the chromatic aberration characteristics of the projection unit, at a designed incidence angle θα which is set to be twice of a standard tilt angle of the ON-state micromirror, and provided that a diffraction angle of main diffraction light of an order j1, which is generated from the ON-state micromirror under the wavelength λ1 and which enters the projection unit, is θj1 and a diffraction angle of main diffraction light of an order j2, which is generated from the ON-state micromirror under the wavelength λ2 and which enters the projection unit, is θj2, the wavelength λ1 and the wavelength λ2 are set so that the diffraction angle θj1 and the diffraction angle θj2 generated under a condition of the designed incidence angle θα are distributed on one side with respect to the optical axis of the projection unit.

According to a fourth aspect of the present invention, provided is a device manufacturing method including a step of forming a photosensitive layer on a substrate on which an electronic device is fabricated, a step of preparing drawing data according to a pattern for the electronic device, a step of installing the substrate on which the photosensitive layer is formed on a moving stage of the pattern exposure device according to any one of the first to third aspects of the present invention and setting the drawing data to a driving controller of the spatial light modulation element of the pattern exposure device, and a step of exposing the pattern to the photosensitive layer of the substrate while synchronizing movement of the substrate by the moving stage and driving of the micro mirrors in an ON-state and an OFF-state of the spatial light modulation element based on the drawing data.

According to a fifth aspect of the present invention, provided is a pattern exposure device configured to irradiate a spatial light modulation element with illumination light, the spatial light modulation element having a number of micro mirrors that are two-dimensionally arranged at a predetermined pitch and that are selectively driven based on drawing data, configured to cause reflection light from a selected ON-state micromirror of the spatial light modulation element to incident on a projection unit, and configured to project and expose a pattern corresponding to the drawing data to a substrate, the pattern exposure device includes an illumination unit configured to irradiate the spatial light modulation element with illumination light, having a predetermined wavelength width±Δλ with respect to a center wavelength λo, at an incidence angle θα (θα>) 0° corresponding to twice of a tilt angle of the ON-state micromirror, and, provided that the wavelength λo+λ2 of the illumination light on a long wavelength side is wavelength λ1, the wavelength λo−λ2 of the illumination light on a short wavelength side is the wavelength λ2, a diffraction angle of main diffraction light of an order j1, which is generated from the ON-state micromirror under light of the wavelength λ1 and which enters the projection unit, is θj1, and a diffraction angle of main diffraction light of an order j2, which is generated from the ON-state micromirror under light of the wavelength λ2 and which enters the projection unit, is θj2, the wavelength width±λ2 is set so that an overall distribution shape of the main diffraction light of the order j1 and the main diffraction light of the order j2 that appear in a pupil of the projection unit is deformed into an isotropic shape due to a difference between the diffraction angles θj1 and θj2.

### BRIEF DESCRIPTION OF DRAWINGS

FIG. 1 is a perspective view schematically showing an appearance configuration of a pattern exposure device EX according to an embodiment.

FIG. 2 is a view showing a layout example of projection areas IAn of a DMD 10 projected onto a substrate P by each of projection units PLU of a plurality of exposure module groups MU.

FIG. 3 is a view for describing a state of seamless exposure of each of specified four projection areas IA8, IA9, IA10 and IA27 in FIG. 2.

FIG. 4 is an optical layout diagram showing a specific configuration of two exposure modules MU18 and MU19 arranged in an X direction (scanning exposure direction) when seen in an XZ plane.

FIG. 5 is a view schematically showing a state in which the DMD 10 and an illumination unit PLU are inclined by an angle θk in an XY plane.

FIG. 6 is a view for describing an imaging condition of a micro mirror of the DMD 10 according to the projection units PLU in detail.

FIG. 7 is a schematic diagram showing an MFE lens 108A as an optical integrator 108 from an emission surface side.

FIG. 8 is a view schematically showing an example of a layout relationship between a point light source SPF formed on an emission surface side of a lens element EL of the MFE lens 108A in FIG. 7 and an emission end of an optical fiber bundle FBn.

FIG. 9 is a view schematically representing an aspect of a light source image formed on a pupil Ep of the projection units PLU shown in FIG. 6.

FIG. 10 is an optical path diagram of simplifying and representing an optical path diagram of FIG. 6.

FIG. 11 is a view schematically representing an aspect of a light source image Ips formed on the pupil Ep by a 0^{th} order light equivalent component of an imaging light flux Sa from the DMD 10.

FIG. 12 is a schematic diagram of a light source surface having an oval shape when the MFE lens 108A of the optical integrator 108 is seen from an emission surface side, like FIG. 7.

FIG. 13 is a view schematically representing a behavior of the imaging light flux Sa in an optical path from the pupil Ep of the projection units PLU to the substrate P shown in FIG. 6.

FIG. 14 is an enlarged perspective view showing a state of some micro mirrors Ms of the DMD 10 when power supply to a driving circuit of the DMD 10 is turned off.

FIG. 15 is an enlarged perspective view showing a part of a mirror surface of the DMD 10 when the micro mirrors Ms of the DMD 10 are in an ON-state and an OFF-state.

FIG. 16 is a view showing a part of the mirror surface of the DMD 10 when seen in an X′Y′ plane, and showing a case in which only a row of the micro mirrors Ms arranged in a Y′ direction are in an ON-state.

FIG. 17 is a view showing an arrow part of the mirror surface of the DMD 10 along line a −a′ in FIG. 16 when seen in an X′Z plane.

FIG. 18 is a view schematically representing an imaging condition by the projection units PLU of reflection light (imaging light flux) Sa from the micro mirrors Msa, which are isolated as in FIG. 16, when seen in the X′Z plane.

FIG. 19 is a graph schematically representing a point image intensity distribution Iea of a diffraction image in the pupil Ep according to regular reflection light Sa from the isolated micro mirrors Msa.

FIG. 20 is a view showing a part of the mirror surface of the DMD 10 when seen in an X′Y′ plane, and showing a case in which a large number of micro mirrors Ms adjacent in the X′ direction are simultaneously in an ON-state.

FIG. 21 is a view showing an arrow part of the mirror surface of the DMD 10 along line a −a′ in FIG. 20 when seen in the X′Z plane.

FIG. 22 is a graph representing an example of a distribution of an angle θj of diffraction light Idj generated from the DMD 10 in a state of FIG. 20 and FIG. 21.

FIG. 23 is a view schematically representing an intensity distribution of an imaging light flux of the pupil Ep in a state in which the diffraction light is generated as in FIG. 22.

FIG. 24 is a view showing a state of a part of the mirror surface of the DMD 10 upon projection of a line and space pattern when seen in the X′Y′ plane.

FIG. 25 is a view showing an arrow part of the mirror surface of the DMD 10 along line a −a′ in FIG. 24 when seen in the X′Z plane.

FIG. 26 is a graph representing an example of a distribution on the angle θj of the diffraction light Idj generated from the DMD 10 in a state of FIG. 24 and FIG. 25.

FIG. 27 is a view schematically representing an intensity distribution of an imaging light flux of the pupil Ep in a generation state of the diffraction light as in FIG. 26.

FIG. 28 is a view showing a specific configuration of an optical path from the optical fiber bundles FBn to the MFE lens 108A in an illumination unit ILU shown in FIG. 4 or FIG. 6.

FIG. 29 is a view showing a specific configuration of an optical path from the MFE lens 108A of the illumination unit ILU to the DMD 10 shown in FIG. 4 or FIG. 6.

FIG. 30 is an exaggerated view showing a state of the point light source SPF formed on an emission surface side of the MFE lens 108A when illumination light ILm entering the MFE lens 108A is inclined in the X′Z plane.

FIG. 31 is a graph in which a relationship between a wavelength λ and a telecentric error Δθt is obtained based on Equation (2) or Equation (3).

FIG. 32 is a graph representing wavelength dependent characteristics of the telecentric error Δθt when the wavelength λ of the illumination light ILm is changed within a range of 280 nm to 450 nm.

FIG. 33 is a view schematically representing wavelength distribution characteristics obtained by combining eight laser light beams with a center wavelength set to 343.333 nm and peak wavelengths each shifted by 0.02 nm.

FIG. 34 is a graph representing characteristics of a telecentric error with the wavelength λwithin a range of 343.200 nm to 343.450 nm.

FIG. 35 is a view schematically representing a distribution on the pupil Ep of 9^{th} order diffraction light Id9 from the DMD 10 entering the projection units PLU.

FIG. 36 is an exaggerated view representing a distribution state of high order diffraction light (j^{th} order diffraction light) appeared in the pupil Ep of the projection units PLU when the illumination light ILm with a large wavelength width Δλ is used.

FIG. 37 is a graph representing a change in an ellipse ratio of a distribution of oval high order diffraction light appeared in the pupil Ep of the projection units PLU when the wavelength width Δλ of the illumination light is changed.

FIG. 38 is a graph representing a relationship between an ellipse ratio of the oval distribution and a change in σ value on the pupil Ep of the projection units PLU of the high order diffraction light from the DMD 10.

FIG. 39 is a view showing an example of wavelength distribution characteristics of the illumination light ILm, a part (A) of FIG. 39 shows a case in which a spectrum is present within a range from a center wavelength λo to the wavelength width Δλ, and a part (B) of FIG. 39 shows a case in which a plurality of spectra each with an extremely small wavelength width are discretely distributed throughout the range of the wavelength width Δλ (±Δλ).

FIG. 40 is a view according to a third embodiment schematically representing an optical path of the illumination unit ILU from the MFE lens 108A to the DMD 10.

FIG. 41 is a view schematically representing a distribution H9c of 9^{th} order diffraction light and a distribution H8c of 8^{th} order diffraction light appeared on the pupil Ep of the projection unit PLU.

FIG. 42 is a view showing an optical layout according to a variant of the embodiment of FIG. 40.

FIG. 43 is an optical layout diagram in which a configuration of the variant of FIG. 42 is further modified.

FIG. 44 is an exaggerated view representing each of layout examples of illumination areas Imf1 and Imf2 projected within a plane of an incident end pff of the MFE lens 108A.

FIG. 45 is an exaggerated view representing another layout example of the illumination areas Imf1 and Imf2 projected within the plane of the incident end pff of the MFE lens 108A.

FIG. 46 is a view schematically illustrating an angle state when the diffraction light Idj from a large number of micro mirrors Msa in the ON-state enters the projection units PLU.

FIG. 47 is a view showing the point image intensity distribution Iea and a distribution of 8^{th} to 10^{th} order diffraction lights Id8, Id9 and Id10 appearing when an error angle Δθd of the micro mirror Msa in the ON-state is zero.

FIG. 48 is a graph obtained by simulating the point image intensity distribution when a tilt angle θd of the micro mirror Msa in the ON-state is changed from a tilt angle θo on design by +0.5° as the error angle Δθd with respect to the characteristics shown in FIG. 47.

FIG. 49 is a graph showing the point image intensity distribution Iea when the wavelength λ1 is 343.333 nm and the point image intensity distribution IeaL when the wavelength λ2 is 355.000 nm in a case in which the error angle Δθd of the micro mirror Msa in the ON-state is zero.

FIG. 50 is a graph showing characteristics of the point image intensity distributions Iea and IeaL when the error angle Δθd of the micro mirror Msa in the ON-state is +0.5° with respect to the state shown in FIG. 49.

FIG. 51 is a graph obtained by simulating a change in light intensity according to the error angle Δθd of the 9^{th} order diffraction lights Id9 (λ1), Id9 (λ2) and Id9 (λ3) generated below each of the three wavelengths λ1, λ2 and λ3.

### DESCRIPTION OF EMBODIMENTS

A pattern exposure device (pattern forming device) according to an aspect of the present invention will be described below in detail with reference to the accompanying drawings, showing preferred embodiments. Further, aspects of the present invention are not limited to these embodiments, and also include various modifications and improvements. That is, the components described below include those that a person skilled in the art could easily conceive and those that are substantially identical, and the components described below can be combined as appropriate. In addition, various omissions, substitutions, or modifications of the components can be made without departing from the scope of the present invention. Further, throughout the drawings and the following detailed description, the same reference signs are used for members or components that perform the same or similar functions.

### [Entire Configuration of Pattern Exposure Device]

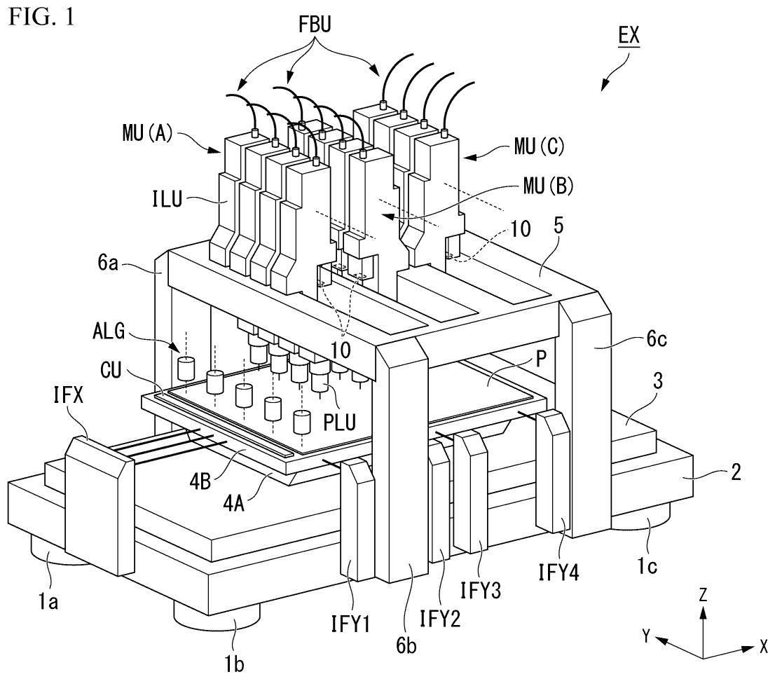

FIG. 1 is a perspective view schematically showing an appearance configuration of a pattern exposure device (hereinafter, also simply referred to as an exposure device) EX of an embodiment. The exposure device EX is a device configured to image and project exposure light with an intensity distribution dynamically modulated in a space to an exposed substrate using a spatial light modulation element (digital mirror device: DMD). In the specified embodiment, the exposure device EX is a step-and-scan projection exposure device (scanner) using a rectangular (square) glass substrate used in a display device (flat panel display) as an exposure object. The glass substrate is a substrate P for a flat panel display, with at least one side or a diagonal length of 500 mm or more and a thickness of 1 mm or less. The exposure device EX exposes a projection image of a pattern created by the DMD onto a photosensitive layer (photoresist) formed with a certain thickness on the surface of the substrate P. After exposure, the substrate P transported out of the exposure device EX is sent to predetermined processes (film forming process, etching process, plating process, and the like) after the development process.

The exposure device EX includes a pedestal 2 placed on active anti-vibration units 1a1, 1b, 1c and 1d (1d is not shown), a fixed plate 3 placed on the pedestal 2, an XY stage 4A 2-dimensionally movable on the fixed plate 3, a substrate holder 4B configured to absorb and hold the substrate P on the XY stage 4A in a planar surface, and a stage device constituted by laser distance measuring interferometers (hereinafter, also simply referred to as interferometers) IFX and IFY1 to IFY4 configured to measure a two-dimensional moving position of the substrate holder 4B (the substrate P). Such a stage device is disclosed in, for example, US Patent No. 2010/0018950 and US Patent No. 2012/0057140.

In FIG. 1, an XY plane of an orthogonal coordinate system XYZ is set parallel to a planar surface of the fixed plate 3 of the stage device, and the XY stage 4A is set to be translated in the XY plane. In addition, in the embodiment, a direction parallel to an X axis of the coordinate system XYZ is set to a scanning movement direction of the substrate P (the XY stage 4A) during scan exposure. A moving position of the substrate P in an X-axis direction is sequentially measured by the interferometer IFX, and a moving position in a Y-axis direction is sequentially measured by at least one (preferably two or more) of the four interferometers IFY1 to IFY4. The substrate holder 4B is configured to be finely movable relative to the XY stage 4A in a Z-axis direction perpendicular to the XY plane and configured to be finely tiltable relative to the XY plane in an arbitrary direction, and focus adjustment and leveling (parallelism) adjustment relative to a surface of the substrate P and an imaging surface with a projected pattern are actively performed. Further, the substrate holder 4B is configured to be finely rotatable (Oz rotation) about an axis parallel to a Z axis in order to actively adjust an inclination of the substrate P in the XY plane.

The exposure device EX further includes an optical fixed plate 5 configured to hold a plurality of exposure (drawing) module groups MU (A), MU (B) and MU (C), and main columns 6a, 6b, 6c and 6d (6d is not shown) configured to support the optical fixed plate 5 from the pedestal 2. Each of the plurality of exposure module groups MU (A), MU (B), MU (C) includes an illumination unit ILU attached to the optical fixed plate 5 on a side at a+Z direction and into which illumination light from an optical fiber unit FBU enters, and a projection unit PLU attached to the optical fixed plate 5 at a side in a −Z direction and having an optical axis parallel to the Z axis. Further, each of the exposure module groups MU (A), MU (B) and MU (C) includes a digital mirror device (DMD) 10 as an optical modulation unit configured to reflect illumination light from the illumination unit ILU in a −Z direction to be incident on the projection units PLU. A specific configuration of the exposure module group constituted by the illumination unit ILU, the DMD 10 and the projection units PLU will be described below.

A plurality of alignment systems (microscopes) ALG configured to detect alignment marks formed at predetermined plural positions on the substrate P are attached to the optical fixed plate 5 of the exposure device EX at a side in the −Z direction. In order to perform confirmation (calibration) of a relative positional relation in an XY plane in a detection field of view of each of the alignment systems ALG, confirmation (calibration) of a baseline error between each projection position of pattern images projected from the projection units PLU of the exposure module groups MU (A), MU (B) and MU (C) and a position of each detection field of view of the alignment systems ALG, or confirmation of a position or image quality of a pattern image projected from the projection units PLU, a calibration reference unit CU is provided at an end portion on the substrate holder 4B in the −X direction. Further, although some of the exposure module groups MU (A), MU (B) and MU (C) are not shown in FIG. 1, in this embodiment, as an example, nine modules are arranged at regular intervals in the Y direction, but the number of modules may be more or less than nine.

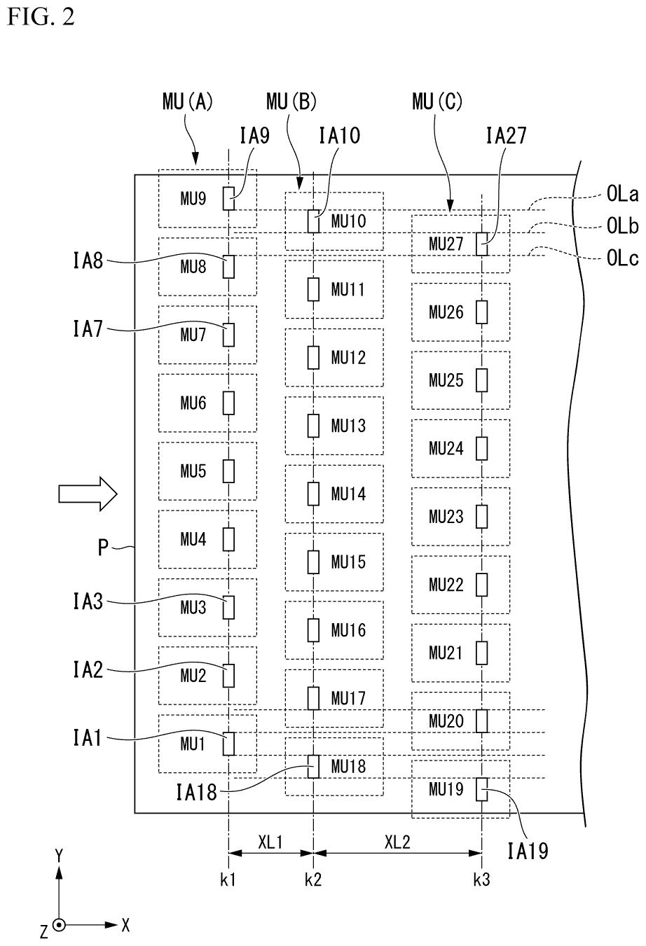

FIG. 2 is a view showing a layout example of the projection areas IAn of a digital mirror device (DMD) 10 projected onto the substrate P by the projection units PLU of each of the exposure module groups MU (A), MU (B) and MU (C), and the orthogonal coordinate system XYZ is set like FIG. 1. In the embodiment, each of the exposure module group MU (A) in a first row, the exposure module group MU (B) in a second row, and the exposure module group MU (C) in a third row, which are disposed separately in the X direction, is constituted by nine modules arranged in the Y direction. The exposure module group MU (A) is constituted by nine modules MU1 to MU9 disposed in a+Y direction, the exposure module group MU (B) is constituted by nine modules MU10 to MU18 disposed in a −Y direction, and the exposure module group MU (C) is constituted by nine modules MU19 to MU27 disposed in the +Y direction. The modules MU1 to MU27 all have the same configuration, and when the exposure module group MU (A) and the exposure module group MU (B) are in a face-to-face relationship in the X direction, the exposure module group MU (B) and the exposure module group MU (C) are in a back-to-back relationship in the X direction.

In FIG. 2, a shape of projection areas IA1, IA2, IA3, . . . , IA27 (sometimes represented as IAn, where n is 1 to 27) of each of the modules MU1 to MU27 is, for example, a rectangle θxtending in the Y direction with an aspect ratio of approximately 1:2. In the embodiment, according to scanning movement of the substrate P in the +X direction, seamless exposure is performed on an end portion in the −Y direction of each of the projection areas IA1 to IA9 in the first row, and on an end portion in the +Y direction of each of the projection areas IA10 to IA18 in the second row. Then, regions on the substrate P that are not exposed in each of the projection areas IA1 to IA18 in the first and second rows are seamlessly exposed by each of the projection areas IA19 to IA27 in the third row. A center point of each of the projection areas IA1 to IA9 in the first row is located on a line k1 parallel to the Y axis, a center point of each of the projection areas IA10 to IA18 in the second row is located on a line k2 parallel to the Y axis, and a center point of each of the projection areas IA19 to IA27 in the third row is located on a line k3 parallel to the Y axis. An interval between the line k1 and the line k2 in the X direction is set to a distance XL1, and an interval between the line k2 and the line k3 in the X direction is set to a distance XL2.

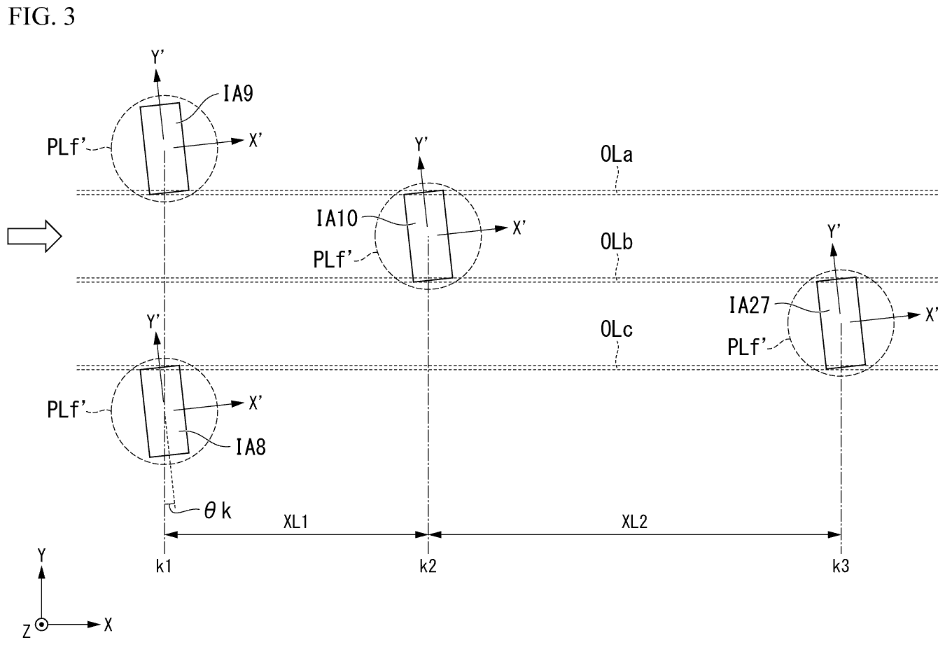

Here, provided that a joint portion between the end portion of the projection area IA9 in the −Y direction and the end portion of the projection area IA10 in the +Y direction is OLa, a joint portion between the end portion of the projection area IA10 in the −Y direction and the end portion of the projection area IA27 in the +Y direction is OLb, and a joint portion between the end portion of the projection area IA8 in the +Y direction and the end portion of the projection area IA27 in the −Y direction is OLc, a state of the seamless exposure will be described with reference to FIG. 3. In FIG. 3, the orthogonal coordinate system XYZ is set up the same as in FIG. 1 and FIG. 2, and a coordinate system X′Y′ in the projection areas IA8, IA9, IA10 and IA27 (and all other projection areas IAn) is set up to be tilted by an angle θk with respect to the X axis and Y axis (the lines k1 to k3) of the orthogonal coordinate system XYZ. That is, the entire DMD 10 is tilted by the angle θk in the XY plane so that the two-dimensional layout of the number of micro mirrors in the DMD 10 is in the coordinate system X′Y′.

A circular region including each of the projection areas IA8, IA9, IA10 and IA27 (and, the other all projection areas IAn are also the same) in FIG. 3 represents a circular image field PLf′ of, the projection unit PLU. The joint portion OLa is set so that a projection image of micro mirrors aligned so as to the tilt (the angle θk) of the end portion of the projection area IA9 in a −Y′ direction overlaps with a projection image of micro mirrors aligned so as to the tilt (the angle θk) of the end portion of the projection area IA10 in a+Y′ direction. In addition, the joint portion OLb is set so that a projection image of the micro mirrors aligned so as to the tilt (the angle θk) of the end portion of the projection area IA10 in the −Y′ direction overlaps with a projection image of the micro mirror aligned so as to the tilt (the angle θk) of the end portion of the projection area IA27 in the +Y′ direction. Similarly, the joint portion OLc is set so that a projection image of the micro mirrors aligned so as to the tilt (the angle θk) of the end portion of the projection area IA8 in the +Y′ direction overlaps with a projection image of the micro mirrors aligned so as to the tilt (the angle θk) of the end portion of the projection area IA27 in the −Y′ direction.

### [Configuration of Illumination Unit]

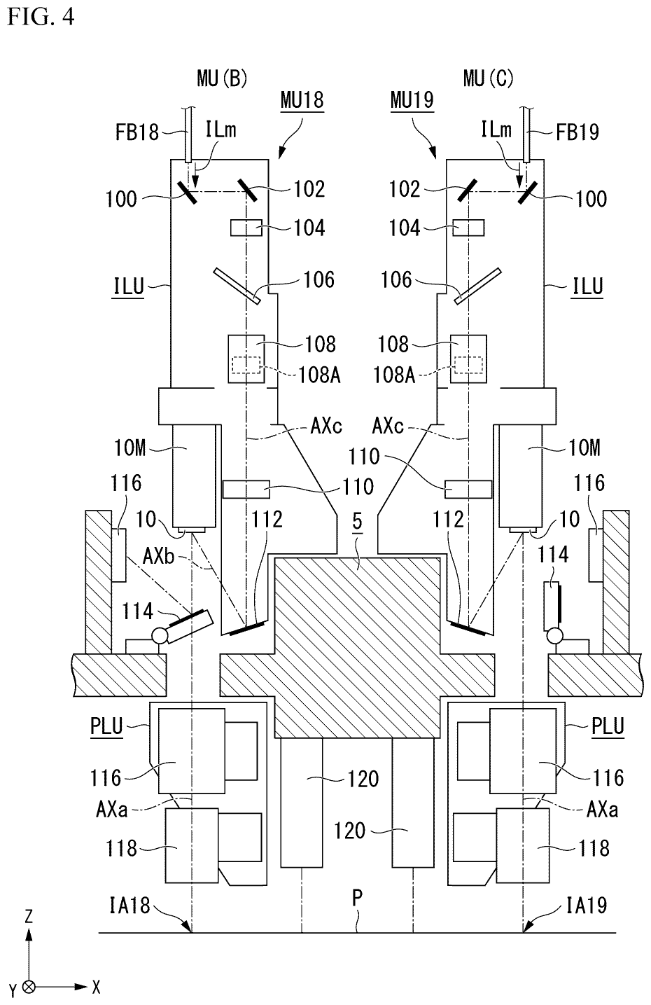

FIG. 4 is an optical layout diagram of a specific configuration of the module MU18 in the exposure module group MU (B) and the module MU19 in the exposure module group MU (C) shown in FIG. 1 and FIG. 2 when seen in the XZ plane. The orthogonal coordinate system XYZ in FIG. 4 is set to the same as the orthogonal coordinate system XYZ in FIG. 1 to FIG. 3. In addition, as is clear from the arrangement of each module in the XY plane shown in FIG. 2, the module MU18 is shifted by a certain interval in the +Y direction with respect to the module MU19, and they are installed in a back-to-back relationship. Since each optical member in the module MU18 and each optical member in the module MU19 are made of the same materials and have the same configuration, the optical configuration of the module MU18 will be mainly described in detail below. Further, the optical fiber unit FBU shown in FIG. 1 is constituted by 27 optical fiber bundles FB1 to FB27, each of which corresponds to the 27 modules MU1 to MU27 shown in FIG. 2.

The illumination unit ILU of the module MU18 is constituted by a mirror 100 configured to reflect the illumination light ILm advancing from an emission end of the optical fiber bundle FB18 in a −Z direction, a mirror 102 configured to reflect the illumination light ILm from the mirror 100 in the −Z direction, an input lens system 104 acting as a collimator lens, an illuminance adjustment filter 106, an optical integrator 108 including micro fly eye (MFE) lens, a field lens, or the like, a condenser lens system 110, and an inclined mirror 112 configured to reflect the illumination light ILm from the condenser lens system 110 toward the DMD 10. The mirror 102, the input lens system 104, the optical integrator 108, the condenser lens system 110, and the inclined mirror 112 are disposed along an optical axis AXc parallel to the Z axis.

The optical fiber bundle FB18 is constituted by one optical fiber line or a bundle of multiple optical fiber lines. The illumination light ILm emitted from the emission end of the optical fiber bundle FB18 (each optical fiber line) is set to a numerical aperture (NA, also referred to as a spread angle) so that it enters an input lens system 104 of a rear stage without being reflected. A position of the front focus of the input lens system 104 is set to be the same as the emission end of the optical fiber bundle FB18 in terms of design. Further, a position of the rear focus of the input lens system 104 is set so that the illumination light ILm from a single or plurality of point light sources formed at the emission end of the optical fiber bundle FB18 overlaps with the incidence surface side of the MFE lens 108A of the optical integrator 108. Accordingly, the incidence surface of the MFE lens 108A is Koehler-illuminated by the illumination light ILm from the emission end of the optical fiber bundle FB18. Further, in an initial state, a geometric center point in the XY plane of the emission end of the optical fiber bundle FB18 is located on the optical axis AXc, and a principal ray (centerline) of the illumination light ILm from the point light source of the emission end of optical fiber bundle is parallel to (coaxial with) the optical axis AXc.

The illumination light ILm from the input lens system 104 has its illuminance attenuated by an arbitrary value in the range of 0% to 90% by the illuminance adjustment filter 106, and then passes through the optical integrator 108 (the MFE lens 108A, a field lens, etc.) and enters the condenser lens system 110. The MFE lens 108A has a two-dimensional layout of many rectangular micro lenses with several tens of micrometers square, and its overall shape is set to be nearly similar to the overall shape of the mirror surface of the DMD 10 (aspect ratio is approximately 1:2) in the XY plane. In addition, the position of the front focus of the condenser lens system 110 is set to be approximately the same as the position of the emission surface of the MFE lens 108A. For this reason, each of the illumination lights from the point light sources formed on each emission side of the number of micro lenses of the MFE lens 108A is converted into an approximately parallel light flux by the condenser lens system 110, reflected by the inclined mirror 112, and then superimposed on the DMD 10 to result in a uniform illuminance distribution.

The emission surface of the MFE lens 108A functions as a surface light source member because a surface light source is generated on which the number of point light sources (focus points) are densely laid out in a two-dimensional manner. Such MFE lens 108A may be configured, for example, as disclosed in Japanese Patent Laid-open Publication No. 2004-045885, by arranging a plurality of cylindrical micro fly eye lens elements, each formed by arranging a number of cylindrical lenses on both the incidence surface side and the emission surface side of the illumination light, at predetermined intervals in the optical axis direction.

In the module MU18 shown in FIG. 4, the optical axis AXc, which is parallel to the Z axis passing through the condenser lens system 110, is bent by the inclined mirror 112 to reach the DMD 10, and the optical axis between the inclined mirror 112 and the DMD 10 is referred to as an optical axis AXb. In the embodiment, a neutral plane containing the center points of the number of micro mirrors of the DMD 10 is set parallel to the XY plane. Accordingly, the angle between the normal line of the neutral plane (parallel to the Z axis) and the optical axis AXb is an incidence angle θα of the illumination light ILm to the DMD 10. The DMD 10 is attached to a lower side of a mounting section 10M which is fixed to a support column of the illumination unit ILU. The mounting section 10M is equipped with a micromotion stage that combines a parallel link mechanism and an extendable piezo element, as disclosed, for example, in PCT International Publication No. 2006/120927, to finely adjust the position and posture of the DMD 10.

The illumination light ILm that is irradiated to the micro mirror in the ON-state among the micro mirrors of the DMD 10 is reflected in the X direction in the XZ plane so as to head toward the projection unit PLU. Meanwhile, the illumination light ILm that is irradiated onto the micro mirror in the OFF-state among the micro mirrors of the DMD 10 is reflected in the Y direction in the YZ plane so as not to proceed toward the projection units PLU. As will be described in more detail later, the DMD 10 in this embodiment employs a roll & pitch drive system that switches between the ON and OFF-states by tilting the micro mirror in roll and pitch directions.

A movable shutter 114 is removably provided in the optical path between the DMD 10 and the projection units PLU to block reflected light from the DMD 10 during non-exposure periods. As shown on the side of the module MU19, the movable shutter 114 is pivoted to an angular position where it is removed from the optical path during the exposure period, and as shown on the side of the module MU18, is pivoted to an angular position where it is inserted obliquely into the optical path during the non-exposure period. A reflecting surface is formed on the side of the movable shutter 114 at the side of the DMD 10, and the light from the DMD 10 reflected there is irradiated to a light absorber 115. The light absorber 115 absorbs light energy in the ultraviolet wavelength range (wavelengths below 400 nm) without re-reflecting the light energy and converts it into thermal energy. For this reason, a heat dissipation mechanism (heat dissipation fin or cooling mechanism) is also provided in the light absorber 115. Further, while not shown in FIG. 4, the reflected light from the micro mirrors of the DMD 10, which are in the OFF-state during the exposure period, is absorbed by a similar light absorber (not shown in FIG. 4) installed in the Y direction (a direction perpendicular to the drawing in FIG. 4) with respect to the optical path between the DMD 10 and the projection units PLU.

### [Configuration of Projection Unit]

The projection units PLU, attached to the lower side of the optical fixed plate 5, are configured as a bilateral telecentric imaging projection lens system constituted by a first lens group 116 and a second lens group 118 arranged along an optical axis AXa parallel to the Z axis. The first lens group 116 and the second lens group 118 are each configured to translate by a micromotion actuator in a direction along the Z axis (the optical axis AXa) relative to a support column fixed to the lower side of the optical fixed plate 5. A projection magnification Mp of the imaging projection lens system constituted by the first lens group 116 and the second lens group 118 is determined by a relationship between an array pitch Pd of the micro mirrors on the DMD 10 and a minimum line width (minimum pixel dimension) Pg of the pattern projected within the projection areas IAn (n=1 to 27) on the substrate P.

As an example, when the required minimum line width (minimum pixel dimension) Pg is 1 μm and the array pitch Pd of the micro mirror is 5.4 μm, the projection magnification Mp is set to approximately ⅙, taking into consideration a tilt angle θk in the XY plane of the projection areas IAn (the DMD 10) described in FIG. 3 above. The imaging projection lens system constituted by the lens groups 116 and 118 inverts/flips the reduced image of the entire mirror surface of the DMD 10 and images it onto the projection areas IA18 (IAn) on the substrate P.

The first lens group 116 of the projection units PLU can be finely moved in the optical axis AXa direction by an actuator to finely adjust (on the order of ±several tens of ppm) the projection magnification Mp, and the second lens group 118 can be finely moved in the optical axis AXa direction by an actuator to quickly adjust the focus. Further, in order to measure the position change in the Z-axis direction on the surface of the substrate P with an accuracy of submicron or less, multiple oblique incidence light type focus sensors 120 are provided on the lower side of the optical fixed plate 5. The plurality of focus sensors 120 measure a position change in the overall Z-axis direction of the substrate P, a position change in the Z-axis direction of a partial region on the substrate P corresponding to each of the projection areas IAn (n=1 to 27), or a partial tilt change of the substrate P or the like.

As described above in FIG. 3, since the illumination unit ILU and the projection units PLU described above need to have the projection areas IAn tilted by the angle θk in the XY plane, the DMD 10 and the illumination unit PLU in FIG. 4 (at least the portion of the optical path from the mirror 102 to the mirror 112 along the optical axis AXc) are positioned so that they are tilted overall by the angle θk in the XY plane.

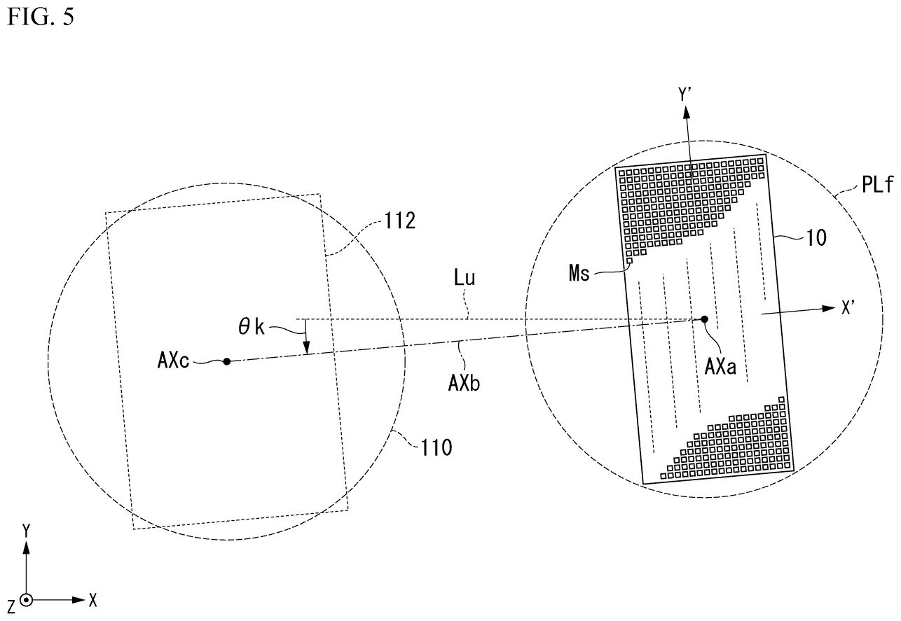

FIG. 5 is a view schematically representing a state in which the DMD 10 and the illumination unit PLU are tilted by the angle θk in the XY plane when seen in the XY plane. In FIG. 5, the orthogonal coordinate system XYZ is the same as the coordinate system XYZ in each of FIGS. 1 to 4 above, and an array coordinate system X′Y′ of the micro mirror MS of the DMD 10 is the same as the coordinate system X′Y′ shown in FIG. 3. A circle containing the DMD 10 is an image field PLf of the projection units PLU on the side of the object surface, and the optical axis AXa is located at its center.

Meanwhile, the optical axis AXc passes through the condenser lens system 110 of the illumination unit ILU and is bent by the inclined mirror 112 to form the optical axis AXb, which is tilted by the angle θk from a line Lu that is parallel to the X axis when seen in the XY plane.

### [Imaging Optical Path by DMD]

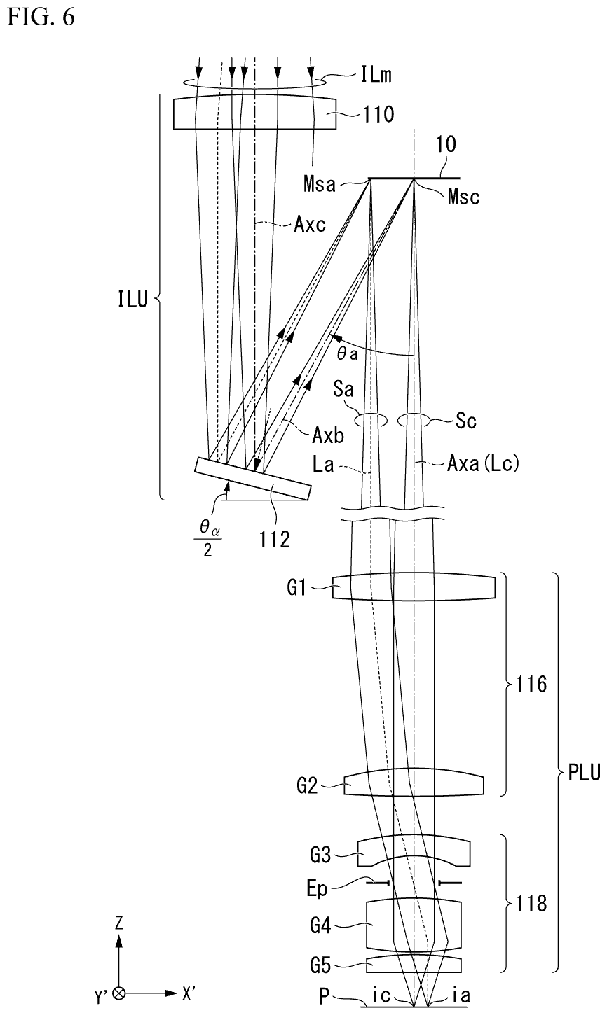

Next, an imaging condition of the micro mirror Ms of the DMD 10 by the projection unit PLU (imaging projection lens system) will be described in detail with reference to FIG. 6. An orthogonal coordinate system X′Y′Z of FIG. 6 is the same as the coordinate system X′Y′Z shown in FIG. 3 and FIG. 5 described above, and FIG. 6 shows an optical path from the condenser lens system 110 of the illumination unit ILU to the substrate P. The illumination light ILm from the condenser lens system 110 travels along the optical axis AXc, is totally reflected by the inclined mirror 112, and reaches the mirror surface of the DMD 10 along the optical axis AXb. Here, the micro mirror Ms located at a center of the DMD 10 is referred to as Msc, the micro mirrors Ms located at surroundings are referred to as Msp, and the micro mirrors Msc and Msp are in the ON-state.

If the tilt angle of the micro mirror Ms in the ON-state is, for example, 17.5° as the standard value with respect to the X′Y′ plane (XY plane), the incidence angle θα (angle of the optical axis AXb from the optical axis AXa) of the illumination light ILm irradiated to the DMD 10 is set to 35.0° in order to make each principal ray of the reflection lights Sac and Sap from each of the micro mirrors Msc and Msp parallel to the optical axis AXa of the projection unit PLU. Accordingly, in this case, the reflecting surface of the inclined mirror 112 is disposed to be tilted by 17.5° (=θα/2) with respect to the X′Y′ plane (XY plane). A principal ray Lc of the reflection light Sac from the micro mirror Msc is coaxial with the optical axis AXa, a principal ray La of the reflection light Sap from the micro mirror Msp is parallel to the optical axis AXa, and the reflection lights Sac and Sap enter the projection unit PLU with a predetermined numerical aperture (NA).

By the reflection light Sac, a reduced image ic of the micro mirror Msc, which is reduced by the projection magnification Mp of the projection unit PLU, is imaged on the substrate P in a telecentric state at the position of the optical axis AXa. Similarly, by the reflection light Sap, a reduced image ia of the micro mirror Msp, reduced by the projection magnification Mp of the projection unit PLU, is imaged on the substrate P in a telecentric state at a position away from the reduced image ic in the +X′ direction. As an example, the first lens system 116 of the projection unit PLU is constituted by three lens groups G1, G2 and G3, and the second lens system 118 is constituted by two lens groups G4 and G5. An exit pupil (also simply referred to as a pupil) Ep is set between the first lens system 116 and the second lens system 118. At the position of the pupil Ep, a light source image of the illumination light ILm (an assembly of the number of point light sources formed on the emission surface side of the MFE lens 108A) is formed, resulting in a Koehler illumination configuration. The pupil Ep is also referred to as the opening of the projection unit PLU, and the size (diameter) of this opening is one of the factors that define the resolution of the projection unit PLU. Further, a position of the pupil Ep corresponds to a position of the aperture of the projection unit PLU.

The specular reflection light from the micro mirror Ms in the ON-state of the DMD 10 is set to pass through the maximum diameter (diameter) of the pupil Ep without being obstructed, and a numerical aperture NAi (also referred to as the maximum numerical aperture NAi (max)) on the image-side (the substrate P side) in the equation representing the resolution R, R=k1 (λ/NAi), is determined by the maximum diameter of the pupil Ep and the distance of the rear (image-side) focus of the projection unit PLU (the lens groups G1 to G5 as the imaging projection lens system). In addition, a numerical aperture NAo (also referred to as the maximum numerical aperture NAo (max)) of the projection unit PLU (the lens groups G1 to G5) on the side of the object surface (the DMD 10) is represented by a product of the projection magnification Mp and the numerical aperture NAi, and becomes NAo=NAi/6 [NAo (max)=NAi (max)/6] when the projection magnification Mp is ⅙.

In the configuration of the illumination unit ILU and the projection unit PLU shown in FIG. 6 and FIG. 4 described above, the emission end of the optical fiber bundles FBn (n=1 to 27) connected to each of the modules MUn (n=1 to 27) is set to an optical conjugate relationship with the emission end side of the MFE lens 108A of the optical integrator 108 by the input lens system 104, and the incident end side of the MFE lens 108A is set to an optical conjugate relationship with the center of the mirror surface (neutral plane) of the DMD 10 by the condenser lens system 110. As a result, the illumination light ILm irradiated onto the entire mirror surface of the DMD 10 has a uniform illuminance distribution (for example, intensity unevenness within +1%) due to the action of the optical integrator 108. In addition, the surface light source (the assembly of the number of point light sources SPF) on the emission end side of the MFE lens 108A and the surface of the pupil Ep of the projection unit PLU are set in an optical conjugate relationship by the condenser lens system 110 and the lens groups G1 to G3 of the projection unit PLU.

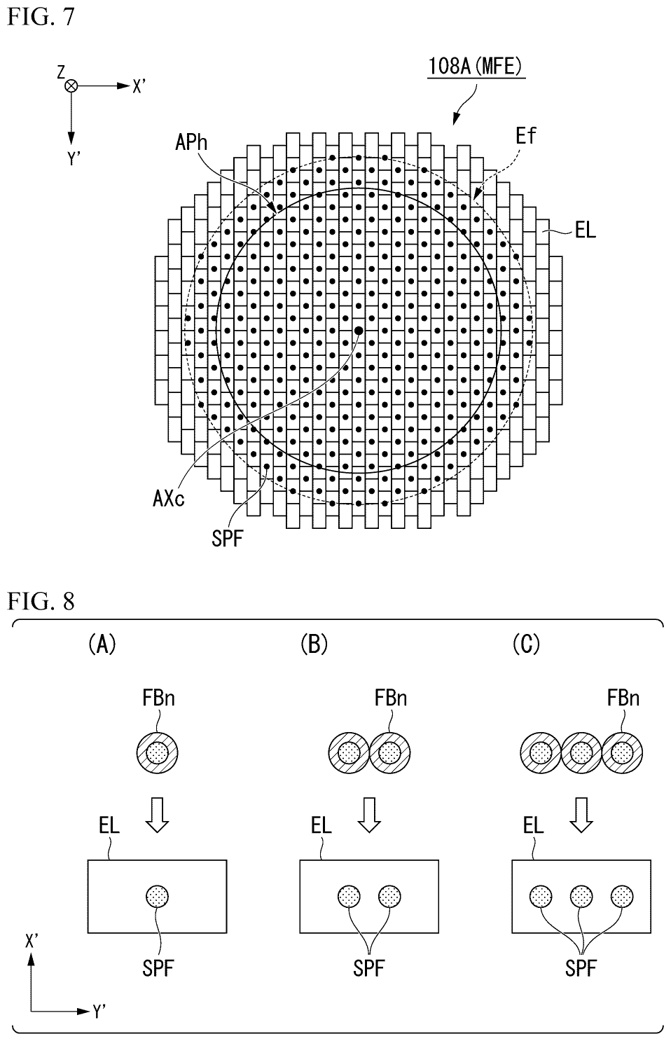

FIG. 7 is a schematic diagram of the MFE lens 108A of the optical integrator 108 when seen from the emission surface side. The MFE lens 108A is constituted by a large number of lens elements EL, each of which has a rectangular cross-section extending in the Y′ direction in the X′Y′ plane and whose cross-sectional shape is similar to the shape of the entire mirror surface (image forming region) of the DMD 10, densely arranged in the X′ and Y′ directions. The illumination light ILm from the input lens system 104 shown in FIG. 4 is irradiated onto the incidence surface side of the MFE lens 108A, forming an approximately circular irradiation region Ef. The irradiation region Ef has a shape similar to each emission end of a single or plurality of optical fiber lines of the optical fiber bundle FB18 (FBn) in FIG. 4, and is a circular region centered on the optical axis AXc by design.

Among the number of lens elements EL of the MFE lens 108A, on the emission surface side of each of the lens elements EL located within the irradiation region Ef, the point light source SPF created by the illumination light ILm from the emission end of the optical fiber bundle FB18 (FBn) is densely distributed within an approximately circular region. In addition, a circular region APh in FIG. 7 represents an opening range when an aperture with a circular opening is provided on the emission surface side of the MFE lens 108A. The actual illumination light ILm is created by the number of point light sources SPF scattered within the circular region APh, and light from the point light sources SPF outside the circular region APh is blocked.

Parts (A), (B) and (C) of FIG. 8 are views for schematically representing an example of a layout relationship between the point light source SPF formed on the emission surface side of the lens element EL of the MFE lens 108A in FIG. 7 and the emission end of the optical fiber bundles FBn. The coordinate system X′Y′ in each of the parts (A), (B) and (C) of FIG. 8 is the same as the coordinate system X′Y′ set in FIG. 7. The part (A) of FIG. 8 represents a case in which the optical fiber bundle FBn is a single optical fiber line, the part (B) of FIG. 8 represents a case in which two optical fiber lines are arranged in the X′ direction as the optical fiber bundles FBn, and the part (C) of FIG. 8 represents a case in which three optical fiber lines are arranged in the X′ direction as the optical fiber bundles FBn.

Since the emission end of the optical fiber bundle FBn and the emission surface of the MFE lens 108A (the lens element EL) are set in an optically conjugate relationship (imaging relationship), when the optical fiber bundle FBn is a single optical fiber line, a single point light source SPF is formed at the center position of the emission surface side of the lens element EL, as shown in the part (A) of FIG. 8. When two optical fiber lines are bundled in the X′ direction as the optical fiber bundles FBn, the geometric centers of the two point light sources SPF are formed at the center position of the emission surface side of the lens element EL, as shown in the part (B) of FIG. 8. Similarly, when three optical fiber lines are bundled in the X′ direction as the optical fiber bundles FBn, the geometric centers of the three point light sources SPF are formed at the center positions of the emission surface side of the lens element EL, as shown in the part (C) of FIG. 8.

Further, if the power of the illumination light ILm from the optical fiber bundles FBn is large and the point light source SPF is focused on the emission surface of each of the lens elements EL of the MFE lens 108A, which acts as a surface light source member or optical integrator, it can cause damage (such as clouding or burning) to each of the lens elements EL. In this case, a focusing position of the point light source SPF may be set in a space slightly shifted outward from the emission surface of the MFE lens 108A (the emission surface of the lens element EL). In this way, an illumination system using a fly eye lens in which a position of the point light source (focus point) is shifted outside the lens element is disclosed, for example, in U.S. Pat. No. 4,939,630.

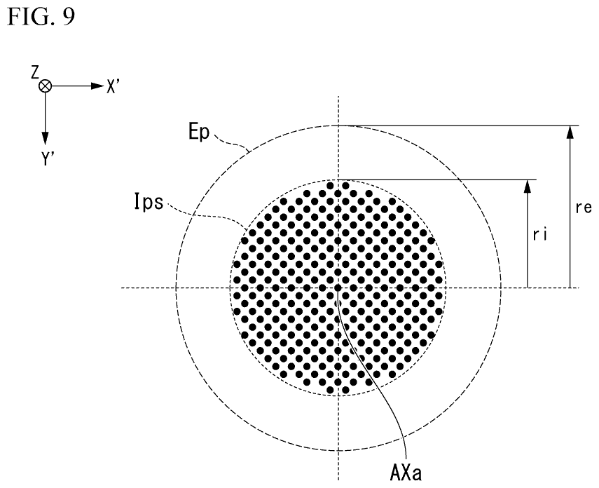

FIG. 9 is a view schematically representing an aspect of the light source image Ips formed on the pupil Ep in the second lens system 118 of the projection unit PL of FIG. 6, assuming the plane mirror is tilted by an angle θα/2 to be parallel to the inclined mirror 112 in FIG. 6 using the entire mirror surface of the DMD 10 as a single plane mirror. The light source image Ips shown in FIG. 9 is a re-imaging of the number of point light sources SPF (which form an almost circular assembly of surface light sources) formed on the emission surface side of the MFE lens 108A. In this case, a plane mirror disposed in place of the DMD 10 does not generate diffraction light or scattered light, and only the light source image Ips is generated in the center of the pupil Ep, coaxial with the optical axis AXa, using only specular reflection light (0^{th} order light).

In FIG. 9, provided that a radius corresponding to the maximum diameter of the pupil Ep is re and a radius corresponding to an effective diameter of the light source image Ips as the surface light source is ri, an σ value that represents a size (area) of the light source image Ips with respect to the size (area) of the pupil Ep is σ=ri/re. The σ value may be changed as needed to improve the line width, crowding, or depth of focus (DOF) of the projected and exposed pattern. The σ value can be changed by providing a variable aperture at the position of the emission surface side of the MFE lens 108A or at the position of the pupil Ep between the first lens system 116 and the second lens system 118 (conjugate relationship with the circular region APh in FIG. 7).

In this type of the exposure device EX, the pupil Ep of the projection units PLU is often used at its maximum diameter, so the σ value is mainly changed using the variable aperture on the emission surface side of the MFE lens 108A. In this case, the radius ri of the light source image Ips is defined by the radius of the circular region APh in FIG. 7. Of course, a variable aperture may be set in the pupil Ep of the projection units PLU to adjust the σ value and the depth of focus (DOF).

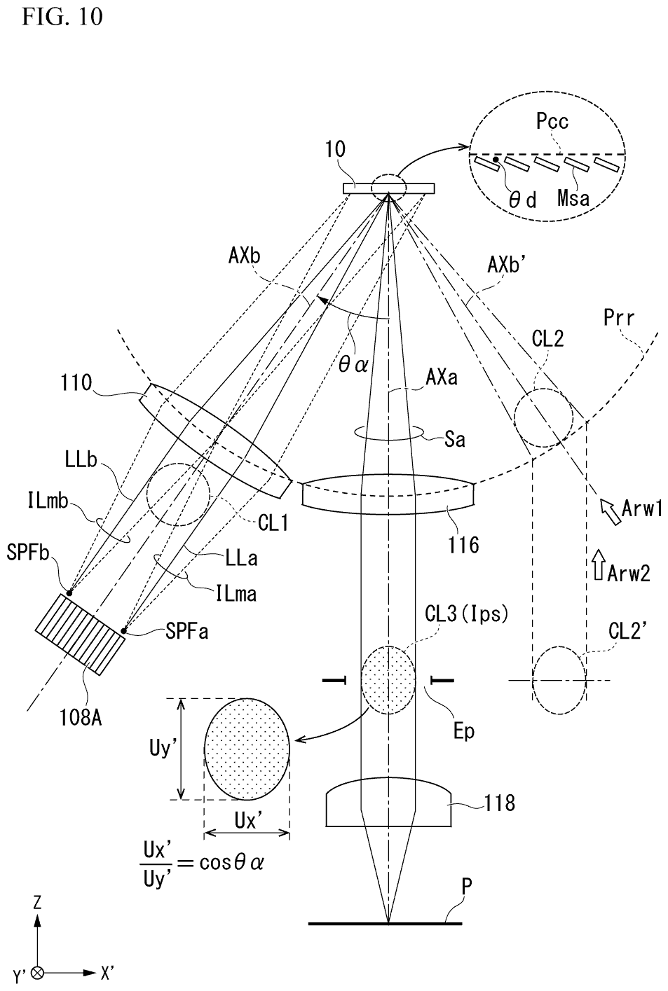

However, when the neutral plane of the DMD 10 is set perpendicular to the optical axis AXa of the projection unit PLU and the illumination light ILm is set at a relatively large incidence angle θ (for example, θα≥) 20°, it was found that the intensity distribution of the imaging light flux at the pupil Ep due to the reflection light from the micro mirror Msa (or Msc) in the ON-state of the DMD 10 does not become the distribution of the light source image Ips bounded by a circular contour as shown in FIG. 9, but becomes an oval shape. This will be described with reference to FIG. 10.

FIG. 10 is an optical path diagram that simplifies and represents the optical path diagram of FIG. 6 in advance, and the orthogonal coordinate system X′Y′Z is set to the same as in FIG. 6 described above. In addition, for ease of description, the inclined mirror 112 shown in FIG. 6 will be omitted. In FIG. 10, a tilt angle θd of the micro mirror Msa of the DMD 10 in the ON-state is set to 17.5° as the design value with respect to a neutral plane Pcc. Accordingly, an angle formed between the optical axis AXb passing through the MFE lens 108A and the condenser lens system 110 and the optical axis AXa of the projection units PLU, i.e., the incidence angle θα is set to 35° in the X′Z plane.

Among the number of point light sources SPF formed on the emission side of the MFE lens 108A, illumination lights ILma and ILmb from each of two point light sources SPFa and SPFb located on the outermost periphery of the circular region APh shown in FIG. 7 within the plane parallel to the X′Z plane including the optical axis AXb illuminate the entire DMD 10 via condenser lens system 110. Central rays LLa and LLb of the illumination lights ILma and ILmb are parallel to the optical axis AXb until entering the condenser lens system 110. Accordingly, when looking at the surface light source (assembly of the point light sources SPF) on the emission side of the MFE lens 108A from the side of the DMD 10, its shape is a circle CL1.

Here, assuming that the reflecting surfaces of the number of micro mirrors in the DMD 10 are all parallel to the neutral plane Pcc, the illumination lights ILma and ILmb travel as regular reflection light along the optical axis AXb′, which is tilted at an angle (−θα) symmetrical to the optical axis AXb with respect to the optical axis AXa. In addition, the main surface of the first lens group 116 of the projection units PLU and the main surface of the condenser lens system 110 are assumed to be located on an arc Prr centered at the intersection of the neutral plane Pcc and the optical axis AXa of the DMD 10. When viewed from an arrow Arw1 side, regular reflection light traveling along the optical axis AXb′ appears as a circle CL2, similar to the surface light source (assembly of the point light sources SPF) on the emission side of the MFE 108A.

However, when viewed from an arrow Arw2 side parallel to the optical axis AXa of the projection units PLU, regular reflection light traveling along the optical axis AXb′ appears as an oval shape CL2′ because the circle surface light source (assembly of the point light sources SPF) on the emission side of the MFE lens 108A is seen obliquely. Meanwhile, when pattern projection is performed by driving the DMD 10, the reflection light (and diffraction light) generated from many of the on-state micro mirrors Msa becomes the imaging light flux Sa and enters the first lens group 116 of the projection units PLU. Since the first lens group 116 and the condenser lens system 110 are arranged along the separate optical axes AXa and AXb, each tilted by an angle θα, when the intensity distribution (distribution of the image of the point light source SPF) of the 0^{th} order light equivalent component of the imaging light flux Sa generated from the micro mirror Msa of the DMD 10 in the ON-state is viewed on the pupil Ep, it appears to have an oval shape CL3 because the circle surface light source on the emission surface side of the MFE lens 108A is viewed obliquely.

When the distribution of the surface light source on the emission surface side of the MFE lens 108A is a perfect circle centered on the optical axis AXb, the intensity distribution of the oval shape CL3 of the imaging light flux Sa (0^{th} order light equivalent component) formed on the pupil Ep of the projection unit PLU is compressed in an incidence direction of the illumination light ILm when viewed in the X′Y′ plane. Since the incidence direction of the illumination light ILm to the DMD 10 is the X′ direction in the X′Y′ plane, the long axis of the intensity distribution of the oval shape CL3 is parallel to the Y′ axis and the short axis is parallel to the X′ axis. If the long axis dimension of the intensity distribution of the oval shape CL3 is Uy′ and the short axis dimension is Ux′, the ellipse ratio Ux′/Uy′ is cosθα, depending on the incidence angle θα of the illumination light ILm. Since the incidence angle θα is twice the tilt angle θd of the micro mirror Msa of the DMD 10 in the ON-state, the ratio Ux′/Uy′ may be set as cos (λ·θd). When the incidence angle θα is 35°, the ratio Ux′/Uy′ is about 0.82.

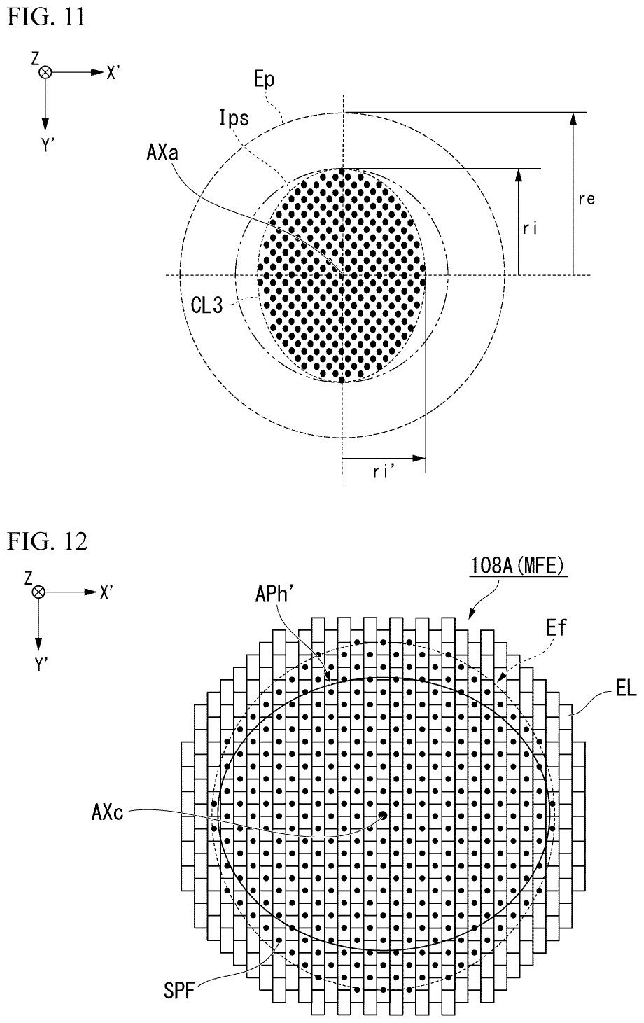

FIG. 11 is a view schematically representing an aspect of the light source image Ips formed on the pupil Ep by the 0^{th} order equivalent component with the largest intensity of the imaging light flux Sa from the DMD 10, like the above-mentioned FIG. 9. The light source image Ips (the oval shape CL3) has a radial dimension in the Y′ direction of the same radius ri as in FIG. 9, and a radial dimension in the X′ direction of a radius ri′ that is approximately 0.82 times smaller than radius ri. In this way, when the intensity distribution (distribution of the light source image Ips) formed in the pupil Ep by the 0^{th} order equivalent component of the imaging light flux Sa is anisotropic, the imaging characteristics of the edge portion may differ depending on the direction in the X′Y′ plane (i.e., in the XY plane) of the edge of the pattern projected onto the substrate P via projection units PLU. For this reason, in general, it is desirable for the intensity distribution formed in the pupil Ep by the 0^{th} order equivalent component of the imaging light flux Sa to be an isotropic circle.

Here, in the embodiment, the circular region APh having the opening shape of the aperture provided on the emission surface side of the MFE lens 108A described above in FIG. 7 is deformed into an ellipse region APh′ with the X′ direction as the long axis and the Y′ direction as the short axis, as shown in FIG. 12. FIG. 12 is a schematic diagram of the MFE lens 108A of the optical integrator 108 when seen from the emission surface side, like FIG. 7. The ellipse region APh′ is obtained by rotating the oval shape CL3 of the light source image Ips formed in the pupil Ep of the projection units PLU by 90 degrees in the X′Y′ plane. Further, the ellipse ratio (short axis dimension/long axis dimension) of the ellipse region APh′ is also set to costa, the same as the ratio of the oval shape CL3 shown in FIG. 10.

In this way, by making the effective overall shape (contour) of the surface light source (assembly of the point light sources SPF) formed on the emission surface side of the MFE lens 108A an oval shape, the intensity distribution of the 0^{th} order light equivalent component (the light source image Ips) of the imaging light flux Sa formed in the pupil Ep of the projection units PLU can be made circular, and the imaging characteristics (especially the edge contrast characteristics) can be made uniform regardless of the direction in which the edge of the pattern extends in the X′Y′ plane (XY plane).

### [Telecentric Error Upon Projection Exposure]

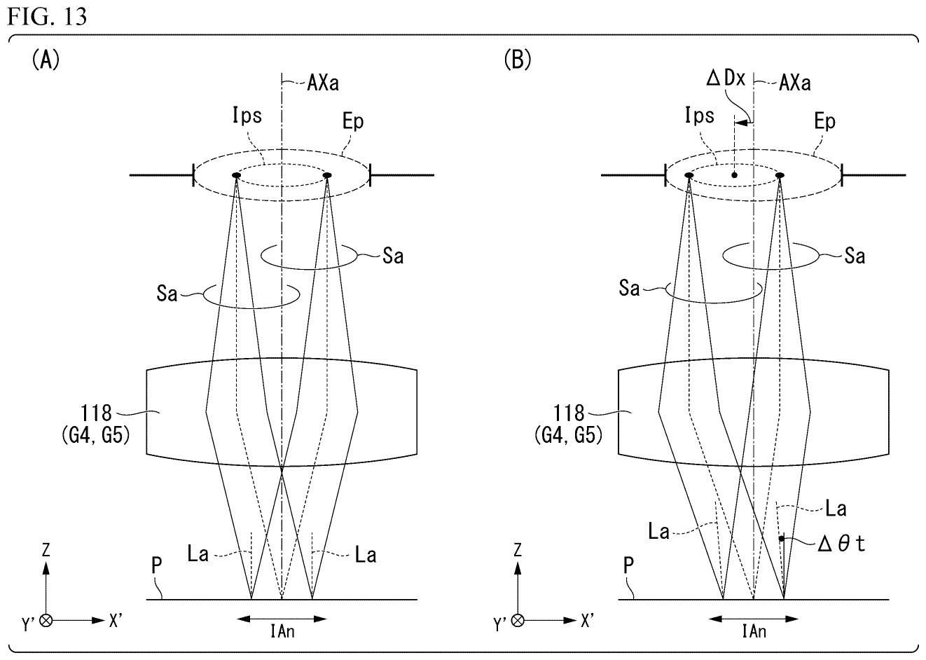

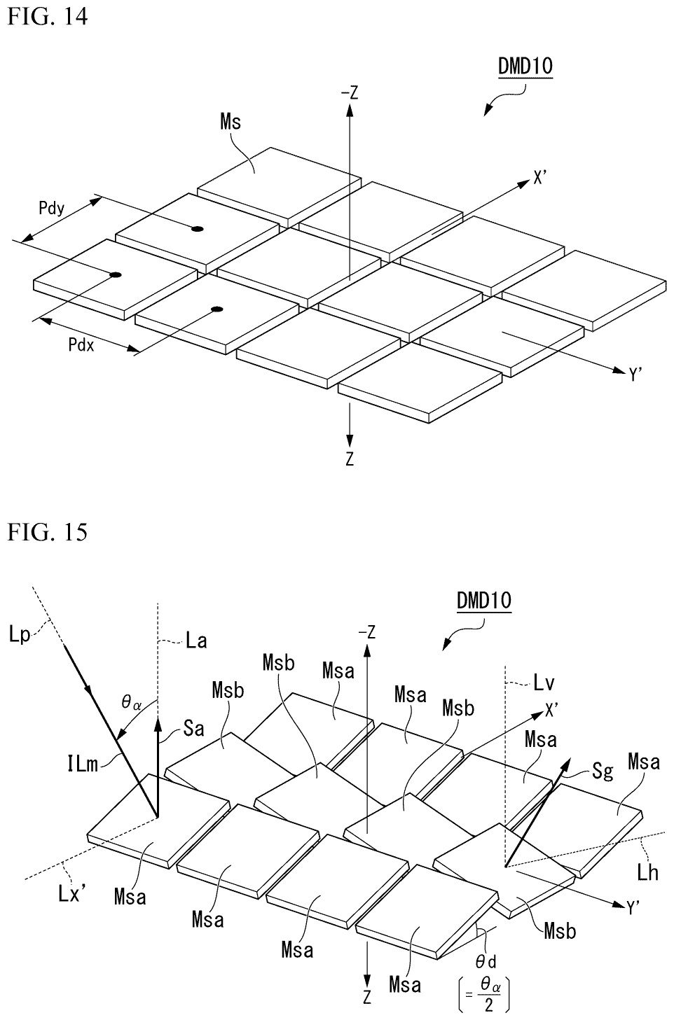

Next, while the telecentric error that can occur in the case of the exposure device EX using the DMD 10 has been described in this embodiment, one of the causes of telecentric error will be described in advance in brief with reference to FIG. 13. The part (A) of FIG. 13 and the part (B) of FIG. 13 are views schematically representing a behavior of the imaging light flux Sa in the optical path from the pupil Ep to the substrate P via second lens group 118 shown in FIG. 6. An orthogonal coordinate system X′Y′Z in the part (A) of FIG. 13 and the part (B) of FIG. 13 is the same as the coordinate system X′Y′Z in FIG. 6. For ease of description, herein, it is assumed that the entire mirror surface of the DMD 10 as a single plane mirror is tilted parallel to the inclined mirror 112 in FIG. 6 by the angle θg/2. In the part (A) of FIG. 13 and the part (B) of FIG. 13, the lens groups G4 and G5 are disposed along the optical axis AXa between the pupil Ep and the substrate P, and the oval light source image (surface light source image) Ips is formed in the pupil Ep as shown in FIG. 11. Further, the principal ray of the reflection light (imaging light flux) Sa that passes through a point on the peripheral portion in the X′ direction of the light source image (surface light source image) Ips and enters the lens groups G4 and G5 is referred to as La.

The part (A) of FIG. 13 shows the behavior of the reflection light (imaging light flux) Sa when the center (or center of gravity) of the light source image (surface light source image) Ips is positioned exactly at the center of the pupil Ep, the principal rays La of the reflection light (imaging light flux) Sa directed toward an arbitrary point in the projection areas IAn on the substrate P are all parallel to the optical axis AXa, and the imaging light flux projected into the projection areas IAn is in a telecentric state, i.e., the telecentric error is zero. On the other hand, the part (B) of FIG. 13 shows the behavior of the reflection light (imaging light flux) Sa when the center (or center of gravity) of the light source image (surface light source image) Ips is shifted laterally by ΔDx in the X′ direction from the center of the pupil Ep. In this case, the principal rays La of the reflection light (imaging light flux) Sa directed toward an arbitrary point within the projection areas IAn on the substrate P are all inclined by λθt with respect to the optical axis AXa. The tilt amount Δθt becomes a telecentric error, and as the tilt amount Δθt (i.e., the horizontal shift amount ΔDx) becomes larger than a predetermined allowable value, the imaging condition of the pattern image projected onto the projection areas IAn deteriorates.

### [Configuration of DMD]

As described above, while the DMD 10 used in this embodiment is of a roll & pitch drive type, its specific configuration will be described with reference to FIG. 14 and FIG. 15. FIG. 14 and FIG. 15 are enlarged perspective views showing some of the mirror surfaces of the DMD 10. Here too, the orthogonal coordinate system X′Y′Z is the same as the coordinate system X′Y′Z in FIG. 6 described above. FIG. 14 shows a state when the power supply to the driving circuit provided below each of the micro mirrors Ms of the DMD 10 is turned off. When the power supply is off, the reflecting surface of each micro mirror Ms is set parallel to the X′Y′ plane. Here, the array pitch of each micro mirror Ms in the X′ direction is Pdx (μm) and the array pitch in the Y′ direction is Pdy (μm), but in practice they are set to a square where Pdx=Pdy. In addition, the dimensions Lms in the X′ and Y′ directions of the micro mirror Ms are Lms =η·Pdx=η·Pdy when the effective dimension ratio is n (n<1.0), and n is set to about 0.8 to 0.9.

FIG. 15 shows an aspect in which the power supply to the driving circuit is turned on and the micro mirrors Msa in the ON-state and the micro mirrors Msb in the OFF-state are mixed. In the embodiment, the micro mirror Msa in the ON-state is driven to tilt at an angle θd (=θα/2) from the X′Y′ plane around a line parallel to the Y′ axis, and the micro mirror Msb in the OFF-state is driven to tilt at the angle θd (=θα/2) from the X′Y′ plane around a line parallel to the X′ axis. The illumination light ILm is irradiated to each of the micro mirrors Msa and Msb along a principal ray Lp parallel to the X′Z plane (parallel to the optical axis AXb shown in FIG. 6). Further, a line Lx′ in FIG. 15 is the projection of the principal ray Lp onto the X′Y′ plane and is parallel to the X′ axis.

The incidence angle θα of the illumination light ILm to the DMD 10 is the tilt angle with respect to the Z axis in the X′Z plane, and from the micro mirror Msa in the ON-state, which is tilted by the angle θα/2 in the X′ direction, reflection light (imaging light flux) Sa is generated that travels almost parallel to the Z axis in the −Z direction from a geometric optical point of view. Meanwhile, reflection light Sg reflected by the micro mirror Msb in the OFF-state occurs in the −Z direction, non-parallel to the Z axis, because the micro mirror Msb is tilted in the Y′ direction. In FIG. 15, if a line Lv is a line parallel to the Z axis (the optical axis AXa) and a line Lh is projection of the principal ray of the reflection light Sg onto the X′Y′ plane, the reflection light Sg travels in a tilted direction within the plane that includes the line Lv and the line Lh.

### [Imaging Condition by DMD]

In the projection exposure using the DMD 10, using the operation shown in FIG. 15, each of the number of micro mirrors Ms is rapidly switched between an ON-state tilt and an OFF-state tilt based on the pattern data (drawing data), and the substrate P is scanned in the X direction at a speed corresponding to the switching speed to perform pattern exposure. However, depending on the fineness, crowding, or periodicity of the projected pattern, the telecentric state (telecentricity) of the imaging light flux projected from the projection units PLU (the first lens group 116 and the second lens group 118) to the substrate P may change. This is because the mirror surface of the DMD 10 acts as a reflective diffraction grating (blazed diffraction grating) depending on the inclination state according to the pattern of the number of the micro mirrors Ms of the DMD 10.

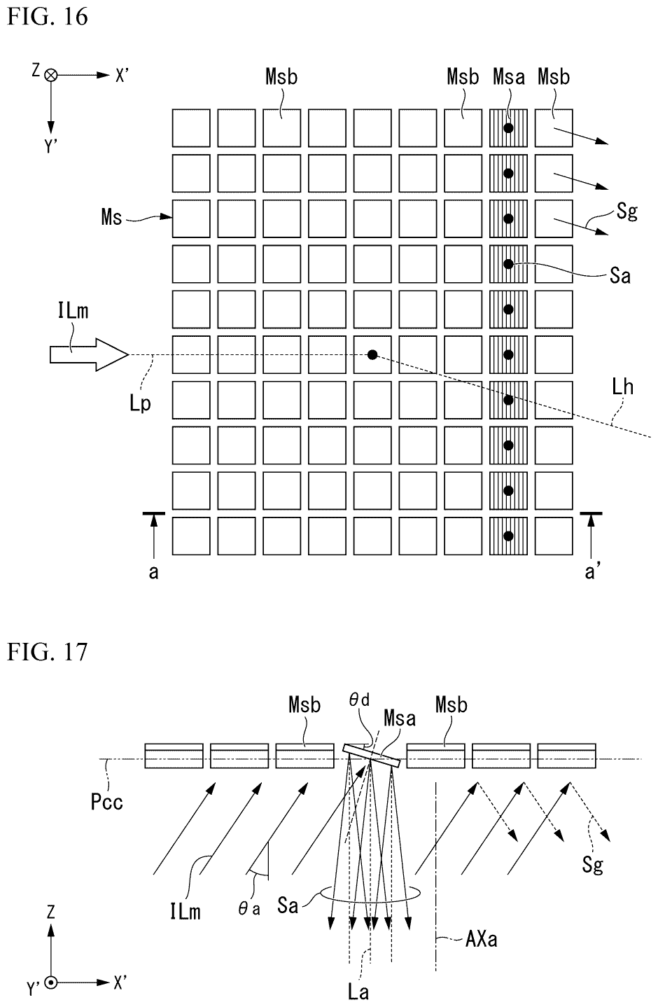

FIG. 16 is a view showing an arrow part of the mirror surface of the DMD 10 when seen in an X′Y′ plane, and FIG. 17 is a view showing the mirror surface of the DMD 10 along line a −a′ in FIG. 16 when seen in an X′Z plane. In FIG. 16, among the number of micro mirrors Ms, only the micro mirrors Ms aligned in the Y′ direction are the micro mirror Msa in the ON-state, and the other micro mirrors Ms are the micro mirrors Msb the OFF-state. The tilted state of the micro mirror Ms as shown in FIG. 16 appears when an isolated line pattern with a line width at the resolution limit (for example, about 1 μm) is projected. In the X′Y′ plane, the reflection light (imaging light flux) Sa from the micro mirror Msa in the ON-state is generated in the −Z direction parallel to the Z axis, and the reflection light Sg from the micro mirror Msb in the OFF-state is generated in the −Z direction but tilted toward a direction along a line Lh in FIG. 11.

In this case, as shown in FIG. 17, among the number of micro mirrors Ms aligned in the X′ direction, only one micro mirror Msa is in the ON-state, tilted by the angle θd (=θα/2) around a line parallel to the Y′ axis with respect to the neutral plane Pcc (a plane parallel to the X′Y′ plane that contains the center points of all the micro mirrors Ms). Accordingly, when viewed in the X′Z plane, the reflection light (imaging light flux) Sa generated from the micro mirror Msa in the ON-state becomes a simple regular reflection light that does not contain first-order or higher diffraction light, and its principal ray La is parallel to the optical axis AXa and enters the projection unit PLU. The reflection light Sg from the other micro mirrors Msb in the OFF-state does not enter the projection unit PLU. Further, when the micro mirror Msa in the ON-state is an isolated one in the X′ direction (or a row in the Y′ direction), the principal ray La of the reflection light (imaging light flux) Sa is parallel to the optical axis AXa by design, regardless of the wavelength λ of the illumination light ILm.

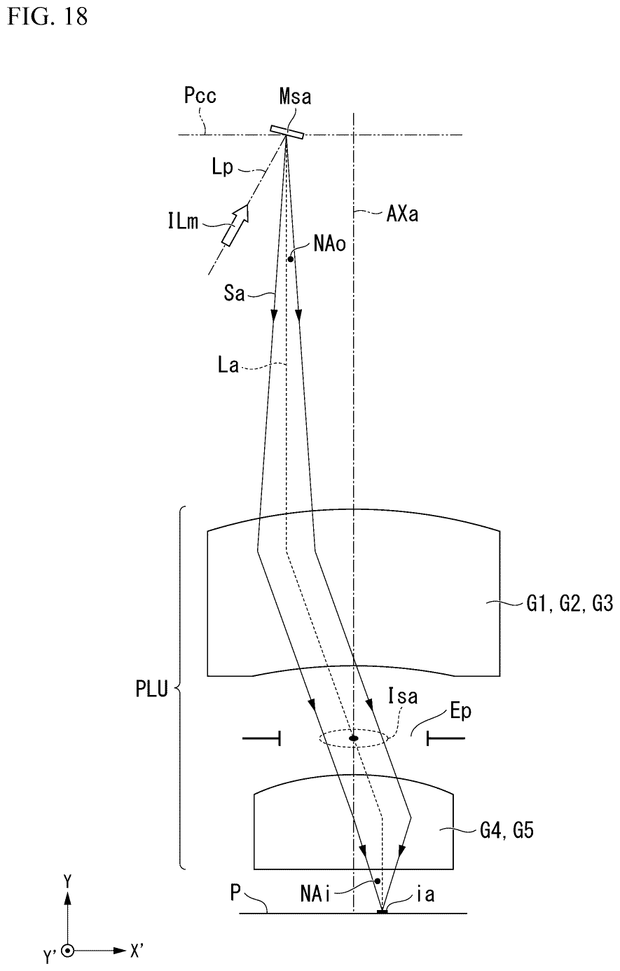

FIG. 18 is a view schematically representing an imaging condition by the projection unit PLU of the reflection light (imaging light flux) Sa from the isolated micro mirror Msa shown in FIG. 17 when seen in the X′Z plane. In FIG. 18, members having the same functions as those described in FIG. 6 above are designated by the same reference signs. Since the projection unit PLU (the lens groups G1 to G5) is a double-sided telecentric reduced projection system, if the principal ray La of the reflected light (imaging light flux) Sa from the isolated micro mirror Msa is parallel to the optical axis AXa, the principal ray La of the reflected light (imaging light flux) Sa imaged as the reduced image ia will also be parallel to the perpendicular line (the optical axis AXa) to the surface of the substrate P, and no telecentric error will occur. Further, the numerical aperture NAo of the reflection light (imaging light flux) Sa on the object surface side (the DMD 10) of the projection unit PLU shown in FIG. 18 is equivalent to the numerical aperture of the illumination light ILm.

As described in FIG. 11 (or FIG. 9) and the part (A) of FIG. 13 above, if the DMD 10 is a single large plane mirror tilted by the angle θα/2, the center (center of gravity) of the light source image (surface light source image) Ips formed in the pupil Ep of the projection units PLU passes through the optical axis AXa. Similarly, when only the regular reflection light Sa from the isolated micro mirror Msa on the mirror surface of the DMD 10 is incident on the projection unit PLU, the point image intensity distribution of a light flux Isa of the regular reflection light Sa at the position of the pupil Ep (Fourier transform surface) is represented as a sinc² function (point image intensity distribution of a square opening) centered on the optical axis AXa, because the reflecting surface of the micro mirror Ms is a tiny rectangle (square).

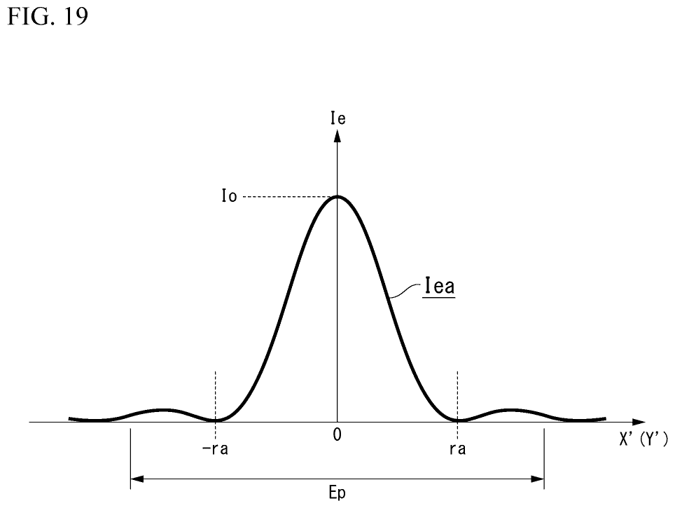

FIG. 19 is a graph schematically representing a theoretical point image intensity distribution Iea (distribution created with light flux from one point light source SPF shown in FIG. 7 and FIG. 8) of the light flux (here, 0^{th} order diffraction light) Isa in the pupil Ep by the reflection light Sa from a row of (or a single) micro mirrors Msa isolated in the X′ direction. In the graph of FIG. 19, a horizontal axis represents a coordinate position in the X′ (or Y′) direction with the optical axis AXa as the origin, and a vertical axis represents a light intensity Ie. The point image intensity distribution Iea is represented by the following Equation (1).

$$\begin{matrix}[ Math . 1 ] & \\ Ie = Io \cdot sin {c}^{2} ( {X}^{′} ) = Io \cdot {sin}^{2} ( {X}^{′} ) / {( {X}^{′} )}^{2} & ( 1 )\end{matrix}$$

In the Equation (1), Io represents a peak value of the light intensity Ie, and a position of a peak value Io due to the reflection light Sa from an isolated row (or single unit) of the micro mirrors Msa coincides with the origin 0 of the X′ (or Y′) direction, that is, the position of the optical axis AXa. In addition, as described in FIG. 12 above, when the shape of the surface light source formed on the emission surface side of the MFE lens 108A is adjusted to be like the ellipse region APh, a position±ra in the X′ (or Y′) direction of the first dark line where the light intensity Ie of the point image intensity distribution Iea first reaches its minimum value (0) from the origin 0 is π(≈3.1416) in Equation (1). The position±ra corresponds to a position of a value λ/Lms (or may be approximated by a value λ/Pdx divided by an array pitch Pdx of the micro mirror Ms) obtained by dividing the wavelength λ(nm) of the illumination light ILm by the dimension Lms (μm) of the single micro mirror Ms in the pupil Ep (Fourier transform surface) of the projection units PLU. Further, the actual intensity distribution in the pupil Ep is convolution integral (convolution operation) of the point image intensity distribution Iea over the range (o value) of the light source image Ips shown in FIG. 9, resulting in an approximately uniform intensity.

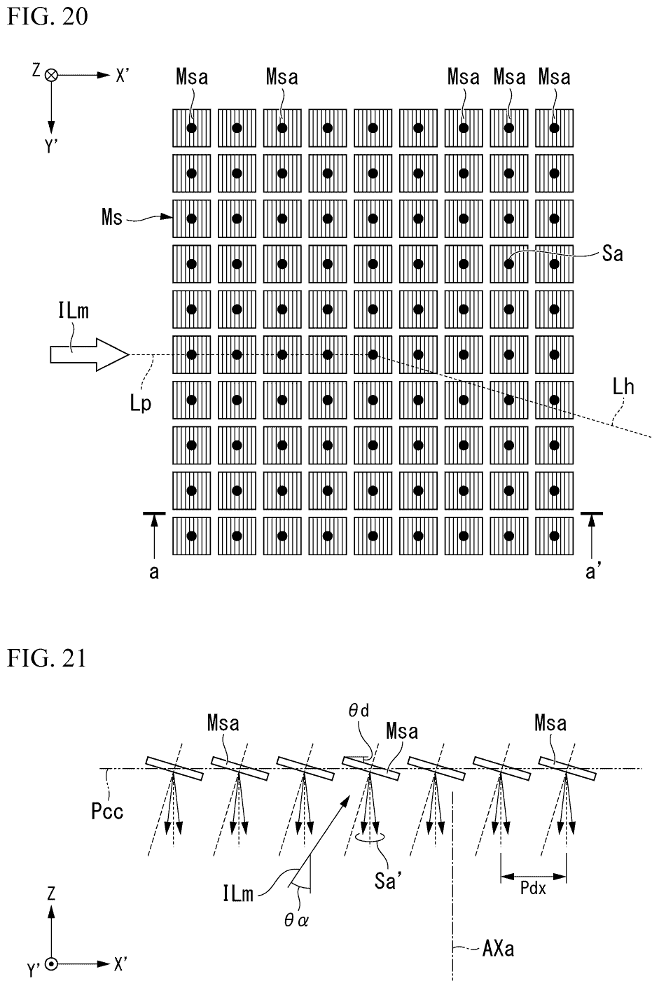

Next, the case where the width of the projected pattern in the X′ direction (X direction) is sufficiently large will be described with reference to FIG. 20 and FIG. 21. FIG. 20 is a view showing a part of the mirror surface of the DMD 10 when seen in the X′Y′ plane, and FIG. 21 is a view showing an arrow part of the mirror surface of the DMD 10 along line a −a′ in FIG. 20 when seen in the X′Z plane. FIG. 20 shows a case in which all the number of micro mirrors Ms shown in FIG. 16 above are the micro mirrors Msa in the ON-state. In FIG. 20, although only the layout of nine micro mirrors Ms in the X′ direction and ten in the Y′ direction is shown, there are cases where more than two adjacent micro mirrors Ms (or may be all of the micro mirrors Ms on the DMD 10) are in the ON-state.

As shown in FIG. 20 and FIG. 21, from the number of micro mirrors Msa in the ON-state that are adjacent to each other in the X′ direction, the reflection light Sa′ (the main diffraction light, which is the 0^{th} order light equivalent component) and other diffraction light are generated at a slight inclination from the optical axis AXa due to the diffraction effect. Considering the mirror surface of the DMD 10 in the state of FIG. 21 as a diffraction grating aligned in the X′ direction along the neutral plane Pcc with a pitch Pdx, the incidence angle θj of the diffraction light can be represented as the following Equation (2) or Equation (3), where j is the order (j=0, 1, 2, 3, . . . ), λ is the wavelength, and Ou is the incidence angle of the illumination light ILm.

$$\begin{matrix}[ Math . 2 ] & \\ sin θ j = j ( λ / Pdx ) - sin θ α & ( 2 )\end{matrix}$$

$$\begin{matrix}[ Math . 3 ] & \\ sin θ j = sin θ α - j ( λ / Pdx ) & ( 3 )\end{matrix}$$

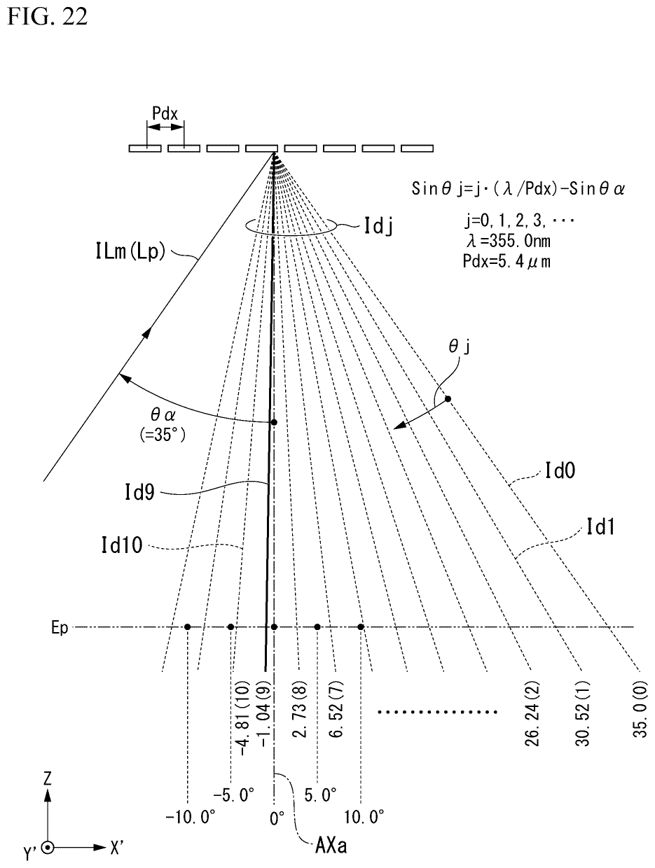

FIG. 22 is a graph representing the distribution of the angle θj of the diffraction light Idj calculated as an example, assuming that the incidence angle θα of the illumination light ILm (the tilt angle of the principal ray Lp of the illumination light ILm relative to the optical axis AXa) is 35.0°, the tilt angle θd of the micro mirror Msa in the ON-state is 17.5°, the pitch Pdx of the micro mirror Msa is 5.4 μm, and the wavelength λ is 355.0 nm. As shown in FIG. 22, since the incidence angle θα of the illumination light Ilm is 35°, the 0^{th} order diffraction light Id0 (j=θ) is tilted at +35° with respect to the optical axis AXa, and as the diffraction order increases, the angle θj with respect to the 0^{th} order diffraction light Id0 increases. The values shown in the bottom of FIG. 22 represent the order j in parentheses and the tilt angle of the diffraction light Idj of each order from the optical axis AXa.

In the case of the numerical condition in FIG. 22, the 9^{th} order diffraction light Id9, which has the smallest tilt angle from the optical axis AXa (approximately)−1.04°, becomes the main diffraction light (0^{th} order light equivalent component) of the imaging light flux Sa′. Accordingly, when the micro mirrors Ms of the DMD 10 are densely packed in the ON-state as shown in FIG. 20 and FIG. 21, the center of the intensity distribution of the imaging light flux (Sa′) within the pupil EP of the projection units PLU is decentered to a position shifted laterally by an angle θquivalent to −1.04° from the position of the optical axis AXa (corresponding to a horizontal shift amount ΔDx shown in the part (B) of FIG. 13 above). The actual distribution of the imaging light flux in the pupil Ep is calculated by performing a convolution integral (convolution operation) on the diffraction light distribution represented by Equation (2) or (3) by the sinc² function represented by Equation (1).

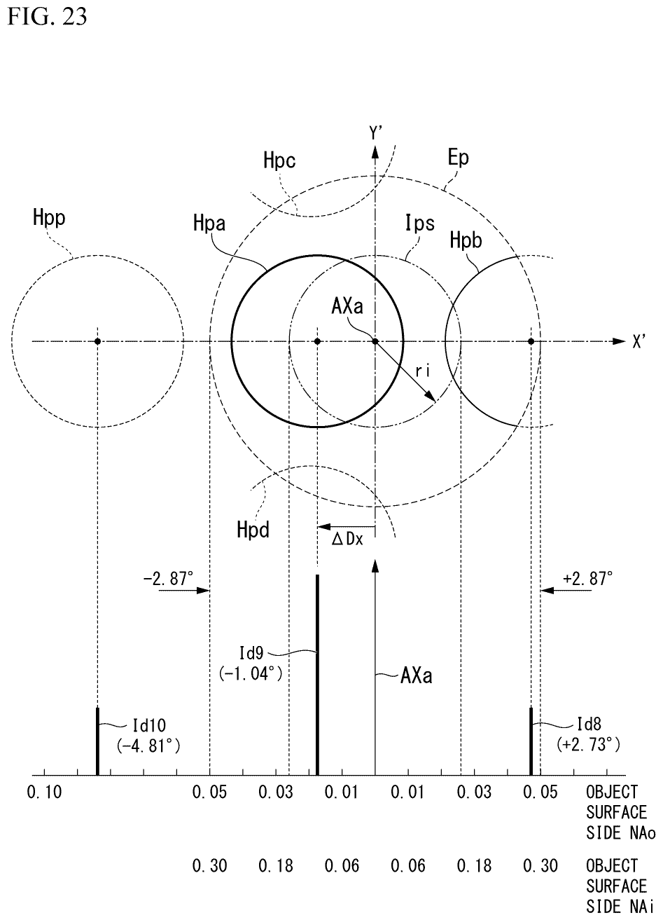

FIG. 23 is a view schematically representing an intensity distribution of the imaging light flux Sa′ in the pupil Ep in a generation state of the diffraction light as in FIG. 22. A horizontal axis of FIG. 23 represents a value obtained by converting the angle θj of the diffraction light Idj into the numerical aperture NAo on the side of the object surface (the DMD 10) and the numerical aperture NAi on the side of the image plane (the substrate P) when the projection magnification Mp of the projection units PLU is ⅙. In addition, it is assumed that the maximum image-plane-side numerical aperture NAi of the projection units PLU is 0.3 (the object-plane-side numerical aperture NAo=0.05). In this case, the resolution (minimum resolution line width) Rs is represented as Rs=k1 (λ/NAi) with a process constant k1 (0<k1≤1).

Accordingly, the resolution Rs is about 0.83 μm when the wavelength λ=355.0 nm and k1=0.7. The pitch Pdx (Pdy) of the micro mirror Ms is reduced by the projection magnification Mp=⅙ on the image plane (the substrate P) side to 0.9 μm. Accordingly, if the projection unit PLU has the image-plane-side numerical aperture NAi of 0.3 or more (the object-plane-side numerical aperture NAo is 0.05), a projection image of one of the micro mirrors Msa in the ON-state can be imaged with high contrast. However, in the projection exposure using the DMD 10, if the numerical apertures NAi and NAo are made larger than necessary, the imaging light flux Sa′ will contain many high order diffraction lights other than 9^{th} order diffraction light Id9, which is the main diffraction light, and this may degrade the image quality exposed to the substrate P.

In FIG. 23, since an angle θe from the optical axis AXa in the X′ direction of the numerical aperture NAo=0.05 on the object surface side that is the maximum diameter of the pupil Ep of the projection unit PLU is NAO=sinθe, θe≈±2.87°. As shown in FIG. 22 described above, the tilt angle−1.04° (accurately,)−1.037° of the 9^{th} order diffraction light Id9 is about 0.018 when converted into the object-plane-side numerical aperture NAo, and the intensity distribution Hpa of the imaging light flux Sa′ (0^{th} order light equivalent component) in the pupil Ep is displaced by a shift amount ΔDx from an original position of the light source image Ips (radius ri) in the X′ direction. Further, a part of the intensity distribution Hpb due to the 8^{th} order diffraction light Id8 appears around the +X′ direction in the pupil Ep, but its peak intensity is low. Further, since the tilt angle from the optical axis AXa of the 10^{th} order diffraction light Id10 on the object surface side is large at 4.81°, its intensity distribution is distributed outside the pupil Ep and does not pass through the projection units PLU. Further, the intensity distributions Hpa and Hpb in FIG. 23 become approximately circular by making the surface light source formed on the emission surface side of the MFE 108A of the illumination unit ILU into an ellipse region APh′, as described in FIG. 12 above.

In addition, since the micro mirrors Ms of the DMD 10 are also laid out with the pitch Pdy (=5.4 μm) in the Y′ direction, diffraction light is generated with low illuminance in the Y′ direction according to the pitch Pdy, resulting in weak intensity distributions Hpc and Hpd. Depending on the size of the numerical aperture NAo (NAi) of the projection units PLU, a portion of the intensity distributions Hpc and Hpd may fall within the pupil Ep. For this reason, by appropriately setting the relationship between the numerical aperture NAo (NAi) of the projection units PLU and the size (radius ri) of the light source image Ips, the intensity distributions Hpc and Hpd can be prevented from falling within the pupil Ep.

As described in the part of (B) of FIG. 13 above, the telecentric error Δθt on the image plane side caused by the shift amount ΔDx of the center of the intensity distribution Hpa is Δθt=−6.22° (≈−1.037°/the projection magnification Mp) under the conditions shown in FIG. 22 and FIG. 23. In this way, during exposure to a large pattern in which many of the micro mirrors Ms in the DMD 10 are densely in the ON-state, the principal ray of the imaging light flux Sa′ inclined on the substrate P will be tilted by more than 6° with respect to the optical axis AXa. This telecentric error Δθt can also be a factor in reducing the imaging quality (contrast characteristics, distortion characteristics, symmetry, etc.) of the projection image.

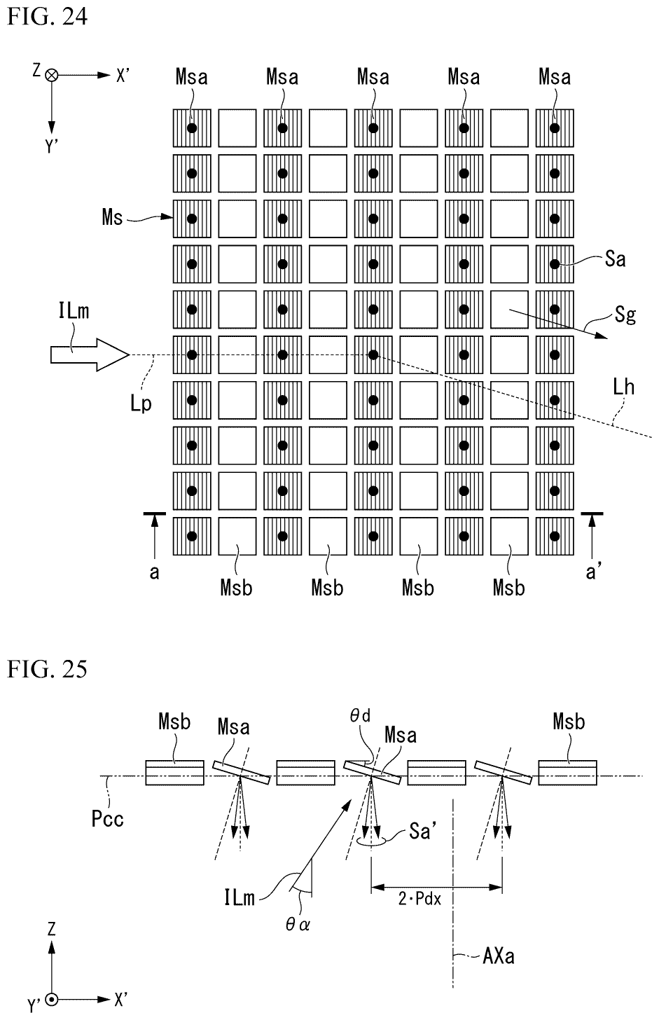

Next, the case where the projected pattern is a line and space pattern with a constant pitch in the X′ direction (X direction) will be described with reference to FIG. 24 and FIG. 25. FIG. 24 is a view showing a part of the mirror surface of the DMD 10 when seen in the X′Y′ plane, and FIG. 25 is a view showing the mirror surface of the DMD 10 along line a −a′ in FIG. 24 when seen in the X′Z plane. FIG. 24 shows a case where, among the number of micro mirrors Ms shown in FIG. 16 above, the odd number of the micro mirrors Ms aligned in the X′ direction are the micro mirrors Msa in the ON-state, and the even number are the micro mirrors Msb in the OFF-state. The odd number of micro mirrors Ms in the X′ direction are all in the ON-state in one row aligned in the Y′ direction, and the even number of micro mirrors Ms are all in the OFF-state in one row aligned in the Y′ direction.

As shown in FIG. 25, when the micro mirrors Msa in the ON-state are laid out alternately in the X′ direction, the angle θj of the diffraction light generated from the DMD 10 is represented by the following Equation (4) or Equation (5), which is similar to the previous Equation (2) or Equation (3), by considering the mirror surface of the DMD 10 as a diffraction grating arranged in the X′ direction along the neutral plane Pcc with a pitch 2·Pdx.

$$\begin{matrix}[ Math . 4 ] & \\ sin θ j = j ( λ / 2 Pdx ) - sin θ α & ( 4 )\end{matrix}$$

$$\begin{matrix}[ Math . 5 ] & \\ sin θ j = sin θ α - j ( λ / 2 Pdx ) & ( 5 )\end{matrix}$$

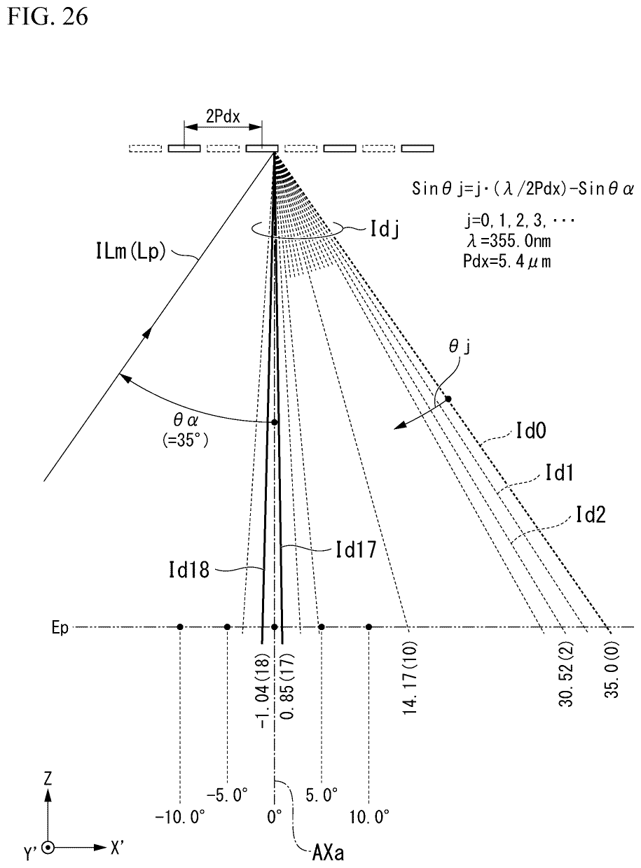

FIG. 26 is a graph representing the distribution of the angle θj of the diffraction light Idj, calculated as in FIG. 22, assuming that the incidence angle θα of the illumination light ILm (the tilt angle of the principal ray Lp of the illumination light ILm relative to the optical axis AXa) is 35.0°, the tilt angle θd of the micro mirror Msa in the ON-state is 17.5°, the pitch 2Pdx of the micro mirrors Msa is 10.8 μm, and the wavelength λ is 355.0 nm. As shown in FIG. 26, since the incidence angle θ a of the illumination light ILm is 35°, the 0^{th} order diffraction light Id0 (j=θ) is inclined at +35° with respect to the optical axis AXa, and as the diffraction order increases, the angle θj with respect to the 0^{th} order diffraction light Id0 increases. The numerical values shown in the bottom of FIG. 26 represent the order j in parentheses and the tilt angle of the diffraction light Idj from the optical axis AXa for each order.

In the case of the numerical condition in FIG. 26, the 17^{th} order diffraction light Id17, which has the smallest tilt angle of approximately 0.85° from the optical axis AXa, is the main diffraction light. Further, the 18^{th} order diffraction light Id18 is also generated with a tilt angle of −1.04° from the optical axis AXa. Accordingly, when the micro mirror Ms of the DMD 10 is in the ON-state with the finest line and space shape as shown in FIG. 24 and FIG. 25, the center of the intensity distribution (main diffraction light) of the imaging light flux Sa′ within the pupil EP of the projection unit PLU is decentered to a position shifted laterally by an angle θquivalent to 0.85° or −1.04° from the position of the optical axis AXa. The actual distribution of the imaging light flux Sa′ in the pupil Ep is calculated by performing a convolution integral (convolution operation) on the diffraction light distribution represented by Equation (4) or Equation (5) using the sinc² function represented by Equation (1).

Even in the case of FIG. 26, as in FIG. 23 described above, the intensity distribution of the 17^{th} order diffraction light Id17, corresponding to a tilt angle of 0.85°, and the intensity distribution of the 18^{th} order diffraction light Id18, corresponding to a tilt angle of −1.04°, appear in the plane of the pupil Ep displaced overall in the X′ direction from the original position of the light source image Ips (radius ri). In the case of the diffraction light distribution shown in FIG. 26, one of the intensity distributions corresponding to the 17^{th} order diffraction light Id17 and the 18^{th} order diffraction light Id18 has a higher intensity than other, so the telecentric error Δθt on the image plane side caused by the shift in these intensity distributions is generally within a range of Δθt=5.1° and Δθt=−6.22°.

This range is slightly different from the telecentric error Δθt=−6.22°, which is the direction in which the 9^{th} order diffraction light Id9 (see FIG. 22) occurring when the number of micro mirrors Ms are adjacent to each other and the micro mirror Msa is in the ON-state, as shown in FIGS. 20 and 21 described above. Further, this is significantly different from the telecentric error Δθt=θ° when one row (or a single one) of the number of micro mirrors Ms is isolated and the micro mirror Msa is in the ON-state as shown in FIGS. 16 and 17 described above. Further, the actual pattern image projected onto the substrate P by the projection units PLU is formed by the interference of the reflection light Sa′, including the diffraction light from the DMD 10, which is captured within the projection units PLU. Further, Equation (4) or Equation (5) can specify the generation state of diffraction light in a line and space pattern whose array pitch or line width is n times Pdx (5.4 μm) by the following Equation (6) or Equation (7), where n is a real number.

$$\begin{matrix}[ Math . 6 ] & \\ sin θ j = j ( λ / ( n \cdot Pdx ) ) - sin θα & ( 6 )\end{matrix}$$

$$\begin{matrix}[ Math . 7 ] & \\ sin θ j = sin θα - j ( λ / ( n \cdot Pdx ) ) & ( 7 )\end{matrix}$$

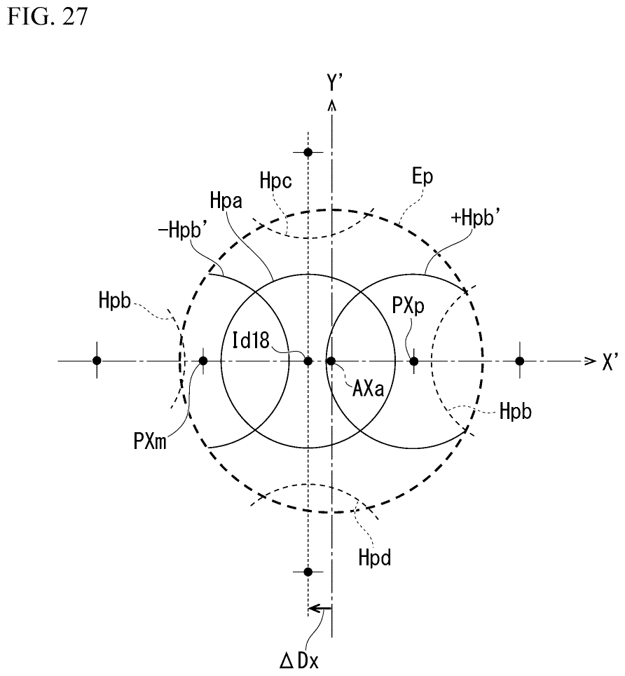

FIG. 27 is a view schematically representing a distribution in the pupil Ep of the projection units PLU by the reflection light (diffraction light) from the DMD 10 shown in FIG. 26, corresponding to FIG. 23 described above. In the case of FIG. 27 also, as described in FIG. 12 above, the contour of the surface light source formed on the emission surface side of the MFE 108A is made to have an ellipse shape APh′, so that the intensity distribution of each of the diffraction light fluxes as the imaging light flux

Sa′ formed in the pupil Ep of the projection units PLU is a circle. In addition, in FIG. 27, the intensity due to the 18^{th} order diffraction light Id18 shown in FIG. 26 is assumed to be the largest, and in the case of the line and space pattern projection as in FIGS. 24 and 25, the 18^{th} order diffraction light Id18 is taken as the intensity distribution Hpa of the 0^{th} order light equivalent component. The intensity distribution Hpa is decentered by ΔDx in the −X′ direction, corresponding to the angle−1.04° from the optical axis AXa of the 18^{th} order diffraction light Id18, resulting in the telecentric error Δθt.

As described in FIG. 23 above, within the plane of the pupil Ep, there are intensity distributions Hpb, Hpc and Hpd of the diffraction light components caused by the pitches Pdx and Pdy of the layout of the micro mirrors Ms of the DMD 10 in the X′ and Y′ directions, but their intensities are sufficiently small compared to the intensity distribution Hpa. Further, in the line and space pattern (line width in the X′ direction is Pdx with a pitch of 2Pdx) created by the micro mirror Ms of the DMD 10, the intensity distribution±Hpb′ of the +1^{st} order light equivalent components (17^{th} order diffraction light Id17 and 19^{th} order diffraction light Id19) generated by the diffraction effect appears on both sides of the intensity distribution Hpa in the X′ direction. The center point PXp of the intensity distribution±Hpb′ of the +1^{st} order light equivalent component is located almost halfway between the center point (Id18) of the intensity distribution Hpa of the 0^{th} order light equivalent component and the center point of the intensity distribution Hpb in the +X′ direction. Similarly, the center point PXm of the intensity distribution-Hpb′ of the −1^{th} order light equivalent component is located almost halfway between the center point (Id18) of the intensity distribution Hpa of the 0^{th} order light equivalent component and the center point of the intensity distribution Hpb in the −X′ direction.

In addition, in FIG. 27, as shown in FIG. 24, the intensity distribution of the imaging light flux Sa′ (diffraction light flux) in the pupil Ep is shown for a line and space pattern with a pitch 2Pdx in the X′ direction. On the other hand, in the case of the line and space pattern with pitch 2Pdy (Pdy=Pdx) in the Y′ direction, when the center point (Id18) of the intensity distribution Hpa of the 0^{th} order light equivalent component is offset by ΔDx in the −X′ direction, the intensity distribution±Hpb′ of the +1^{st} order light equivalent component appears on both sides of the intensity distribution Hpa in the Y′ direction.

In this way, even if many of the micro mirrors Ms of the DMD 10 are in the ON-state in the line and space pattern, the principal ray of the imaging light flux onto the substrate P may be significantly tilted with respect to the optical axis AXa, which may significantly degrade the imaging quality (contrast characteristics, distortion characteristics, and the like) of the projection image.

[Telecentric adjustment mechanism]

As Described Above, when the Micro Mirrors Msa, which are Turned on according to the pattern to be exposed to the substrate P, among the number of micro mirrors Ms in the DMD 10, are densely arranged in the X′ direction and Y′ direction, or are arranged with periodicity in the X′ direction (or Y′ direction), a telecentric error (angle change) λθt occurs in the imaging light flux Sa′ projected from the projection units PLU, although the degree of error may vary. Each of the number of micro mirrors Ms of the DMD 10 is switched between the on and OFF-states at a response speed of about 10 KHz, so the pattern image generated by the DMD 10 also changes rapidly in response to the drawing data. For this reason, while scanning and exposing a pattern such as a display panel, the pattern image projected from each of the modules MUn (n=1 to 27) instantaneously changes shape to an isolated line or dot pattern, a line and space pattern, or a large land pattern, and the like.

A typical television display panel (liquid crystal type, organic EL type) is constituted by an image display region arranged in a matrix on the substrate P so that pixel sections of approximately 200 to 300 μm square have a predetermined aspect ratio such as 2:1 or 16:9, and peripheral circuit parts (pull-out wiring, connection pads, and the like) arranged around the region. Within each pixel section, a thin film transistor (TFT) for switching or current driving is formed, but the size (line width) of the TFT patterns (patterns of a gate layer, a drain/source layer, a semiconductor layer, and the like), a gate wiring or a driving wiring are much smaller than array pitch (200 to 300 μm) of the pixel section. For this reason, when exposing a pattern within the image display region, the pattern image projected from the DMD 10 is almost isolated, so the telecentric error Δθt does not occur.

However, depending on the configuration of the lighting driving circuit (TFT circuit) for each pixel section, line-and-space wiring may be formed in the X or Y direction with a pitch smaller than array pitch of the pixel section. In this case, when exposing a pattern within the image display region, the pattern image projected from the DMD 10 has periodicity. For this reason, depending on the degree of periodicity, the telecentric error Δθt occurs. In addition, when exposing an image display region, a rectangular pattern may be uniformly (tiled) exposed, with the pattern being approximately the same size as the pixel section, or at least half the area of the pixel section. In this case, during exposure of the image display region, more than half of the number of micro mirrors Ms in the DMD 10 are densely in the ON-state. For this reason, a relatively large telecentric error Δθt can occur.

The occurrence state of the telecentric error Δθt can be estimated before exposure based on the drawing data of the pattern for the display panel exposed to each of the plurality of modules MUn (n=1 to 27). In the embodiment, the position and posture of each of several optical members in the modules MUn are made finely adjustable, and among these optical members, adjustable optical members can be selected according to the size of the estimated telecentric error Δθt to correct the telecentric error Δθτ.

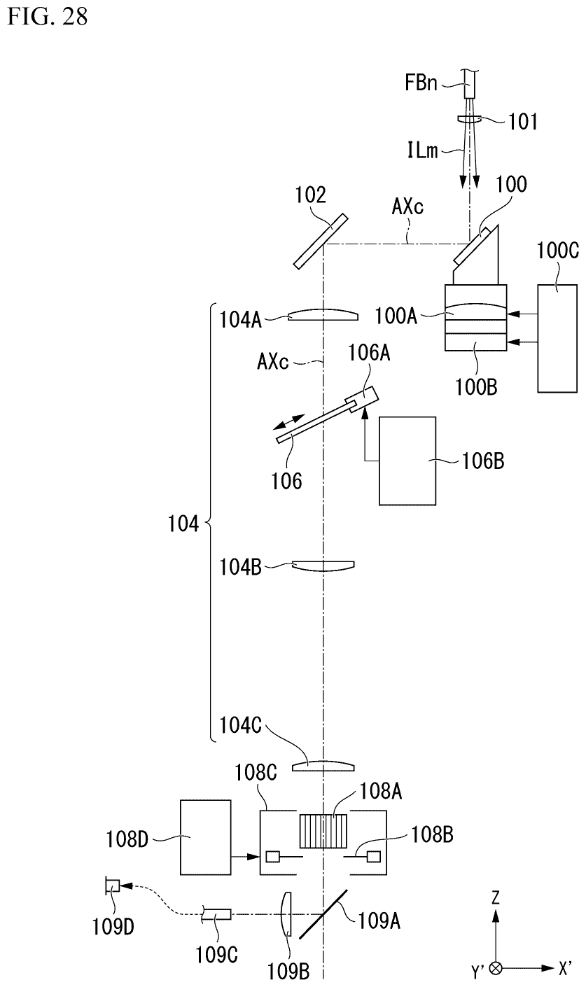

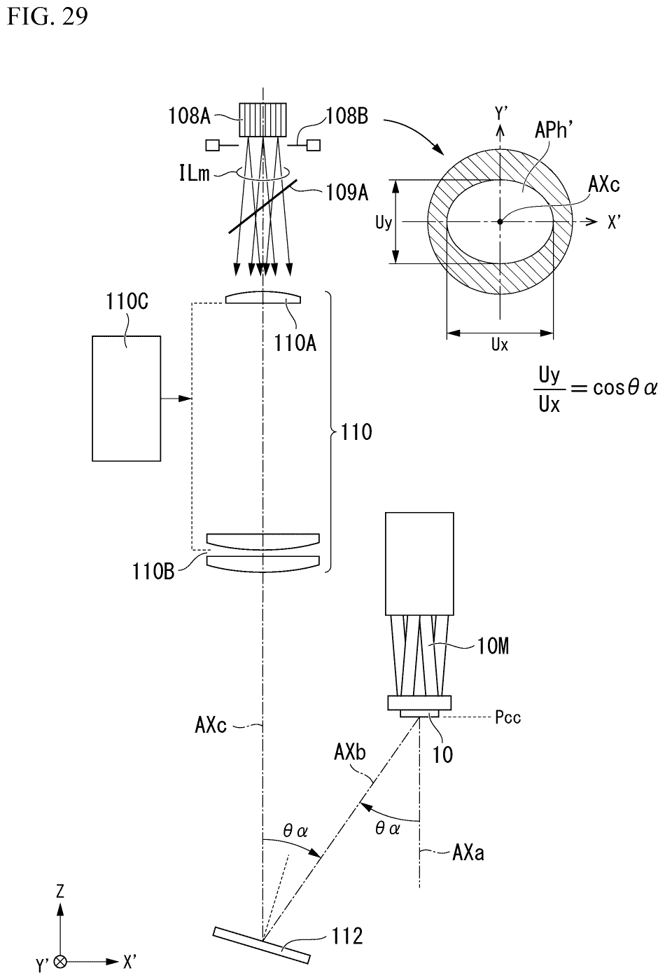

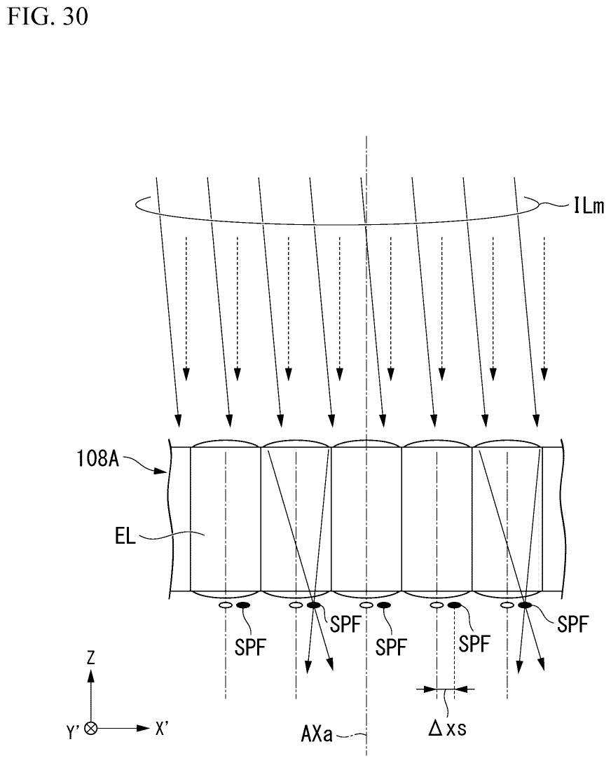

FIG. 28 shows a specific configuration of an optical path from the optical fiber bundles FBn to the MFE lens 108A in the illumination unit ILU of the modules MUn shown in FIG. 4 or FIG. 6, and FIG. 29 shows a specific configuration of an optical path from the MFE lens 108A of the illumination unit ILU to the DMD 10. In FIG. 28 and FIG. 29, the orthogonal coordinate system X′Y′Z is set to the same as the coordinate system X′Y′Z in FIG. 4 (FIG. 6), and members with the same functions as those shown in FIG. 4 are designated by the same reference signs.

While not shown in FIG. 4, in FIG. 28, a contact lens 101 is disposed immediately after the emission end of the optical fiber bundles FBn to suppress the spread of the illumination light ILm from the emission end. The optical axis of the contact lens 101 is set parallel to the Z axis, and the illumination light ILm traveling from the optical fiber bundles FBn with a predetermined numerical aperture is reflected by the mirror 100, travels parallel to the X′ axis, and is reflected by the mirror 102 in the −Z direction. The input lens system 104, located in the optical path from the mirror 102 to the MFE lens 108A, is constituted by three lens groups 104A, 104B and 104C spaced apart from one another along the optical axis AXc.

The illuminance adjustment filter 106 is supported by a holding member 106A translated by a driving mechanism 106B, and disposed between the lens group 104A and the lens group 104B. An example of the illuminance adjustment filter 106, as disclosed in Japanese Patent Laid-open Publication No. H11-195587, is a filter in which a pattern of fine light-blocking dots is formed on a transparent plate such as quartz with gradually changing density, or in which multiple rows of elongated light-blocking wedge patterns are formed, and by translating the quartz plate, the transmittance of the illumination light ILm can be continuously changed within a specified range.

A first telecentric adjustment mechanism is constituted by a tilt mechanism 100A configured to finely adjust a two-dimensional tile (a rotation angle around the X′ axis and the Y′ axis) of the mirror 100 that reflects the illumination light ILm from the optical fiber bundles FBn, a translation mechanism 100B configured to two-dimensionally finely move the mirror 100 in the X′Y′ plane perpendicular to the optical axis AXc, and a driving unit 100C constituted by a micro head, a piezo actuator, or the like, configured to individually drive each of the tilt mechanism 100A and the translation mechanism 100B.

By adjusting the inclination of the mirror 100, the central ray (principal ray) of the illumination light ILm entering the input lens system 104 can be adjusted to be coaxial with the optical axis AXc. In addition, since the emission end of the fiber bundles FBn is positioned at the front focus position of the input lens system 104, when the mirror 100 is moved slightly in the X′ direction, the central ray (principal ray) of the illumination light ILm entering the input lens system 104 shifts parallel to the X′ direction relative to the optical axis AXc. Accordingly, the central ray (principal ray) of the illumination light ILm emitting from the input lens system 104 travels at a slight inclination with respect to the optical axis AXc. Accordingly, the illumination light ILm entering the MFE lens 108A is slightly tilted overall in the X′Z plane. FIG. 30 is an exaggerated view showing a state of the point light source SPF formed on the emission surface side of the MFE lens 108A when the illumination light ILm entering the MFE lens 108A is inclined in the X′Z plane. When the central ray (principal ray) of the illumination light ILm is parallel to the optical axis AXc, the point light source SPF focused on the emission surface side of each lens element EL of the MFE lens 108A is located at the center in the X′ direction, as shown by a white circle in FIG. 30. When the illumination light ILm is tilted with respect to the optical axis AXc in the X′Z plane, the point light source SPF focused on each emission surface side of the lens element EL is decentered by Δxs in the X′ direction from the center position, as shown by a black circle in FIG. 30. In this case, as described in FIG. 7 to FIG. 9 above, the surface light source formed on the emission surface side of the MFE lens 108A by the assembly of the number of point light sources SPF is entirely shifted laterally in the X′ direction by Δxs. Since the cross-sectional dimension in the X′Y′ plane of each lens element EL of the MFE lens 108A is small, the eccentricity Δxs in the X′ direction as a surface light source is also small.

As shown in FIG. 28, an aperture 108B having the opening shape of the ellipse region APh′ shown in FIG. 12 is provided on the emission surface side of the MFE lens 108A, and the MFE lens 108A and the aperture 108B are integrally attached to a holding part 108C. The holding part 108C (the MFE 108A) is set up so that its position in the X′Y′ plane can be finely adjusted by a micromotion mechanism 108D using a micro head, a piezo motor, or the like. In the embodiment, the micromotion mechanism 108D, which finely moves the MFE lens 108A two-dimensionally in the X′Y′ plane, functions as a second telecentric adjustment mechanism. As shown in FIG. 29, the aperture 108B has an opening of the ellipse region APh′ with its long axis in the X′ direction and its short axis in the Y′ direction. If a long axis dimension of the ellipse region APh′ is Ux and a short axis dimension is Uy, the ellipse ratio Uy/Ux depends on a cosine value of the incidence angle θα of the illumination light ILm to the DMD 10 (twice the tilt angle θd of the micro mirror Msa in the ON-state), and is set to the relationship Uy/Ux=cosθα.

Immediately after the MFE lens 108A (the aperture 108B), a plate type beam splitter 109λ is provided, which is inclined at about 45° with respect to the optical axis AXc. The beam splitter 109A transmits most of the light intensity of the illumination light ILm from the MFE lens 108A and reflects the remaining light intensity (for example, a few percent) toward a condensing lens 109B. Some of the illumination light ILm condensed by the condensing lens 109B is guided by an optical fiber bundle 109C to a photoelectric element 109D. The photoelectric element 109D is used as an integrated sensor (accumulation monitor) that monitors the intensity of the illumination light ILm and measures the exposure amount of the imaging light flux projected onto the substrate P.

As shown in FIG. 29, the illumination light ILm from the surface light source (assembly of the point light sources SPF) on the emission surface side of the MFE lens 108A passes through the beam splitter 109A and enters the condenser lens system 110. The condenser lens system 110 is constituted by a front group lens system 110A and a rear group lens system 110B arranged with a gap between them, and its two-dimensional position in the X′Y′ plane can be finely adjusted by a micromotion mechanism 110C using a micro head, a piezo motor, or the like. That is, the micromotion mechanism 110C allows for decentering adjustment of the condenser lens system 110. In the embodiment, the micromotion mechanism 110C configured to two-dimensionally and finely move the condenser lens system 110 in the X′Y′ plane functions as a third telecentric adjustment mechanism. Further, the first telecentric adjustment mechanism, the second telecentric adjustment mechanism, and the third telecentric adjustment mechanism all adjust the relative positional relation regarding the decentering direction between the surface light source generated on the emission surface side of the MFE lens 108A (or the surface light source limited within the opening of the ellipse region APh′ of the aperture 108B) and the condenser lens system 110.

A front focus of the condenser lens system 110 is set to the position of the surface light source (assembly of the point light sources SPF) on the emission surface side of the MFE lens 108A, and the illumination light ILm, which travels in a telecentric state from the condenser lens system 110 via inclined mirror 112, provides Koehler illumination to the DMD 10. As described above in FIG. 30, when the surface light source formed by the assembly of the number of point light sources SPF formed on the emission surface side of the MFE lens 108A is shifted laterally in the X′ direction by Δxs as a whole, the principal ray (central ray) of the illumination light ILm irradiated to the DMD 10 becomes slightly tilted with respect to the optical axis AXb in FIG. 29. That is, by intentionally adding the telecentric error to the illumination light ILm using the first telecentric adjustment mechanism, the incidence angle θα of the illumination light ILm in FIGS. 6, 17, 21, and 25 described above can be slightly changed from the initial setting angle) (35.0° in the X′Z plane.

In addition, when the MFE lens 108A and the variable aperture 108B are displaced together in the X′ direction in the X′Y′ plane by the micromotion mechanism 108D as the second telecentric adjustment mechanism shown in FIG. 28, the opening of the aperture 108B (the ellipse region APh′ in FIG. 29) is decentered with respect to the optical axis AXc. Accordingly, the surface light source formed within the ellipse region APh′ also shifts overall in the X′ direction. Even in this case, the principal ray (central ray) of the illumination light ILm irradiated to the DMD 10 can be tilted in the X′Z plane with respect to the optical axis AXb in FIG. 29, i.e., the incidence angle θα of the illumination light ILm to the DMD 10 can be changed from the initial setting angle) (35.0° in the X′Z plane. Further, the incidence angle θα can be similarly changed by configuring the aperture 108B to move slightly alone in the X′Y′ plane using the micromotion mechanism 108D.

In this way, in order to displace the MFE lens 108A and the aperture 108B together by a relatively large amount, it is necessary to widen the light flux width (diameter of the irradiation range) of the illumination light ILm irradiated from the input lens system 104 to the MFE lens 108A. Further, it is also effective to provide a shift mechanism that shifts the illumination light ILm irradiated to the MFE lens 108A laterally within the X′Y′ plane in conjunction with the amount of displacement. The shift mechanism can be constituted by a mechanism that tilts the direction of the emission end of the optical fiber bundles FBn, or a mechanism that tilts a parallel plane plate (quartz plate) placed in front of the MFE lens 108A.

Both the first telecentric adjustment mechanism (the driving unit 100C or the like) and the second telecentric adjustment mechanism (the micromotion mechanism 108D or the like) can adjust the incidence angle θα of the illumination light ILm to the DMD 10, but in terms of the amount of adjustment, the first telecentric adjustment mechanism can be used for fine adjustment, while the second telecentric adjustment mechanism can be used for coarse adjustment. In actual adjustment, it is possible to select whether to use both the first telecentric adjustment mechanism and the second telecentric adjustment mechanism or just one of them, depending on the shape of the pattern to be projected and exposed (the amount of the telecentric error Δθt and the correction amount).

Further, the micromotion mechanism 110C, which serves as a third telecentric adjustment mechanism to decenter the condenser lens system 110 in the X′Y′ plane, has the same effect as the second telecentric adjustment mechanism which decenters the position of the surface light source relative to the MFE lens 108A and the aperture 108B. However, when the condenser lens system 110 is relatively decentered in the X′ direction (or Y′ direction), the irradiation region of the illumination light ILm projected onto the DMD 10 also shifts laterally, so the irradiation region is set larger than entire size of the mirror surface of the DMD 10 to take this lateral shift into account. The third telecentric adjustment mechanism by the micromotion mechanism 110C can also be used for coarse adjustment, just like the second telecentric adjustment mechanism.

### [Wavelength Dependency of Telecentric Error]

The telecentric error Δθt described above varies depending on the wavelength λ, as is clear from Equation (2) to Equation (5) above. For example, in the state of FIG. 20 and FIG. 21 represented by Equation (2), in order to make the telecentric error Δθt on the image plane side zero, it is necessary to set the wavelength λ so that the tilt angle of the 9^{th} order diffraction light Id9 from the optical axis AXa shown in FIG. 22 and FIG. 23, which is −1.04° (−1.037° to be exact), becomes zero.

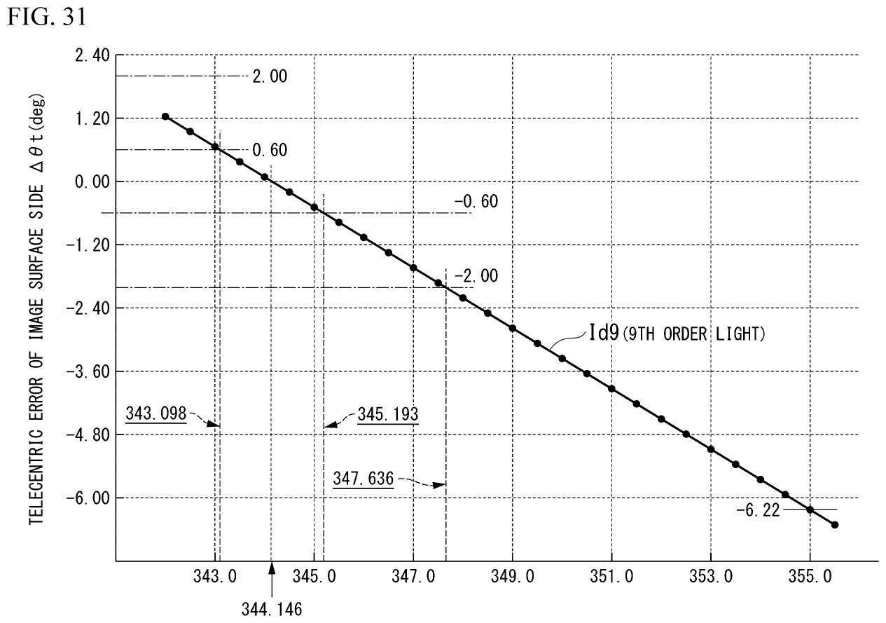

FIG. 31 is a graph in which a relationship between the center wavelength λ and the telecentric error Δθt is obtained based on the above-mentioned Equation (2), a horizontal axis represents the center wavelength λ(nm), and a vertical axis represents the telecentric error Δθt (deg) on the image plane side. Provided that the pitch Pdx (Pdy) of the micro mirror Ms of the DMD 10 is 5.4 μm, the tilt angle θd of the micro mirror Ms is 17.5°, and the incidence angle θα of the illumination light ILm is 35°, when the micro mirrors Ms are densely turned on as shown in FIGS. 20 and 21, the telecentric error Δft will theoretically be zero when the center wavelength λ is approximately 344.146 nm. It is desirable to reduce the telecentric error Δθt on the image plane to zero as much as possible, but an allowable range can be given taking into account the minimum line width (or the resolution Rs) of the pattern to be projected or the chromatic aberration characteristics of the projection units PLU, or the like.

For example, as shown in FIG. 31, when the allowable range of the telecentric error Δθt on the image plane side is set to within +0.6° (approximately 10 mrad), the center wavelength λ may be in the range of 343.098 nm to 345.193 nm (2.095 nm in width). In addition, when the allowable range of the telecentric error Δθt on the image plane side is set within +2.0°, the center wavelength λ may be in the range of 340.655 nm to 347.636 nm (6.98 nm in width).

In this way, the telecentric error Δθt, which occurs due to the layout (periodicity) or the crowding of the micro mirror Msa in the ON-state of the DMD 10, i.e., the size of the distribution density, also has wavelength dependency. In general, the specifications of the micro mirror Ms of the DMD 10, such as the pitch Pdx (Pdy) or the tilt angle θd, are set uniquely as a ready-made product (for example, an ultraviolet ray-compatible DMD made by Texas Instruments), so the wavelength λ of the illumination light ILm is set to match those specifications. In the DMD 10 of this embodiment, the pitch Pdx (Pdy) of the micro mirror Ms is 5.4 μm and the tilt angle θd is 17.5°, so a fiber amplifier laser light source that generates high-brightness pulsed ultraviolet light may be used as a light source to supply the illumination light ILm to each of the optical fiber bundles FBn (n=1 to 27).

The fiber amplifier laser light source is constituted by, for example, as disclosed in Japanese Patent No. 6428675, a semiconductor laser element configured to generate seed light in the infra-red wavelength range, a high speed switching element for seed light (electro-optical element or the like), an optical fiber configured to amplify the switched seed light (pulsed light) using pump light, a wavelength conversion element configured to convert the amplified light within an infra-red wavelength range into pulsed light with a high frequency (ultraviolet wavelength range), and the like. In the case of such a fiber amplifier laser light source, the peak wavelength of the ultraviolet ray, which can achieve high generation efficiency (conversion efficiency) by combining available semiconductor laser elements, optical fibers, and wavelength conversion elements, is 343.333 nm (wavelength width is less than 50 pm). In the case of this peak wavelength, the telecentric error Δθt on the maximum image plane side that can occur in the state of FIG. 20 (the tilt angle on the image plane side of the 9^{th} order diffraction light Id9 in FIG. 22 and FIG. 23) is approximately 0.466° (approximately 8.13 mrad).

For the above reasons, when two or more lights with significantly different peak wavelengths (for example, light with a wavelength of 350 nm and light with a wavelength of 400 nm) are combined or switched as the illumination light ILm, the telecentric error Δθt changes significantly depending on the shape of the pattern to be projected (isolated pattern, line and space pattern, or large land pattern), which causes a problem.

Here, in the embodiment, the illumination light ILm supplied to each module MUn (n=1 to 27) is a multi-wavelength laser light (for example, within a wavelength width of about +0.2 nm relative to the center wavelength) composed of laser light (for example, wavelength width of about 50 pm) from a plurality of fiber amplifier laser light sources, with the peak wavelengths shifted slightly within the range in which the wavelength-dependent telecentric error Δθt is allowed. In this way, by using a multi-wavelength laser light combined by slightly shifting the peak wavelength as the illumination light ILm, the contrast of speckles (or interference fringes) that occur on the micro mirror Ms of the DMD 10 and on the substrate P due to the coherence of the illumination light ILm can be sufficiently reduced.

### Second Embodiment

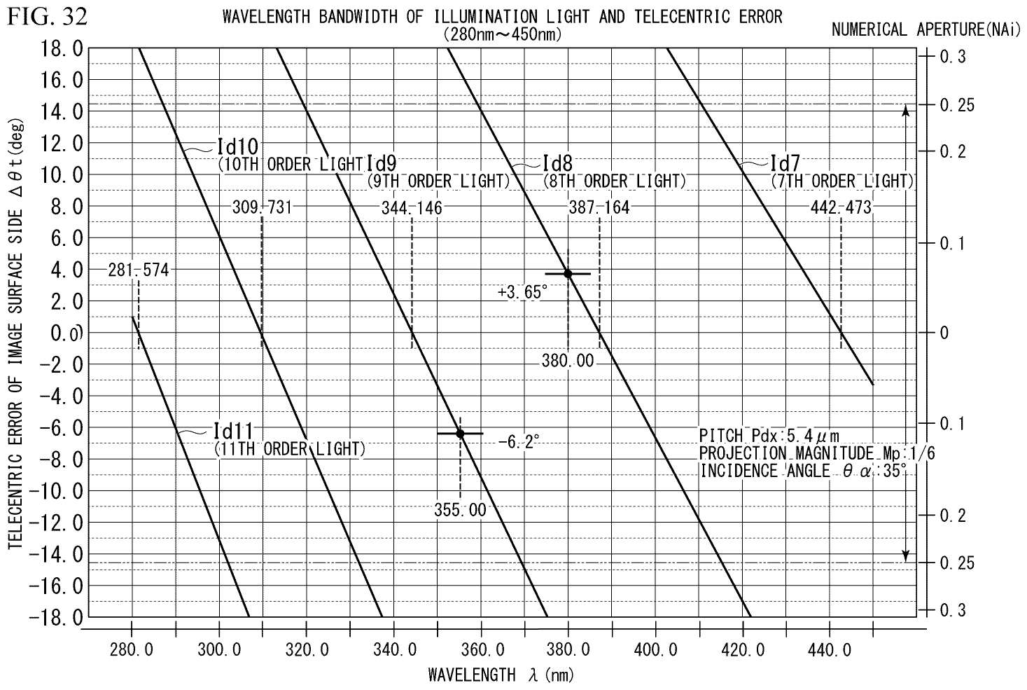

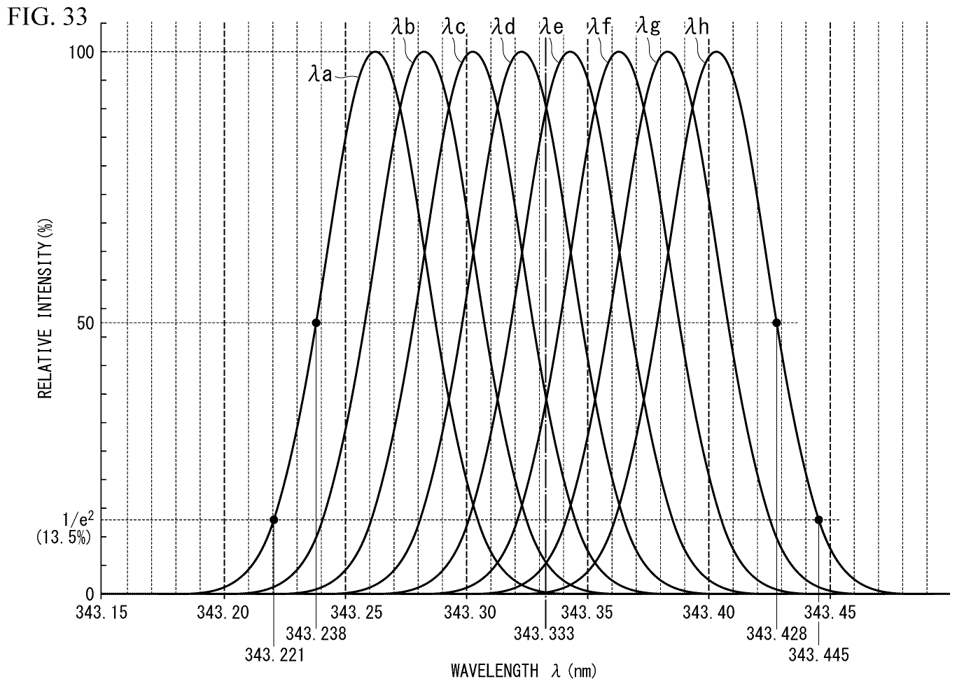

When the DMD 10 is obliquely illuminated by the illumination light ILm at the incidence angle θα (θα>) 20°, if two or more lights with significantly different peak wavelengths (for example, light with a wavelength of about 350 nm and light with a wavelength of about 400 nm) are combined or switched as the illumination light ILm, different telecentric errors λθt may occur depending on the difference in wavelength, as shown in FIG. 31. Here, provided that the array pitch Pdx (Pdy) of the micro mirror Ms of the DMD 10 is 5.4 μm, the tilt angle θd on the design of the micro mirror Msa in the ON-state is 17.5°, the incidence angle θα of the illumination light ILm is 35.0°, and the projection magnification Mp is ⅙, when the maximum telecentric error Δθt (on the image plane side) that can occur when the wavelength λ of the illumination light ILm is changed significantly is investigated, the results shown in FIG. 32 was obtained. FIG. 32 is a graph representing wavelength dependent characteristics of the telecentric error, with the wavelength λ(nm) taken as a horizontal axis and the telecentric error Δθt (deg) on the image plane side taken as a vertical axis. In FIG. 32, the wavelength λ ranges from 280 nm to 450 nm, and the vertical axis on the right side of the graph represents the image-plane-side numerical aperture NAi of the projection units PLU corresponding to the angle. In the embodiment, for example, the maximum numerical aperture NAi (max) on the image plane side of the projection units PLU is set to 0.25. As described above, under the conditions of Pdx=5.4 μm and θα=35°, when the micro mirror Msa in the ON-state is densely distributed, the 9^{th} order diffraction light Id9 generated when the center wavelength λ is 344.146 nm becomes the 0^{th} order light equivalent component, and the telecentric error Δθt becomes zero.

Similarly, according to Equation (2) or Equation (3) above, when the center wavelength λ of the illumination light ILm is 281.574 nm on the short wavelength side, the 11^{th} order diffraction light Id11 generated from the DMD 10 becomes the 0^{th} order light equivalent component and the telecentric error Δθt is zero, and when the center wavelength λ of the illumination light ILm is 309.731 nm, the 10^{th} order diffraction light Id10 generated from the DMD 10 becomes the 0^{th} order light equivalent component and the telecentric error Δθt is zero. Similarly, when the center wavelength λ of the illumination light ILm is 387.164 nm on the long wavelength side, 8^{th} order diffraction generated from the DMD 10 becomes the 0^{th} order light equivalent component and the telecentric error Δθt is zero, and when the center wavelength λ of the illumination light ILm is 442.473 nm, 7^{th} order diffraction generated from the DMD 10 becomes the 0^{th} order light equivalent component and the telecentric error Δθt is zero.

Here, assuming that the illumination light ILm contains two wavelength components, provided that the first wavelength λ1 is 355,000 nm and the second wavelength λ2 is 380,000 nm, the telecentric error Δθt1 (tilt angle in the X′Z plane) on the image plane side under the wavelength λ1 (355,000 nm) is approximately −6.2°, as described in FIG. 22 and FIG. 23 above, because the 9^{th} order diffraction light Id9 becomes the 0^{th} order light equivalent component. In addition, the telecentric error Δθt2 (tilt angle in the X′Z plane) on the image plane side under the wavelength λ2 (380,000 nm) is approximately +3.65°, because the 8^{th} order diffraction light Id8 becomes the 0^{th} order light equivalent component.

The illumination light ILm is supplied from the optical fiber bundles FBn (n=1 to 27) as shown in FIG. 28 and FIG. 29 above, so that the light with the wavelength λ1 (355 nm) and the light with the wavelength λ2 (380 nm) obliquely illuminate the DMD 10 at the same incidence angle θα. However, due to the wavelength dependent characteristics of the telecentric error shown in FIG. 32, the telecentric error Δθt1) (−6.2° for the light with the wavelength λ1 is significantly different from the telecentric error Δθt2) (+3.65° for the light with the wavelength λ2. For this reason, if the illumination light ILm contains both light with the wavelength λ1 and light with the wavelength λ2, there is a possibility that the image quality of the pattern projected on the substrate P will be degraded.

Even if the various telecentric error adjustment mechanisms described in FIG. 28 and FIG. 29 above are used, the difference angle (about) 9.85° between the telecentric error Δθt1 and the telecentric error Δθt2 hardly changes. Here, in a first condition proposal, the wavelengths λ1 and λ2 are set so that the angle of difference between the maximum telecentric errors Δθt1 and Δθt2 that can occur in each of the two wavelengths λ1 and λ2 is within an allowable range (for example, +1°). In this case, the projection units PLU are assumed to be chromatic aberration corrected for each of the light with the wavelength λ1 and the light with the wavelength λ2.

For example, for the maximum telecentric error Δθt1) (−6.2° for the light with the wavelength λ1 (355.000 nm), the maximum telecentric error Δθt2 for the light with the wavelength λ2 is set to be within the allowable range (+1°), that is, the range of −5.2° to −7.2°. In this case, based on Equation (2) or Equation (3) above, the wavelength λ2 may be set in the range of approximately 397.35 nm to 401.25 nm. By setting it in this way, the adjustment mechanisms for various telecentric errors make the difference between the maximum telecentric errors Δθt1 and Δθt2 that can occur on design sufficiently small, making it possible to correct the various telecentric errors by the adjustment mechanisms.

Similarly, for the maximum telecentric error Δθt2) (+3.65° for the light with the wavelength λ2 (380,000 nm), the wavelength λ1 may be selected so that the maximum telecentric error Δθt1 for the light with the wavelength λ1 is within the allowable range (+1°) of +4.65° to +2.65°. Even in this case, based on Equation (2) or Equation (3) above, the wavelength λ1 may be set in the range of approximately 336.04 nm to 339.53 nm.

Provided that a diffraction angle of a main diffraction light (0^{th} order light equivalent) of an order j1 generated from the micro mirror Msa in the ON-state under the wavelength λ1 and reaching the substrate P via projection units PLU is θj1 and a diffraction angle of a main diffraction light (0^{th} order light equivalent) of an order j2 generated from the micro mirror Msa in the ON-state under the wavelength λ2 (λ2≈λ1) and reaching the substrate P via projection units PLU is θj2, the difference of the telecentric errors Δθt1 and Δθt2 described above is, in other words, a difference between the diffraction angle θj1 and the diffraction angle θj2.

Although it depends on the fineness of the pattern to be projected (fineness of line width, pitch, etc.) and the size of the σ value of the illumination light to the DMD 10, when the angle of the difference between the diffraction angle θj1 and the diffraction angle θj2 is Δθj (1-2) and the angle corresponding to the maximum numerical aperture NAi (max) of the projection units PLU is On (max), it is preferable to set the wavelengths λ1 and λ2 so that the allowable range of the angle Δθj (1-2) is ⅕ or less of the angle θn (max), and more preferably ⅛ or less. For example, as shown in FIG. 32, when the numerical aperture NAi (max) is set to 0.25, the angle θn (max) is approximately 14.5°, and depending on the setting of the wavelengths λ1 and λ2, the allowable range of the angle Δθj (1-2) may be 0<Δθj (1-2)≤2.9°, preferably 0<Δθj (1-2)≤1.8°.

In addition, in the embodiment, the first illumination light, whose center wavelength is the wavelength λ1, and the second illumination light, whose center wavelength is the wavelength λ2, are both set so that the wavelength width Δλ is sufficiently narrow. In the case of the condition shown in FIG. 32, the range of change of the telecentric error Δθt on the image plane side per 1.0 nm change in wavelength is approximately 0.57° when the 0^{th} order light equivalent component is 9^{th} order light Id9, and approximately 0.51° when the 0^{th} order light equivalent component is 8^{th} order light Id8. If the range of change in the telecentric error Δθt is to be within the allowable range, it is advisable to use laser light whose wavelength width Δλ is narrowed to within ±0.5 nm with respect to the center wavelength (each of 21 and 22).

Further, when the diffraction angle of the 0^{th} order light equivalent component (9^{th} order light Id9 or 8^{th} order light Id8) generated under the wavelength λ1 and the diffraction angle of the 0^{th} order light equivalent component (9^{th} order light Id9 or 8^{th} order light Id8) generated under the wavelength λ2 are generated on one side of the optical axis AXa of the projection units PLU, the following condition is required based on the above-mentioned Equation (3).

Provided that the array pitch of the micro mirror Ms is Pd, the incidence angle θα on the design is θα>0°, and the orders j1 and j2 are greater than 0, the relationship between the wavelengths λ1 and λ2 is set so that either the first condition λ1<Pd·sinθα/j1 and λ2<Pd·sinθα/j2 or the second condition 21>Pd·sinθα/j1 and λ2>Pd·sinθα/j2 is satisfied.

According to the above-mentioned embodiment, when the illumination light ILm containing the light with the two wavelengths λ1 and λ2 (λ1 ≈λ2) is used, the telecentric error of the imaging light flux Sa′ caused by the diffraction effect of the DMD 10 can be corrected well by setting the difference between the wavelength λ1 and the wavelength λ2 so that a difference angle between the diffraction angle θj1 of the main diffraction light of the order j1 generated from the micro mirror Msa in the ON-state under the light with the wavelength λ1 and reaching the substrate P via projection units PLU and the diffraction angle θj2 of the main diffraction light of the order j2 generated from the micro mirror Msa in the ON-state under the light with the wavelength λ2 and reaching the substrate P via projection units PLU, i.e., a difference angle between the telecentric error Δθt1 and the telecentric error Δθt2 is within a predetermined allowable range.

Further, according to the embodiment, when the illumination light ILm containing the light with the two wavelengths λ1 and λ2 (λ1+λ2) is irradiated onto the DMD 10 at the incidence angle θα on the design, which is equal to the double angle of the tilt angle θd of the micro mirror Msa in the ON-state, the telecentric error of the imaging light flux Sa′ caused by the diffraction effect of the DMD 10 can be corrected well by setting the wavelength λ1 and the wavelength λ2 so that the diffraction angle θj1 of the main diffraction light of the order j1 generated from the micro mirror Msa in the ON-state under the light with the wavelength λ1 and entering the projection units PLU and the diffraction angle θj2 of the main diffraction light of the order j2 generated from the micro mirror Msa in the ON-state under the light with the wavelength λ2 and entering the projection units PLU are distributed on one side of the optical axis AXa of the projection units PLU (one of positive and negative sides of the maximum telecentric error Δθt that occurs on the design).

### [Variant 1]

As described above, even when using multi-wavelength laser light (broadband light or multispectral light) in which the laser lights with the plurality of peak wavelengths are included within a relatively narrow wavelength width for the center wavelength λo, the telecentric error Δθt taking into account the entire wavelength width can be optimally corrected by the second condition proposal. In the second condition proposal, the telecentric error Δθt is corrected taking into account the effective bandwidth of multi-wavelength laser light (broadband light, or multispectral light). FIG. 33 is a view schematically representing wavelength distribution characteristics obtained by combining eight laser lights with a center wavelength λo set to 343.333 nm and peak wavelengths shifted by 20 pm (0.02 nm). In FIG. 33, a horizontal axis represents the wavelength λ(nm), and a vertical axis represents the relative intensity of each laser light normalized to 100% peak intensity. In addition, each of the eight laser lights has a wavelength width of approximately 50 pm (0.05 nm) at half-value (relative intensity 50%) and an approximately Gaussian distribution. In this way, by using a plurality of laser lights with different peak wavelengths, interference noise (speckles and interference fringes) occurring on the DMD 10 or the substrate P can be effectively suppressed.

If the peak wavelengths of the eight laser lights are Na, λb, λc, λd, λe, λf, λg, and λh, in order from shortest wavelength, there is a shift of approximately 20 pm between adjacent peak wavelengths. Since the center wavelength λo is set to 343.333 nm, the adjacent peak wavelength λd is set to 343.323 nm, and the peak wavelength λe is set to 343.343 nm. Further, the peak wavelength λc is set to 343.303 nm, the peak wavelength λb is set to 343.283 nm, the peak wavelength λ a is set to 343.263 nm, the peak wavelength λf is set to 343.363 nm, the peak wavelength λg is set to 343.383 nm, and the peak wavelength λh is set to 343.403 nm.

Accordingly, the bandwidth of the peak wavelength λ a to Ah is 140 pm (0.14 nm), from 343.263 nm to 343.403 nm. When the wavelength width of each laser light is 50 pm at half-value, the full width at half-value (relative intensity 50%) of the multi-wavelength laser light (broadband light, or multispectral light) composed of laser lights with the peak wavelengths λ a to Ah is approximately 190 pm (0.19 nm) in the range from 343.238 nm to 343.428 nm, as shown in FIG. 33. Further, the wavelength bandwidth of multi-wavelength laser light, where the relative intensity of the laser light is 1/e² (13.5%), is approximately 224 pm (0.224 nm) in the range from 343.221 nm to 343.445 nm. Here, when such broadband laser light is used, the telecentric error Δθt is calculated for the wavelengths of 343.221 nm and 343.445 nm, where the relative intensity is 1/e². Further, the projection units PLU are assumed to be chromatic aberration corrected in the wavelength range of 343.221 nm to 343.445 nm.

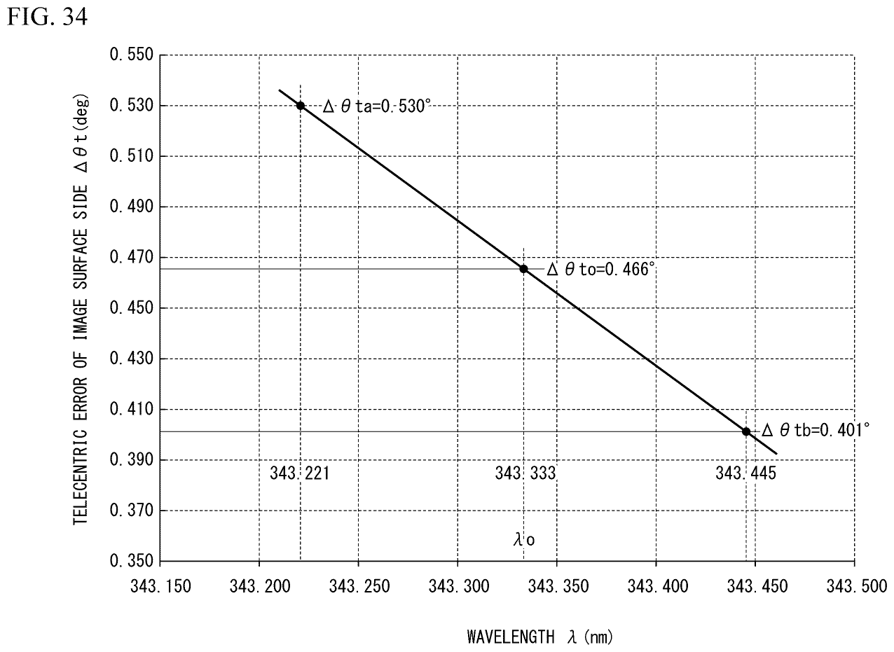

FIG. 34 is a graph representing characteristics of a telecentric error with the wavelength λ within a range of 343.200 nm to 343.450 nm with a horizontal axis representing the wavelength λ(nm) and a vertical axis representing the telecentric error λθt (deg) on the image plane side. Even in this case, the array pitch Pdx of the micro mirror Msa in the ON-state was set to 5.4 μm, the tilt angle θd on the design of the micro mirror Msa was set to 17.5°, and the incidence angle θα of the illumination light ILm (wavelength width 343.221 nm to 343.445 nm) to the DMD 10 was set to 35.0°. In addition, at that wavelength width, the 0^{th} order light equivalent component generated from the DMD 10 (the number of micro mirrors Msa in the ON-state) and entering the projection unit PLU is the 9^{th} order light Id9. Based on Equation (2) or Equation (3) above, the telecentric error Δθ to at the center wavelength λo (343.333 nm) is approximately 0.466°, the maximum telecentric error Δθta at the wavelength λ of 343.221 nm is approximately 0.530°, and the maximum telecentric error Δθtb at the wavelength λ of 343.445 nm is approximately 0.401°.

From the above, when using the multi-wavelength laser light (broadband light), it is assumed that the median value (average value) between the telecentric error Δθta on the short wavelength side of the wavelength bandwidth and the telecentric error Δθtb on the long wavelength side is the maximum telecentric error Δθt [=(Δθta+λθtb)/2] that can occur on design, and correction can be performed using the telecentric adjustment mechanism described in FIG. 28 and FIG. 29 above. After the telecentric adjustment is performed, the telecentric error remaining for the light on the short wavelength side of the wavelength bandwidth and the telecentric error remaining for the light on the long wavelength side of the wavelength bandwidth are both tilted at symmetric angles around the optical axis AXa of the projection units PLU. In the case of the condition shown in FIG. 34, since the median value (average value) of the telecentric error Δθta and the telecentric error Δθtb is equal to the telecentric error Δθ to, the telecentric error (Δθ to−Δθta, λθ to−Δθtb) remaining after the telecentric adjustment is within the range of +0.1° with respect to the optical axis AXa and can be almost ignored.

According to the above-mentioned second condition proposal, when the first illumination light of the peak wavelength λ a allowed by the chromatic aberration characteristics of the projection units PLU and the second illumination light of the peak wavelength λh (λ a≈λh) allowed by the chromatic aberration characteristics of the projection units PLU are irradiated onto the DMD 10 at the incidence angle θα corresponding to the double angle of the tilt angle θd of the micro mirror Msa in the ON-state, provided that the diffraction angle of the main diffraction light of the order j1 (9^{th} order light Id9 in the case of FIG. 34), which is generated from the micro mirror Msa in the ON-state under the light with the wavelength λ a and which enters the projection units PLU, is θj1 and provided that the diffraction angle of main diffraction light of the order j2 (9^{th} order light Id9 in the case of FIG. 34), which is generated from the micro mirror Msa in the ON-state under the light with the wavelength λh and which enters the projection units PLU, is θj2, a difference (bandwidth) between the wavelength λ a and the wavelength λh is set so that the diffraction angle θj1 (corresponding to the telecentric error Δθta) and the diffraction angle θj2 (corresponding to the telecentric error Δθtb) are distributed while having the optical axis AXa of the projection units PLU between the diffraction angle θj1 and the diffraction angle θj2.

Accordingly, even when the illumination light ILm having a broadband wavelength width within the range allowed by the chromatic aberration characteristics of the projection units PLU is used, the telecentric error of the imaging light flux Sa′ caused by the diffraction effect of the DMD 10 can be effectively corrected. [Variant 2]

As shown in FIG. 33 and FIG. 34, when the effective wavelength width Δλ of the illumination light ILm is narrow, such as 0.224 nm (343.221 nm to 343.445 nm), the width of the overall telecentric error is also small, but, when the wavelength width Δλ of the single illumination light ILm becomes wider, the width of the telecentric error increases accordingly.

For example, when using the illumination light ILm with the center wavelength λo of 355.0 nm and the effective wavelength width Δλ of approximately +2 nm (within the correction range of chromatic aberration), the width of the telecentric error increases, and the distribution state of the imaging light flux in the pupil Ep of the projection unit PLU also changes. Under the initial design conditions (Pdx=5.4 μm, θd=17.5°, θα=35.0°, Mp=⅙), the maximum telecentric error Δθt on the image plane side when the center wavelength λθ=355.0 nm of the illumination light ILm is −6.23° for the 9^{th} order diffraction light Id9, which is the 0^{th} order light equivalent component, based on FIG. 32 above and Equation (2) or Equation (3) above.

In this case, the center of the projection units PLU of the 9^{th} order diffraction light Id9) (−6.23° in the pupil Ep plane appears at a numerical aperture of approximately 0.109 on the image plane side. Similarly, when the wavelength width Δλ of the illumination light ILm is +2 nm, since the wavelength λ1 on the short wavelength side is 353.0 nm, the telecentric error Δθt1 on the image plane side caused by the wavelength λ1 is −5.08° (approximately 0.089 in numerical aperture). Further, since the wavelength λ2 on the long wavelength side is 357.0 nm, the telecentric error Δθt2 on the image plane side caused by the wavelength λ2 is −7.39° (approximately 0.129 in numerical aperture).

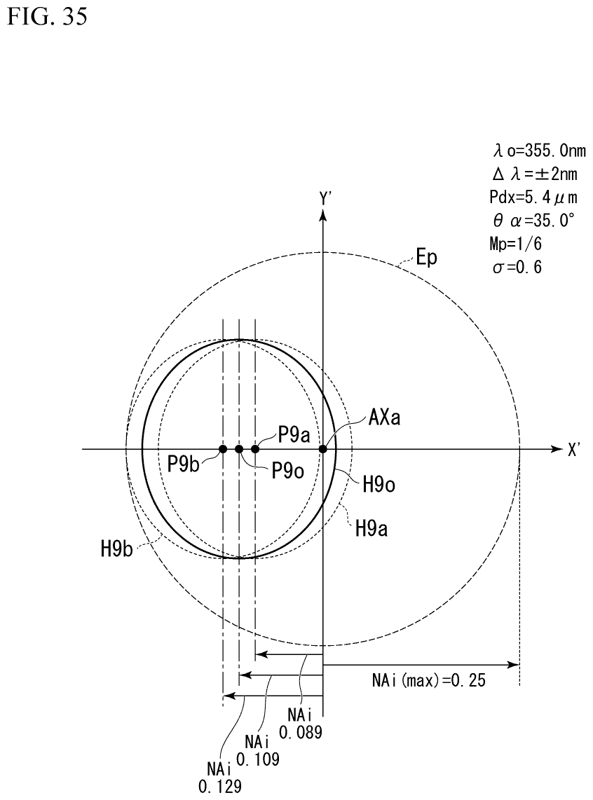

Here, FIG. 35 shows a schematic diagram of the state of the 9^{th} order diffraction light Id9 distributed to the pupil Ep of the projection units PLU, whose maximum numerical aperture NAi (max) on the image plane side is 0.25, when the center wavelength λo is 355.0 nm and the wavelength width Δλ is +2 nm. FIG. 35 shows a distribution of the 9^{th} order diffraction light Id9 appeared on the pupil Ep when the number of micro mirrors Ms of the DMD 10 are densely turned on, like in FIG. 23 above. In addition, in FIG. 35, the σ value, which is the ratio of the numerical aperture of the illumination light ILm to the numerical aperture of the projection units PLU, is set to 0.6 as an example, and the distribution of the oval shape of the 9^{th} order diffraction light Id9 (ellipse ratio≈0.82) that occurs when the incidence angle θα is 35.0° is left uncorrected.

A center P9o of the 9^{th} order diffraction light Id9 due to the light with the center wavelength λo (355.0 nm) appears at a position of the numerical aperture NAi=0.109 in the pupil Ep, a center P9a of the 9^{th} order diffraction light Id9 due to the light with the center wavelength λ1 (353.0 nm) appears at a position of the numerical aperture NAi=0.089, and a center P9b of the 9^{th} order diffraction light Id9 by the light with the center wavelength λ2 (357.0 nm) appears at a position of the numerical aperture NAi=0.129. Then, each of an oval distribution H9o of the 9^{th} order diffraction light Id9 due to the light with the center wavelength λo, an oval distribution H9a (almost congruent with the distribution H9o) of the 9^{th} order diffraction light Id9 due to the light with the center wavelength λ1, and an oval distribution H9b (almost congruent with the distribution H9o) of the 9^{th} order diffraction light Id9 due to the light with the center wavelength λ2 appears shifted in the X′ direction by approximately 0.02 in numerical aperture.

Accordingly, when the center wavelength λo is 355.0 nm and the illumination light ILm has the wavelength width Δλ of +2 nm, the 9^{th} order diffraction light Id9 (0^{th} order light equivalent component) is distributed in the pupil Ep throughout the distribution H9a and the distribution H9b shifted in the X′ direction. The telecentric error Δft) (−6.23° caused by the light with the center wavelength λo (355.0 nm) is corrected to zero by the telecentric adjustment mechanism described in FIG. 28 and FIG. 29 above. Accordingly, even if the center P9o of the distribution H9o is adjusted to coincide with the optical axis AXa, the relative decentering state (approximately 0.02 in numerical aperture conversion) of the distribution H9a due to the light on the short wavelength side of the wavelength λ1 and the distribution H9b due to the light on the long wavelength side of the wavelength λ2 with respect to the distribution H9o hardly changes.

Since the σ value of the illumination light ILm is 0.6 and the maximum numerical aperture NAi (max) of the projection units PLU is 0.25, a numerical aperture NAy′ in the Y′ direction of the distribution H9o of the 9^{th} order diffraction light Id9 due to the light with the center wavelength λo is NAi (max)×6=0.15. In addition, since the ellipse ratio at the incidence angle θα=35.0° is 0.82 (=cosθα), the numerical aperture NAx′ in the X′ direction of the distribution H9o of the 9^{th} order diffraction light Id9 due to the light with the center wavelength λo is NAy′×0.82=0.123. In addition, since the distribution H9a of the 9^{th} order diffraction light Id9 due to the light on the short wavelength side of the wavelength λ1 and the distribution H9b of the 9^{th} order diffraction light Id9 due to the light on the long wavelength side of the wavelength λ2 are decentered with respect to the distribution H9o by approximately 0.02 in the X′ direction when converted into a numerical aperture, the numerical aperture in the X′ direction of the overall distribution of the distributions H9a and H9b is 0.123+0.02=0.143.

From the above, when the illumination light ILm with the center wavelength λo =355.0 nm and the wavelength width Δλ=+2 nm is obliquely illuminated at the incidence angle θα=35° on the DMD 10 (Pdx=5.4 μm) under the condition of σ value=0.6, the overall distribution of the 9^{th} order diffraction light Id9 (0^{th} order light equivalent component) in the pupil Ep is 0.15 in the Y′ direction and 0.143 in the X′ direction in numerical aperture conversion, and the ellipse ratio is improved to approximately 0.95 (=0.143/0.15). Accordingly, by using the illumination light ILm (multi-wavelength light or broadband light) with an appropriate wavelength width Δλ, the overall distribution of the 0^{th} order light equivalent component (j^{th} order diffraction light) that appears in the pupil Ep of the projection unit PLU can be made circular (isotropic distribution with approximately the same dimensions in the X′ direction and Y′ direction) by suppressing the elliptical shape that inevitably occurs with oblique illumination (the incidence angle θα).

That is, by providing a predetermined wavelength width Δλ to the illumination light ILm that obliquely illuminates the DMD 10 within the range allowed by the chromatic aberration characteristics of the projection units PLU, it is possible to provide an ellipse reduction function that suppresses the ellipse of the distribution (the light source image Ips) of the imaging light flux (high order diffraction light) in the pupil Ep of the projection units PLU.

As shown in FIG. 10 and FIG. 11 (as well as FIG. 33) above, when the wavelength width Δλ of the narrowband light is sufficiently narrow (for example, Δλ≤0.2 nm), the distribution of the imaging light flux (the distribution of the light source image Ips) in the pupil Ep of the projection units PLU is defined by the σ value based on the dimension ri in the Y′ direction from the center (the optical axis AXa). Accordingly, the numerical aperture NAy′ in the Y′ direction of the distribution of the imaging light flux (distribution of the light source image Ips) is NAy′=σ·NAi (max) due to the maximum numerical aperture NAi (max) of the projection units PLU, and the numerical aperture NAx′ in the X′ direction of the distribution of the imaging light flux (distribution of the light source image Ips) is NAx′=σ·NAi (max)·cosθα. Accordingly, the ellipse ratio Ux′/Uy′ (=cosθα) described in FIG. 10 is also represented by the numerical aperture ratio NAx′/NAy′.

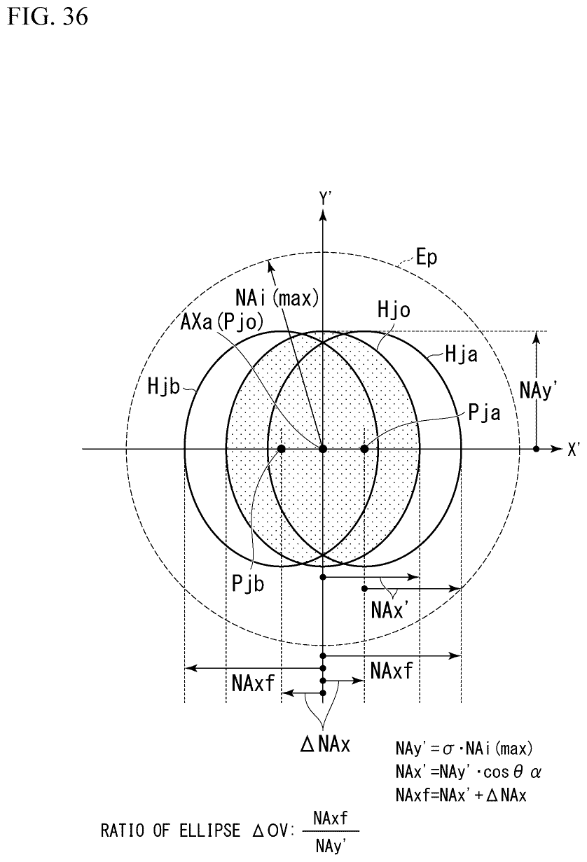

Meanwhile, in the case of the broadband illumination light ILm having a relatively wide wavelength width Δλ, as shown in FIG. 35, the imaging light flux (j^{th} order diffraction light) is distributed throughout the entire region from the distribution H9a corresponding to the light with the wavelength λo−λ2 to the distribution H9b corresponding to the light with the wavelength λo+λ2, and therefore, the effective oval distribution of the imaging light flux in the pupil Ep changes. Here, referring to FIG. 36, the relationship between the ellipse ratio of the entire imaging light flux (j^{th} order diffraction light) distributed on the pupil Ep plane and the wavelength width Δλ will be described.

FIG. 36 is an exaggerated view representing a distribution state of the distributions Hjo, Hja and Hjb of the high order diffraction light (j^{th} order diffraction light) from the DMD 10 appeared in the pupil Ep of the projection units PLU when the illumination light ILm with a large wavelength width Δλ is used, like FIG. 35. In FIG. 36, it is assumed that the telecentric adjustment mechanism is used to correct a center Pjo of an oval distribution Hjo that appears in response to the light with the center wavelength λo so that it coincides with the optical axis AXa of the projection units PLU. For this reason, a center Pja of an oval distribution Hja that appears in response to the light with the wavelength λo−λ2 on the short wavelength side, and a center Pjb of an oval distribution Hjb that appears in response to the light with the wavelength λo+λ2 on the long wavelength side are located almost symmetrically with a certain interval in the X′ direction with respect to the center Pjo (the position of the optical axis AXa). In addition, the interval of the center Pjo-Pja and the interval of the center Pjo-Pjb are assumed to be equal.

According to Equation (3) above, “sinθj” on the left side of Equation (3) represents the numerical aperture corresponding to the position of the central ray (the centers Pjo, Pja and Pjb) of the j^{th} order diffraction light passing through the pupil Ep of the projection unit PLU. Here, if the interval from the center Pjo to the center Pja (or Pjb) is converted to a numerical aperture and defined as the numerical aperture ΔNAx on the image plane side, the numerical aperture ΔNAx can be calculated by the following

Equation (8) or Equation (9) taking into account the projection magnification Mp (for example, Mp=⅙).

$$Δ NAx = [ sin θα - j \cdot λ o / Pdx ] / Mp - [ sin θα - j \cdot ( λ o + Δλ ) / Pdx ] / Mp = j \cdot Δλ / Pdx / Mp \qquad ( 8 )$$

$$Δ NAx = [ sinθα - j \cdot ( λ o - Δλ ) / Pdx ] / Mp - [ sinθα - j \cdot λ o / Pdx ] / Mp = j \cdot Δλ / Pdx / Mp \qquad ( 9 )$$

In addition, the size of the distribution Hjo (Hja and Hjb are the same) deformed into an oval shape due to the incidence angle θα from the optical axis AXa (the center Pjo) in the long axis direction (Y′ direction) can be expressed in numerical aperture using the σ value on design and the maximum numerical aperture NAi (max) on the image plane side of the projection units PLU. As shown in FIG. 36, if the numerical aperture in the Y′ direction of the distribution Hjo (Hja and Hjb are also the same) is NAy′, the numerical aperture NAy′ can be calculated by the following Equation (10).

$${NAy}^{′} = σ \cdot NAi ( max ) \qquad ( 10 )$$

Further, the numerical aperture NAx′ corresponding to the size of the distribution Hjo (Hja and Hjb are also the same) in the X′ direction is obtained by the following Equation (11) based on the ellipse ratio costa caused by the incidence angle θα.

$${NAx}^{′} = {NAy}^{′} \cdot cos θα = σ \cdot NAi ( max ) \cdot cos θα \qquad ( 11 )$$

As shown in FIG. 36, if the dimension in the X′ direction of the entire imaging light flux due to the j^{th} order diffraction light in the pupil Ep is converted to a numerical aperture of NAxf, the numerical aperture NAxf is represented as NAx′+ΔNAx. If the ellipse ratio of the distribution of the entire imaging light flux due to the j^{th} order diffraction light is represented as ΔOV, the ratio ΔOV is represented as NAxf/NAy′. When this ratio ΔOV becomes 1 (100%), the numerical apertures of the entire imaging light flux due to the j^{th} order diffraction light in the X′ and Y′ directions become equal on the substrate P, resulting in an isotropic imaging light flux. Based on Equations (8) to (11) above, the ratio ΔOV is represented by the following Equation (12).

$$Δ O V = ( {NAx}^{′} + Δ NAx ) / {NAy}^{′} = {NAx}^{′} / {NAy}^{′} + Δ NAx / {NAy}^{′} = cos θα + ( j \cdot Δλ / Pdx / Mp ) / ( σ \cdot NAi ( max ) ) \qquad ( 12 )$$

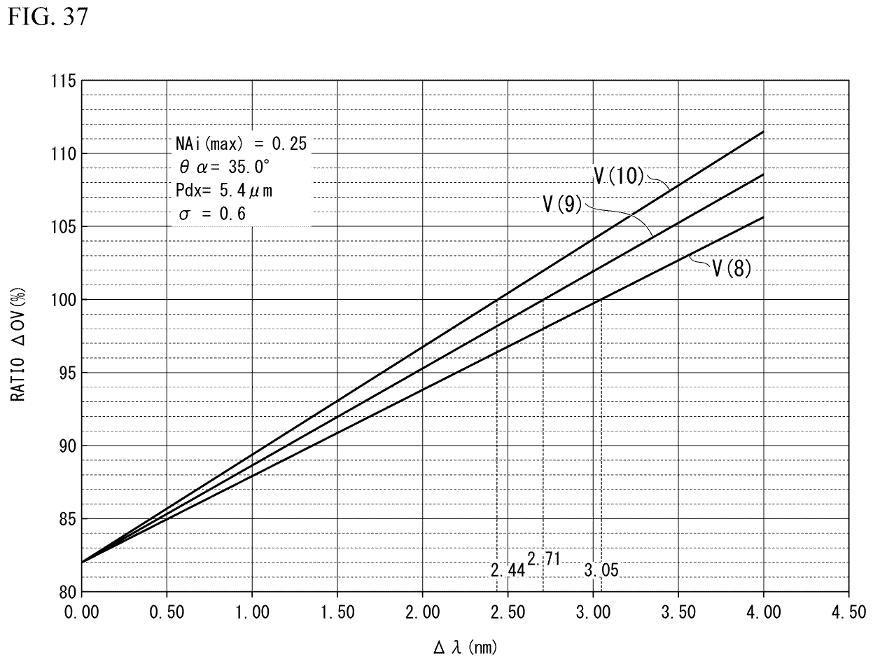

According to the graph in FIG. 32 above, since the order j that can be the 0^{th} order light equivalent component in a practical wavelength bandwidth (for example, about 300 nm to 400 nm) is 8^{th}, 9^{th}, and 10^{th}, when the order j in Equation (12) is j=8, j =9, and j=10, the change in the ellipse ratio ΔOV when the wavelength width Δλ is changed is calculated, and the characteristics shown in FIG. 37 are obtained.

In FIG. 37, a horizontal axis represents the wavelength width Δλ (nm), a vertical axis represents the ellipse ratio ΔOV (%), characteristics V (8) represents the case where the 0^{th} order light equivalent component is the 8^{th} order diffraction light, characteristics V (9) represents the case where the 0^{th} order light equivalent component is the 9^{th} order diffraction light, and characteristics V (10) represents the case where the 0^{th} order light equivalent component is the 10^{th} order diffraction light. The graph in FIG. 37 shows the characteristics obtained when the pitch Pdx of the micro mirror Msa in the ON-state is 5.4 μm, the incidence angle θα of the illumination light ILm is 35.0°, the numerical aperture NAi (max) of the projection units PLU is 0.25, the σ value is 0.6, and the projection magnification Mp is ⅙.

In the case of the characteristics V (8) in FIG. 37, when the wavelength width Δ2 is distributed over a range of +3.05 nm including the center wavelength λo (total width is 6.1 nm), the ratio ΔOV becomes 100%, the numerical aperture of the imaging light flux reaching the substrate P becomes equal in the X′ direction and the Y′ direction, and the quality (accuracy of the line width) of the projection image of various edge portions with different directionalities of the pattern to be exposed can be made the same. Similarly, in the case of the characteristics V (9), the ratio ΔOV becomes 100% when the wavelength width Δλ is distributed over a range of +2.71 nm including the center wavelength λo (5.42 nm in total width), and in the case of the characteristics V (10), the ratio ΔOV becomes 100% when the wavelength width Δλ is distributed over a range of +2.44 nm including the center wavelength λo (4.88 nm in total width).

Further, the ratio ΔOV does not necessarily have to be 100%, and it is possible to have a predetermined allowable range, such as +5% or +10%, depending on the fineness of the pattern to be exposed. In general, since a range of the wavelength width Δ2 is often limited by the chromatic aberration characteristics of the projection units

PLU, the allowable range is set so that the ratio ΔOV is about 95% or 90%. For example, in the characteristics V (9) in FIG. 37, when the ratio ΔOV is 90%, the wavelength width Δλ is approximately 1.45 nm (total width is approximately 2.9 nm), which has the advantage of facilitating chromatic aberration correction of the projection units PLU.

On the contrary, while the ratio ΔOV is set to be close to 100%, when the wavelength width Δλ is limited to within ±1.0 nm due to restrictions on the chromatic aberration characteristics of the projection units PLU, the ratio ΔOV at Δλ=1.0 nm is approximately 88% in the characteristics V (9). In this case, to further improve the ratio ΔOV and bring it closer to 100%, the opening shape of the aperture 108B shown in FIG. 29 above can be compensated for by changing it to an oval shape that improves the remaining ellipse ratio of about 12%. That is, it is possible to use in combination a function for reducing the ellipse by giving the illumination light ILm a constant wavelength width Δλ and a function for reducing the ellipse by providing an optical member such as the aperture 108B.

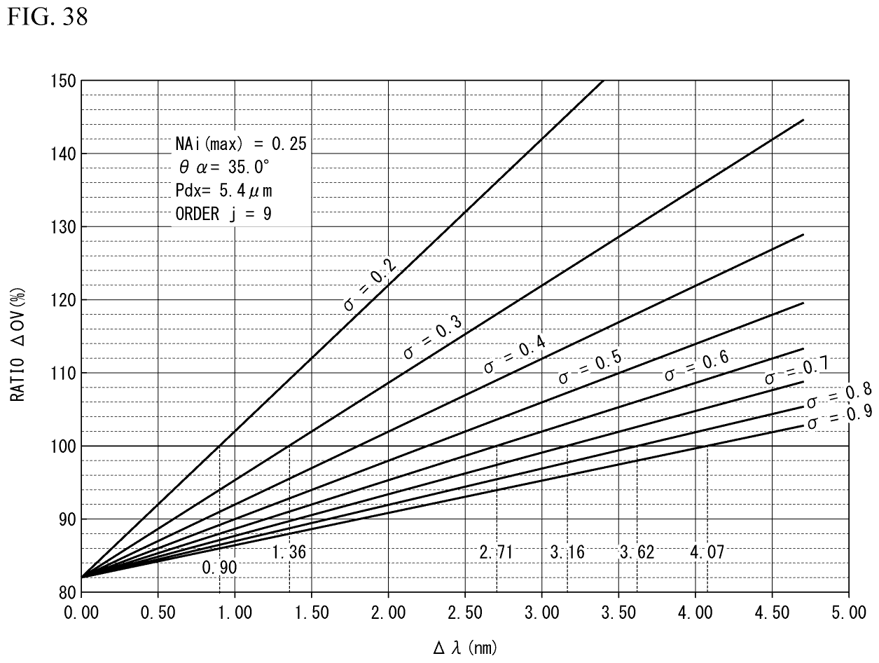

In the characteristics shown in FIG. 37, the σ value is set to 0.6, but the σ value may be adjustable to obtain a resolution or a depth of focus (DOF) appropriate for the fineness of the pattern to be exposed. Here, FIG. 38 describes how the characteristics V (9) in FIG. 37 change with a difference in the σ value.

FIG. 38 represents the characteristics when a horizontal axis is the wavelength width Δλ (nm) and a vertical axis is the ellipse ratio ΔOV (%), and the σ value is changed in the range of 0.2 to 0.9. Even in the graph of FIG. 38, the pitch Pdx of the micro mirror Msa in the ON-state is 5.4 μm, the incidence angle θα of the illumination light ILm is 35.0°, the numerical aperture NAi (max) of the projection units PLU is 0.25, the projection magnification Mp is ⅙, and the 0^{th} order light equivalent component is the 9^{th} order diffraction light (j=9).

As shown in FIG. 38, the wavelength width Δλ required to make the ratio ΔOV 100% is, for example, about 1.36 nm when the σ value is 0.3, about 2.71 nm when the σ value is 0.6, and about 3.62 nm when the σ value is 0.8. In this way, as the σ value increases, the wavelength width Δλ required to make the ellipse ratio ΔOV 100% increases. On the other hand, due to the limitations of the chromatic aberration characteristics of the projection units PLU, if the wavelength width Δλ of the illumination light ILm is set within ±1.0 nm (total width 2.0 nm), the ratio ΔOV can be improved to 100% when the σ value is set to 0.2, but if the σ value becomes larger than that, improvement of 100% is not achieved. Accordingly, even in this case, it is possible to use both the function of improving the ratio ΔOV by giving the illumination light ILm a constant wavelength width Δλ and the function of improving the ratio ΔOV by providing such an optical member of the aperture 108B.

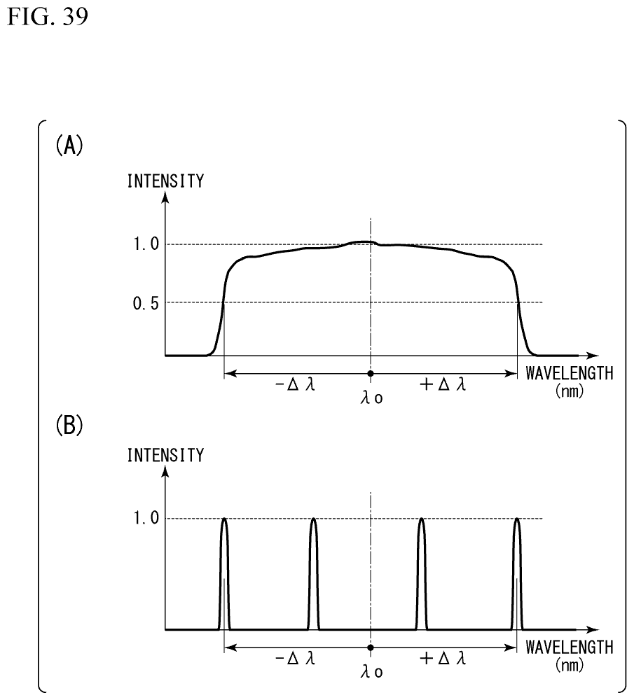

The broadbandized illumination light ILm described above does not need to have a continuous spectrum across the wavelength width Δλ. FIG. 39 is a graph showing an example of wavelength distribution characteristics of the illumination light ILm, the part (A) of FIG. 39 shows a case in which a spectrum is present within a range from the center wavelength λo to the wavelength width Δλ, and the part (B) of FIG. 39 shows a case in which a plurality of spectra with each single extremely small wavelength width are discretely distributed throughout the range of the wavelength width Δλ (±Δλ).

In FIGS. 39(A) and 39(B), a horizontal axis represents a wavelength (nm), and a vertical axis represents the relative intensity normalized to 1 for the peak value of the spectrum.

A continuous spectrum like that shown in the part (A) of FIG. 39 can be obtained with a specific bright line from a mercury discharge lamp or with laser light from an excimer laser light source in a non-band-narrowed natural oscillation state. In addition, as shown in the part (B) of FIG. 39, the technique of creating a plurality of spectra with different peak wavelengths can be achieved by using a plurality of different laser light sources (fiber amplifier laser, high frequency laser light sources such as Nd-YAG lasers, narrow-band excimer laser light sources, etc.), similar to the method described in FIG. 33 above. In this case, to effectively improve the ellipse ratio ΔOV, at least two spectra are required: one with a peak at the wavelength λθ-Δ2 on the short wavelength side, and one with a peak at the wavelength λo+λ2 on the long wavelength side.

According to Variant 2 described in FIGS. 35 to 39 above, as a pattern exposure device that irradiates illumination light onto the DMD 10 as a spatial light modulation element having the number of micro mirrors Ms that are two-dimensionally laid out with the pitch Pdx and are selectively driven based on drawing data, causes reflection light from the micro mirrors Msa selected from the DMD 10 in the ON-state to be incident on the projection units PLU and projects and exposes a pattern corresponding to the drawing data onto the substrate P, the illumination unit ILU configured to irradiate the illumination light ILm, which has a predetermined wavelength width±Δ2 with respect to the center wavelength λo, onto the DMD 10 at the incidence angle θα (θα>) 0° corresponding to the double angle of the tilt angle (d) on the design of the micro mirror Msa in the ON-state is provided.

Here, by appropriately setting wavelength width±λ2, a difference can occur between the diffraction angle θj1 of the main diffraction light (Id9) of the order j1 (for example, 9^{th}) generated from the micro mirror Msa in the ON-state under the light with the wavelength λo+λ2 on the long wavelength side of the illumination light ILm and entering the projection units PLU and the diffraction angle θj2 of the main diffraction light (Id9) of the order j2 (for example, 9^{th}) generated from the micro mirror Msa in the ON-state under the light with the wavelength λo−λ2 on the short wavelength side of the illumination light ILm and entering the projection units PLU. Accordingly, the overall distribution shape of the main diffraction light of the order j1 and the main diffraction light of the order j2 that appears in the pupil Ep of the projection units PLU (for example, the shape obtained by combining the distributions H9a and H9b of the oval shape in FIG. 35) can be deformed into an isotropic shape (approximately a circle) within the pupil Ep by the difference between the diffraction angle θj1 and the diffraction angle θj2 (for example, the difference between the numerical aperture NAi at the center P9a and the numerical aperture NAi at the center P9b in FIG. 35).

### Third Embodiment

In the above-mentioned first embodiment, second embodiment, or Variant 1, the array pitch Pdx of the micro mirror Ms of the DMD 10, the tilt angle θd of the micro mirror Ms, and the designed incidence angle θα (the angle formed by the optical axis AXb and the optical axis AXa in FIG. 6 above) of the illumination light ILm are set as fixed values, and the wavelength or the bandwidth of the illumination light ILm are selected so that the telecentric error Δθt can be corrected within the allowable range. However, when generating a broadband illumination light ILm in which the wavelength width is expanded by combining a plurality of lights with different peak wavelengths, it may not be possible to obtain a light source (fiber amplifier laser light source, excimer laser light source, semiconductor laser light source, high pressure mercury discharge lamp, or the like) with an ultraviolet wavelength range having the desired peak wavelength.

Here, in the embodiment, when at least two illumination lights having significantly different peak wavelengths (or wavelength bandwidths) are obliquely illuminated onto the DMD 10, the incidence angle of the illumination light for each wavelength range can be individually changed, thereby reducing the difference in the telecentric error Δθt that may occur due to differences in the wavelength range.

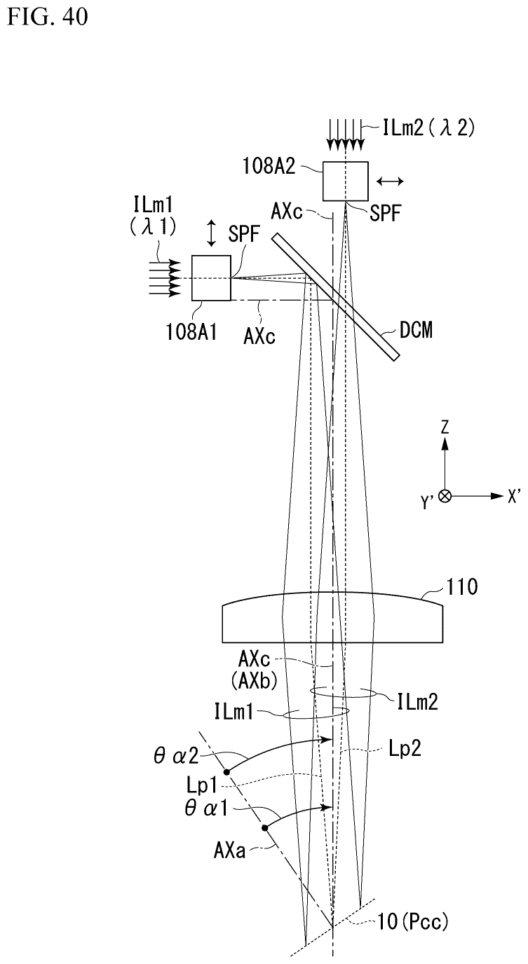

FIG. 40 is a view diagrammatically representing the optical path from the MFE lens 108A to the DMD 10 of the illumination unit ILU shown in FIGS. 4, 6, 28 and 29 above, in which two MFE lenses 108A1 and 108A2 and a plate-shaped dichroic mirror DCM (dichroic optical member) with wavelength selection characteristics have been added. Further, in FIG. 40, the coordinate system X′Y′Z is the same as that shown in FIG. 29 above, and the aperture 108B or the inclined mirror 112 shown in FIG. 29 above has been omitted to make the description easier to understand.

In the embodiment, the illumination light ILm1 having a peak wavelength (center wavelength) 21 in the ultraviolet range and the illumination light ILm2 having a peak wavelength (center wavelength) 22 longer than wavelength λ1 are projected onto the MFE lenses 108A1 and 108A2 via fiber bundles FBn or the lens system, respectively. The dichroic mirrors DCMs having a reflectivity of 90% or more for the wavelength λ1 and a transmittance of 90% or more for the wavelength λ2 are provided in the optical path between the MFE lens 108A1 and the condenser lens system 110, and in the optical path between the MFE lens 108A2 and the condenser lens system 110. The wavelength split plane of the dichroic mirror DCM is set to be tilted by 45° in the X′Z plane with respect to the optical axis AXc of the condenser lens system 110.

In addition, in FIG. 40, it is assumed that the point light source SPF formed at the center of the emission surface side of each of the MFE lenses 108A1 and 108A2 is decentered a predetermined distance from the optical axis AXc of the condenser lens system 110. That is, similar to a state as described above in FIG. 13, by decentering the circular or oval-shaped surface light source (assembly of the number of point light sources SPF), which is formed on the emission surface side of each of the MFE lenses 108A1 and 108A2, with respect to the optical axis AXc of the condenser lens system 110, the incidence angle θα1 of the principal ray (central ray) Lp1 of the illumination light ILm1 irradiated to the DMD 10 (the neutral plane Pcc) can be made different from the incidence angle θα2 of the principal ray (central ray) Lp2 of the illumination light ILm2 irradiated to the neutral plane Pcc.

If the tilt angle θd (for example,) 17.5° of the micro mirror Msa of the DMD 10 in the ON-state cannot be changed on design, the angle θα formed between the optical axis AXc (and AXb) of the condenser lens system 110 and the optical axis AXa of the projection units PLU is set to θα=2θd (for example,) 35.0° on design. In the embodiment, by adjusting the eccentricity of the MFE lens 108A1 relative to the optical axis AXc of the condenser lens system 110, the incidence angle θα1 of the illumination light ILm 1 directed toward the DMD 10 can be changed from the angle θg, and by adjusting the eccentricity of the MFE lens 108A2 relative to the optical axis AXc, the incidence angle θα2 of the illumination light ILm2 directed toward the DMD 10 can be changed from the angle θα.

Here, based on the relationship between wavelength bandwidth and the telecentric error described in the graph of FIG. 32 above, an example of the selection of the wavelength λ1 and the wavelength λ2 will be described. Here, the center wavelength (peak wavelength) 21 of the illumination light ILm1 on the short wavelength side is set to 343.0 nm, which is close to the sensitive wavelength band of typical liquid photoresists and is likely to be procured (produced) as an ultraviolet pulse light source, and the wavelength λ2 of the illumination light ILm2 on the long wavelength side is set to 405.0 nm (for example, a h-line spectrum of a mercury discharge lamp) to match the sensitive wavelength band of dry film resists.

According to FIG. 31 above, when the illumination light ILm1 has a center wavelength λ1 of 343.0 nm, the 9^{th} order diffraction light Id9 generated from the micro mirror Msa that is densely turned on becomes the 0^{th} order light equivalent (imaging light flux), and the maximum telecentric error Δθt1 on the image plane side that can occur under the initial design condition (when the eccentricity of the MFE 108A1 is zero) is approximately +0.6° (strictly speaking, it is about +0.66° based on Equation (2) or Equation (3) above). Meanwhile, for the illumination light ILm2 with the center wavelength λ2 of 405.0 nm, the 8^{th} order diffraction light Id8 generated from the micro mirror Msa, which is densely turned on, becomes the 0^{th} order light equivalent (imaging light flux), and the maximum telecentric error Δθt2 on the image plane side that can occur under the initial design condition (when the eccentricity of the MFE 108A2 is zero) is calculated to be approximately −9.12° based on Equation (2) or Equation (3) above.

From the above, by decentering the MFE lens 108A1 so that the telecentric error Δθt1) (+0.66° that may occur under the illumination light ILm1 is corrected, and decentering the MFE lens 108A2 so that the telecentric error Δθt2) (−9.12° that may occur under the illumination light ILm2 is corrected, the overall telecentric error of the imaging light flux generated during pattern exposure can be minimized even if the two illumination lights ILm1 and ILm2 are projected onto the DMD 10 simultaneously or in a time-division manner. Ultimately, it can be said that the difference between the telecentric error Δθt1 and the telecentric error Δθt2 occurs due to the difference between the wavelength λ1 of the illumination light ILm1 and the wavelength λ2 of the illumination light ILm2.

In addition, in the embodiment, since the two MFE lenses 108A1 and 108A2 are provided separately for each of the illumination lights ILm1 and ILm2, the aperture 108B having an oval shape opening as described in FIG. 29 above can also be provided separately. For this reason, the ellipse ratio of the opening of the aperture 108B provided on the emission side of the MFE lens 108A1 is set in accordance with the incidence angle θα1 of the central ray of the illumination light ILm1 to the DMD 10, and the ellipse ratio of the opening of the aperture 108B provided on the emission side of the MFE lens 108A2 is set in accordance with the incidence angle θα2 of the central ray of the illumination light ILm2 to the DMD 10.

### [Variant 3]

In FIG. 40, the two MFE lenses 108A1 and 108A2, which correspond to the illumination lights ILm1 and ILm2, are positioned and decentered from the optical axis AXc according to the telecentric errors Δθt1 and Δθt2, respectively. However, by providing tiltable quartz parallel plates between the dichroic mirror DCM and the MFE lens 108A1, and between the dichroic mirror DCM and the MFE lens 108A2, it is not necessary to decenter and position each of the two MFE lenses 108A1 and 108A2. In this case, by individually adjusting the tilt angle of each parallel plate, the illumination lights ILm1 and ILm2 projected onto the dichroic mirror DCM can be decentered with respect to the optical axis AXc.

### [Variant 4]

As described in FIG. 40, if the incidence angle θα1 of the illumination light ILm1 with the wavelength λ1 to the DMD 10 and the incidence angle θα2 of the illumination light ILm2 with the wavelength λ2 to the DMD 10 can be adjusted individually, it is also possible to prevent the distribution of the imaging light flux (9^{th} order diffraction light or 8^{th} order diffraction light) formed in the pupil Ep of the projection unit PLU from being deformed into an oval shape, as described above in FIG. 36.

As illustrated in the description of FIG. 40, the wavelength λ1 of the illumination light ILm1 is set to 343.0 nm, and the wavelength λ2 of the illumination light ILm2 is set to 405.0 nm. When the incidence angle θα of the illumination lights ILm1 and ILm2 to the DMD 10 is both 35.0°, as described above, the 0^{th} order light equivalent component generated from the DMD 10 by irradiation of the illumination light ILm1 becomes the 9^{th} order diffraction light, and the maximum telecentric error Δθt1 on the image plane side is approximately +0.66° (equivalent to approximately 0.01 in numerical aperture). In addition, the 0^{th} order light equivalent component generated from the DMD 10 by irradiation with the illumination light ILm2 is the 8^{th} order diffraction light, and the maximum telecentric error Δθt2 on the image plane side is approximately −9.12° (equivalent to approximately 0.16 in numerical aperture).

Here, the distribution of the 9^{th} order diffraction light with the wavelength λ1 and the 8^{th} order diffraction light with the wavelength λ2 that appear in the pupil Ep of the projection units PLU is considered, when the pitch in the X′ direction of the micro mirror Msa of the DMD 10 in the ON-state is 5.4 μm, the maximum numerical aperture NAi (max) of the projection units PLU (the projection magnification Mpp=⅙) is 0.25, and the σ value is 0.6. Further, the wavelengths λ1 and λ2 are both sufficiently narrow in wavelength width Δλ (for example, Δλ≤0.2 nm), and the ellipse ratio (ΔOV) of each diffraction light distributed to the pupil Ep of the projection units PLU is cosθα=0.82, which depends on the incidence angle θα.

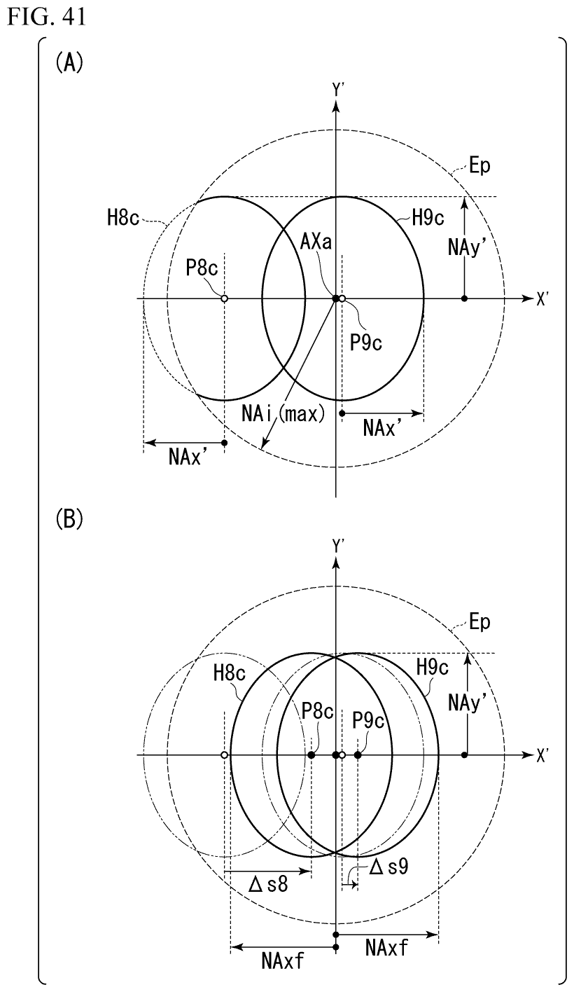

A part (A) of FIG. 41 is a view schematic representing the distribution H9c of the 9^{th} order diffraction light and the distribution H8c of the 8^{th} order diffraction light appearing in the pupil Ep of the projection unit PLU under the initial design condition (the incidence angle θα=) 35.0°, and the coordinate system X′Y′ is the same as in FIG. 35 or FIG. 36 above. The distribution H9c of the 9^{th} order diffraction light and the distribution H8c of the 8^{th} order diffraction light are both set to the same numerical aperture NAy′ in the Y′ direction. In addition, centers of the distribution H9c and the distribution H8c are P9c and P8c, respectively. Under the initial setting conditions, the distribution H8c of the 8^{th} order diffraction light is partly outside the numerical aperture NAi (max) of the pupil Ep due to the large telecentric error Δθt2 (−9.12°).

In a part (A) of FIG. 41, the position of the center P9c of the distribution H9c with respect to the optical axis AXa (the deviation in the X′ direction) is approximately 0.01 when converted to numerical aperture, and the position of the center P8c of the distribution H8c with respect to the optical axis AXa (the deviation in the X′ direction) is approximately 0.16 when converted to numerical aperture. In addition, the numerical aperture NAy′ corresponding to the spread in the Y′ direction of each of the distributions H9c and H8c is NAy′=σ·NAi (max)=0.15 according to Equation (10) above, and the numerical aperture NAx′ corresponding to the spread in the X′ direction is NAx′=NAy′·cosθα=0.123 according to Equation (11) above.

Here, the distribution state of the distributions H9c and H8c under the initial design condition shown in the part (A) of FIG. 41(A) is corrected to the state shown in the part (B) of FIG. 41. That is, in order to position the distribution H9c (wavelength λ1) of the 9^{th} order diffraction light and the distribution H8c (wavelength λ2) of the 8^{th} order diffraction light symmetrically in the X′ direction across the optical axis AXa with most of them overlapping, the center P9c of the distribution H9c is shifted by Δs9 in the +X′ direction from its initial position, and the center P8c of the distribution H8c is shifted by Δs8 in the +X′ direction from its initial position. These shifts can be set by the eccentricity of each of the MFE lenses 108A1 and 108A2 shown in FIG. 40 above.

In the case of this example, by shifting both the distributions H9c and H8c in the +X′ direction, the incidence angles of the illumination lights ILm1 and ILm2 irradiated to the DMD 10 become smaller than initial setting value of angle 35.0°. By this adjustment (correction), the numerical aperture NAxf, which corresponds to the overall size (spread) of the distributions H9c and H8c in the X′ direction, can be set to be approximately the same as the numerical aperture NAy′ in the Y′ direction, as described in FIG. 36 above.

In this example, since the wavelength λ1 of the illumination light ILm1 is 343.0 nm and the wavelength λ2 of the illumination light ILm2 is 405 nm, the projection units PLU need to be chromatic aberration corrected at these two wavelengths. For this reason, it is desirable to make the wavelength width Δλ of each of the illumination lights ILm1 and ILm2 as narrow as possible (for example, less than a few tens of pm).

### [Variant 5]

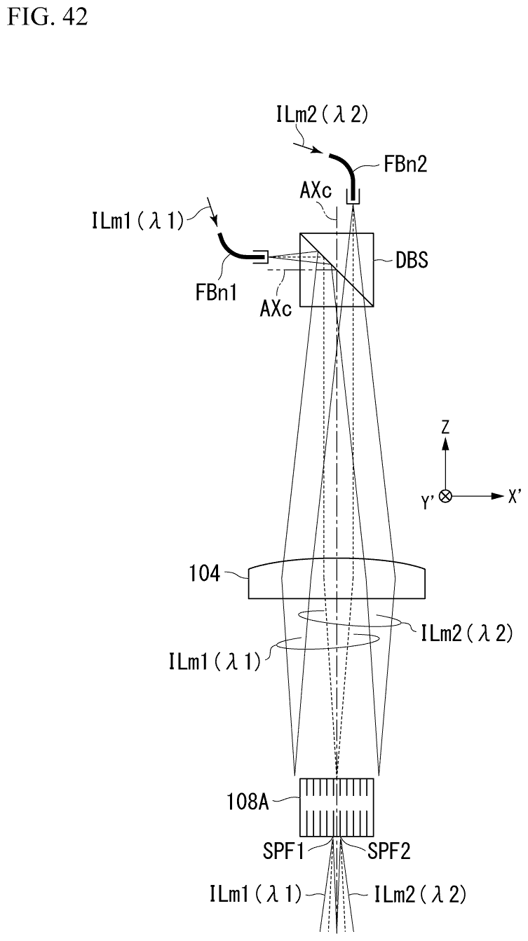

FIG. 42 is an optical layout diagram of a variant of the embodiment of FIG. 40, in which the illumination light ILm1 having the wavelength λ1 and the illumination light ILm2 having the wavelength λ2 enter a single MFE lens 108A at slightly different angles. Accordingly, a surface light source image assembled by the number of point light sources SPF with the wavelength λ1 and a surface light source image assembled by the number of point light sources SPF with the wavelength λ2 are formed on the emission surface side of the MFE lens 108A with a slight shift in the X′ direction (the occurrence direction of the telecentric error).

The optical layout in FIG. 41 is a modification of the optical path from the optical fiber bundles FBn to the MFE lens 108A shown in FIG. 28 above, in which the optical fiber bundle FBn1 that guides the illumination light ILm1 of the wavelength λ1 and the optical fiber bundle FBn2 that guide the illumination light ILm2 of the wavelength λ2 (λ2>λ1) are provided. Like FIG. 28, while the illumination light from each of the optical fiber bundles FBn1 and FBn2 irradiates the MFE lens 108A through the input lens system 104, which functions as a condenser lens, a cube-shaped dichroic beam splitter (hereinafter simply referred to as the beam splitter) DBS, which has wavelength selection function equivalent to the dichroic mirror DCM described in FIG. 40, is provided between the input lens system 104 and the emission end of the optical fiber bundle FBn1, and between the input lens system 104 and the emission end of the optical fiber bundle FBn2.

The light splitting surface of the beam splitter DBS (dichroic optical member) is disposed so as to be inclined at 45° with respect to the optical axis AXc of the input lens system 104 in the X′Z plane, and the emission ends of the optical fiber bundles FBn1 and FBn2 are both located at the front focus position of the input lens system 104. In FIG. 41, the center (light emitting point) of the emission end of the optical fiber bundle FBn1 and the center (light emitting point) of the emission end of the optical fiber bundle FBn2 are both decentered by a specified amount from the position of the optical axis AXc.

The beam splitter DBS reflects the illumination light ILm1 of the wavelength 21 with a reflectivity of 90% or more and transmits the illumination light ILm2 of the wavelength λ2 with a transmittance of 90% or more. Accordingly, the illumination light ILm1 from the emission end of the optical fiber bundle FBn1 is mostly reflected by the beam splitter DBS and enters the input lens system 104 with the principal ray (central ray) parallel to the optical axis AXc and decentered. Meanwhile, the illumination light ILm2 from the emission end of the optical fiber bundle FBn2 is mostly transmitted through the beam splitter DBS and enters the input lens system 104 with the principal ray (central ray) parallel to the optical axis AXc and decentered.

The illumination light ILm1 that passes through the input lens system 104 becomes a nearly parallel light flux, but is generally tilted with respect to the optical axis AXc when it enters the MFE lens 108A. Similarly, the illumination light ILm2 that passes through the input lens system 104 also becomes a nearly parallel light flux, but is generally tilted with respect to the optical axis AXc when it enters the MFE lens 108A. The incident end of the MFE lens 108A is set at the rear focus position of the input lens system 104, so that the two illumination lights ILm1 and ILm2 overlap to form an approximately circular distribution within the plane of the incident end of the MFE lens 108A.

However, since the incidence angles of the illumination lights ILm1 and ILm2 to the MFE lens 108A are slightly different, as described above in FIG. 30, the point light source SPF1 caused by the illumination light ILm1 and the point light source SPF2 caused by the illumination light ILm2 are formed with slight separation in the X′ direction for each of the number of the lens elements EL of the MFE lens 108A at the emission end of the MFE lens 108A (conjugate with the emission ends of the optical fiber bundles FBn1 and FBn2). Accordingly, at the emission end of the MFE lens 108A, a surface light source (Ips) assembled in an approximately circular shape by the number of point light sources SPF1 by the illumination light ILm1, and a surface light source (Ips) assembled in an approximately circular shape by the number of point light sources SPF2 by the illumination light ILm2 are formed while being shifted in the X′ direction. The shift amount is less than dimension in the X′ direction in the X′Y′ plane of one of the lens elements EL of the MFE lens 108A.

In this way, by making the incidence angle of each of the two illumination lights ILm1, ILm2 to the MFE lens 108A different, the surface light source of the illumination light ILm1 and the surface light source of the illumination light ILm2 formed at the emission end of the MFE lens 108A can be shifted relatively in the X′ direction. For this reason, the incidence angles of the principal rays of the illumination light ILm1 and the illumination light ILm2 irradiated to the DMD 10 can be individually adjusted (corrected) slightly.

### [Variant 6]

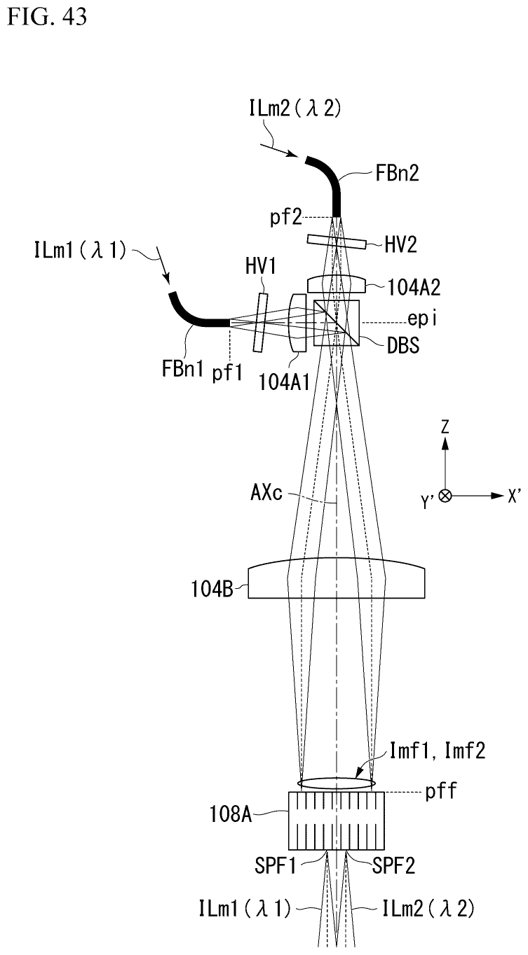

FIG. 43 is an optical layout diagram in which Variant 5 in FIG. 42 is further modified, and in the variant, the illumination light ILm1 with the wavelength λ1 and the illumination light ILm2 with the wavelength λ2 are configured to critically illuminate a single MFE lens 108A. In FIG. 43, the coordinate system X′Y′Z is set to the same as in FIG. 42, and the wavelength λ1 and the wavelength λ2 are set to a relationship of λ1<λ2.

In this example, an emission end pf1 of the optical fiber bundle FBn1 and an incident end pff of the MFE lens 108A, which guide the illumination light ILm1, are set in a conjugate relationship (imaging relationship) with each other by a magnification imaging system constituted by a lens system 104A1 and a lens system 104B arranged along the optical axis AXc. A dichroic beam splitter (hereinafter simply referred to as a beam splitter) DBS as shown in FIG. 42 is provided between the lens system 104A1 and the lens system 104B at approximately the position of a pupil epi. Accordingly, the illumination light ILm1 diverges and advances from the emission end pf1 of the optical fiber bundle FBn1, passes through the lens system 104A1, is reflected in the −Z direction by the wavelength separation surface (dichroic surface) of the beam splitter DBS, and passes through the lens system 104B to irradiate an illumination area Imf1 on the incident end pff of the MFE lens 108A.

Similarly, an emission end pf2 of the optical fiber bundle FBn2 and the incident end pff of the MFE lens 108A, which guide the illumination light ILm2, are set in a conjugate relationship (imaging relationship) with each other by a magnification imaging system constituted by a lens system 104A2 and the lens system 104B disposed along the optical axis AXc. Accordingly, the illumination light ILm2 diverges and advances from the emission end pf2 of the optical fiber bundle FBn2, passes through the lens system 104A2, then transmits through the wavelength separation surface (dichroic surface) of the beam splitter DBS in the −Z direction, and passes through the lens system 104B to irradiate the illumination area Imf2 on the incident end pff of the MFE lens 108A.

In the case of this example, each of the optical fiber bundles FBn1 and FBn2 uses a single fiber with a core diameter of about 1.2 mm, so the emission ends pf1 and pf2 are each circular. For this reason, the illumination areas Imf1 and Imf2 formed on the incident end pff of the MFE lens 108A are also each an enlarged circle. As an example, when the magnification of the magnification imaging system using the lens system 104A1 and the lens system 104B, and the magnification of the magnification imaging system using the lens system 104A2 and the lens system 104B is 20 times, the diameter of each of the illumination areas Imf1 and Imf2 is 24 mm. When the center point of the emission end pf1 of the optical fiber bundle FBn1 is aligned with the optical axis AXc, and the center point of the emission end pf2 of the optical fiber bundle FBn2 is aligned with the optical axis AXc, the illumination area Imf1 caused by the illumination light ILm1 and the illumination area Imf2 caused by the illumination light ILm2 overlap concentrically on the incident end pff of the MFE lens 108A.

Here, in this example, while making the overall dimensions in the X′ and Y′ directions of the incident end pff of the MFE lens 108A larger than diameters of each of the illumination areas Imf1 and Imf2, the dimensions in the X′Y′ plane of each of the lens elements EL (see FIG. 7 and FIG. 12 above) are made as small as possible. Then, by providing a mechanism to individually adjust the position of each of the illumination areas Imf1 and Imf2 within the plane of the incident end pff of the MFE lens 108A, it is possible to adjust the telecentric error of the imaging light flux and to mitigate the elliptical distribution of the imaging light flux in the pupil Ep of the projection units PLU.

The position adjustment of each of the illumination areas Imf1 and Imf2 within the plane of the incident end pff of the MFE lens 108A can be realized by a micromotion mechanism that mechanically shifts the emission ends pf1 and pf2 of each of the optical fiber bundles FBn1 and FBn2. However, since the magnification of the magnification imaging system constituted by the lens systems 104A1 and 104A2 and the lens system 104B is large, it is preferable to provide tiltable quartz parallel plates HV1 and HV2 between the emission end pf1 of the optical fiber bundle FBn1 and the lens system 104A1, and between the emission end pf2p of the optical fiber bundle FBn2 and the lens system 104A2, as shown in FIG. 43.

In this case, depending on the inclination of the parallel plate HV1 (HV2), the principal ray of the illumination light ILm1 (ILm2) which travels parallel to the optical axis AXc from the center point of the emission end pf1 (pf2) of the optical fiber bundle FBn1 (FBn2) and enters the lens system 104A1 (104A2) can be decentered and adjusted from the optical axis AXc to the X′ direction on the order of μm.

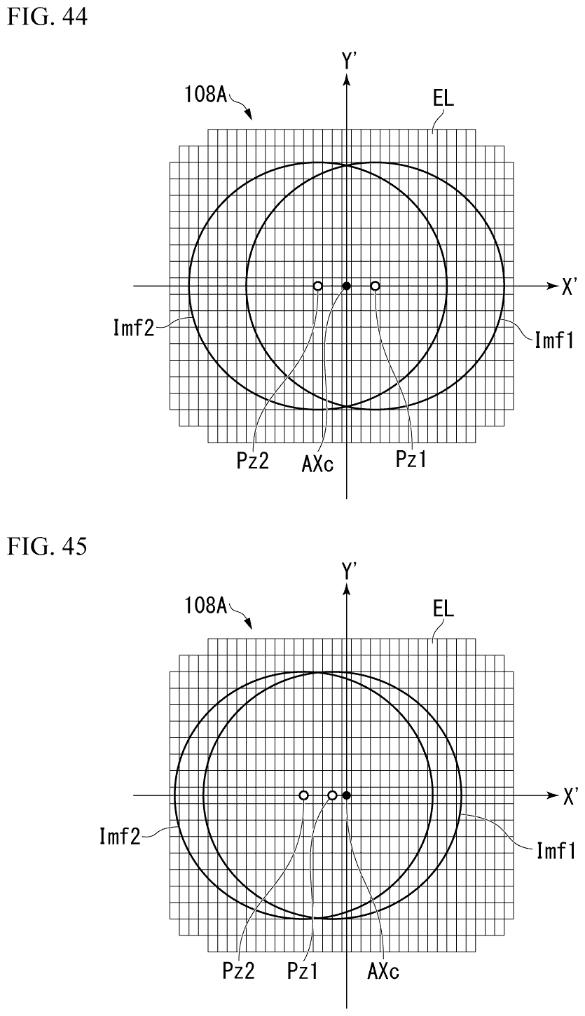

FIG. 44 is an exaggerated view representing a layout example of each of the illumination areas Imf1 and Imf2 projected within a plane of the incident end pff of the MFE lens 108A. As shown in FIG. 44, the overall dimensions in the X′ and Y′ directions of the incident end pff of the MFE lens 108A are set larger than diameter of each of the circular illumination areas Imf1 and Imf2 (the magnified image regions of each of the emission ends pf1 and pf2). In addition, a center point Pz1 of the illumination area Imf1 is conjugate to the center point of the emission end pf1 of the optical fiber bundle FBn1, and a center point Pz2 of the illumination area Imf2 is conjugate to the center point of the emission end pf2 of the optical fiber bundle FBn2.

By adjusting the tilt amount of each of the parallel plates HV1 and HV2 shown in FIG. 43, the illumination areas Imf1 and Imf2 (the center points Pz1 and Pz2) can be distributed symmetrically decentered in the X′ direction across the optical axis AXc. Accordingly, the assembly (circle distribution) of the number of point light sources SPF1 by the illumination light ILm1 formed on the emission end side of the MFE lens 108A and the assembly (circle distribution) of the number of point light sources SPF2 by the illumination light ILm2 are distributed with a predetermined amount decentered, with most of them overlapping in the X′ direction.

Accordingly, the overall shape of the surface light source (an assembly of the number of point light sources SPF1 and SPF2) formed on the emission end side of the MFE lens 108A is an oval shape with the X′ direction as its long axis and the Y′ direction as its short axis, which can correct (cancel) the oval distribution of the imaging light flux in the pupil Ep of the projection units PLU that occurs by oblique illumination of the DMD 10. In this case, it is advantageous that the aperture 108B shown in FIG. 29 above is no longer necessary, and as long as each of the illumination areas Imf1 and Imf2 is distributed within the range of the incident end pff of the MFE lens 108A, partial blocking or shading of the illumination light does not occur, thereby preventing loss of the illumination light amount.

In addition, the configuration in FIG. 43 enables correction of the oval distribution of the imaging light flux in the pupil Ep of the projection units PLU as well as correction of the telecentric error Δθt of the imaging light flux. Like FIG. 44, FIG. 45 is an exaggerated view representing another layout example of the illumination areas

Imf1 and Imf2 projected within the plane of the incident end pff of the MFE lens 108A. In FIG. 45, the center point Pz1 of the illumination area Imf1 and the center point Pz2 of the illumination area Imf2 are both decentered in the −X′ direction from the position of the optical axis AXc. The ellipse correction is performed by making the eccentricity of the center point Pz1 different from the eccentricity of the center point Pz2.

Further, decentering the overall distribution of the illumination areas Imf1 and Imf2 from the optical axis AXc to the −X′ direction is equivalent to shifting laterally the light source image on the emission surface side of the MFE lens 108A as seen from the side of the condenser lens system 110 shown in FIG. 29 above, and the incidence angle θα of the central ray of the illumination lights ILm1 and ILm2 irradiated to the DMD 10 can be changed from the design value (for example,) 35.0°, making it possible to correct the telecentric error Δθt.

For the above reasons, a configuration such as that shown in FIG. 43, which allows for a margin of error in laterally shifting the positions of the illumination areas Imf1 and Imf2 of the illumination lights ILm1 and ILm2 projected onto the incident end pff of the MFE lens 108A, also functions as a telecentric adjustment mechanism. Further, in the configuration of FIG. 43, a tiltable parallel plate can also be provided between the lens system 104B and the incident end pff of the MFE lens 108A. In this case, the illumination areas Imf1 and Imf2 shown in FIG. 44 and FIG. 45 can be shifted laterally together on the incident end pff of the MFE lens 108A, making it easy to correct the overall telecentric error of the imaging light flux projected from the projection units PLU to the substrate P.

For the above reasons, when changing the optical system from the optical fiber bundles FBn to the MFE lens 108A of one of the illumination unit ILUs shown in FIG. 28 above to a magnification imaging optical system and making the incident end of the MFE lens 108A a critical illumination system, telecentric adjustment can be achieved by installing a tiltable parallel plate between the emission end of the optical fiber bundles FBn and the magnification imaging system, or between the magnification imaging optical system and the incident end of the MFE lens 108A. In this case, since a circular illumination area is formed at the incident end of the MFE lens 108A, when the wavelength width Δλ of the illumination light ILm is narrow, for example, less than +0.2 nm, the effect of reducing ellipse caused by broadband light as described in FIGS. 35 to 39 above cannot be obtained.

For this reason, while the aperture 108B has an oval-shaped opening as shown in FIG. 29, since the position of the illumination area of the illumination light ILm on the incident end of the MFE lens 108A changes, a micromotion mechanism is required to shift the aperture 108B laterally independently. Alternatively, the magnification imaging optical system to be placed between the optical fiber bundles FBn and the MFE lens 108A in FIG. 28 may incorporate a cylindrical lens, an anamorphic lens, a toric lens, or a diffraction optical element (DOE) plate that has anisotropic refractive force (power) that transforms the illumination area on the incident end of the MFE lens 108A into an oval shape.

### [Other Variants]

In each embodiment or variant described above, an isolated pattern as an aspect of a pattern is not necessarily limited to a case where a single micro mirror Msa or a single row of all the micro mirrors Ms of the DMD 10 is in the ON-state. For example, it can also be considered as an isolated pattern when two, three (1×3), four (2×2), six (2×3), eight (2×4), or nine (3×3) micro mirrors Msa in the ON-state are densely arranged and the surrounding micro mirrors Ms are, for example, 10 or more micro mirrors Msb in the OFF-state in the X′ and Y′ directions. On the other hand, it can also be considered as a land-like pattern when two, three (1×3), four (2×2), six (2×3), eight (2×4), or nine (3×3) micro mirrors Msb in the OFF-state are densely arranged and the surrounding micro mirrors Ms are densely arranged over an area of several or more micro mirrors Msa in the ON-state in the X′ direction and Y′ direction (corresponding to a dimension several times larger than that of the isolated pattern).

In addition, the line and space pattern as an aspect of the pattern is not necessarily limited to the aspect shown in FIG. 24, in which one row of the micro mirrors Msa in the ON-state and one row of the micro mirrors Msb in the OFF-state are arranged alternately and repeatedly. For example, the aspect may be an aspect in which two rows of the micro mirrors Msa in the ON-state and two rows of the micro mirrors Msb in the OFF-state are alternately and repeatedly arranged, an aspect in which three rows of the micro mirrors Msa in the ON-state and three rows of the micro mirrors Msb in the OFF-state are alternately and repeatedly arranged, or an aspect in which two rows of the micro mirrors Msa in the ON-state and four rows of the micro mirrors Msb in the OFF-state are alternately and repeatedly arranged. Even in any pattern form, if the distribution state (density or crowding) of the micro mirrors Ms in the ON-state per unit area (for example, the layout region of 100×100 micro mirrors Ms) in all the micro mirrors Ms of the DMD 10 is determined, the telecentric error Δθt or the degree of asymmetry of the pattern edge can be easily specified by simulation or the like.

### Fourth Embodiment

In each embodiment or variant described above, it has been described that making the illumination light ILm multi-wavelength or broadband has the effect of reducing the inevitable deformation of the distribution of the imaging light flux (high order diffraction light) formed in the pupil Ep of the projection unit PLU into an oval shape caused by oblique illumination. In addition, making the illumination light ILm multi-wavelength or broadband also has the effect of reducing the illuminance fluctuation of the imaging light flux (reflected diffraction light that is the 0^{th} order light equivalent component) that occurs due to the residual error from the design value of the tilt angle θd of the micro mirror Msa in the ON-state of the DMD 10, or the time-dependent fluctuation error of the tilt angle θd.

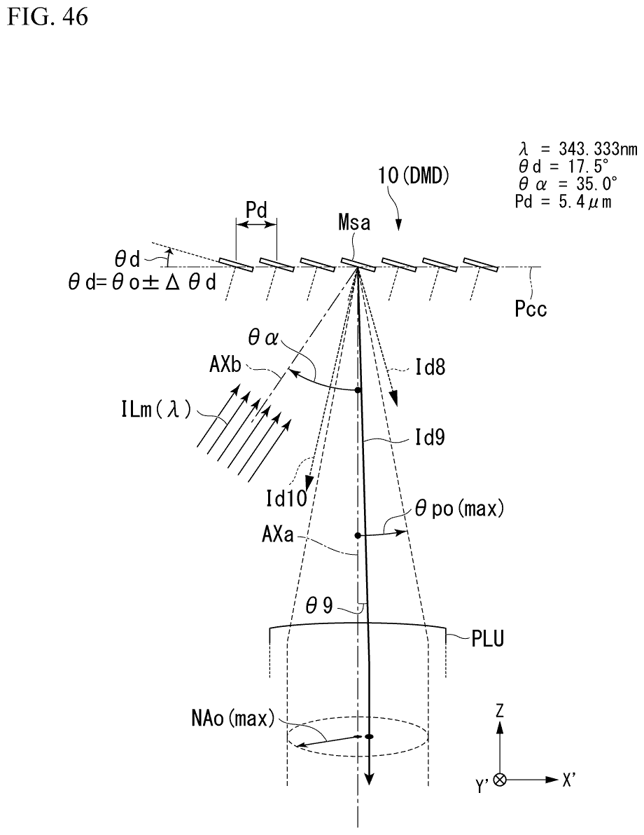

Here, the change in the tilt angle θd of the micro mirror Msa in the ON-state and the change in the diffraction angle θj of the high order diffraction light Idj from the DMD 10 will be described again with reference to FIG. 46. FIG. 46 is a view schematically describing an angle state when the diffraction light Idj from the number of the micro mirror Msa in the ON-state densely enters the projection units PLU. In addition, the coordinate system X′Y′Z in FIG. 46 is set in the same way as in FIG. 6, FIG. 10, FIGS. 20 to 22, FIG. 28, FIG. 29 above, and the like.

As shown in FIG. 46, the actual tilt angle θd of the number of the micro mirror Msa in the ON-state is expressed as θd=00+Δθd, where θo is the tilt angle on the design and Δθd is the absolute value of the fluctuation angle (error angle) as the error component. The incidence angle θg, which is the angle between the optical axis AXb of the condenser lens system 110 of the illumination unit ILU, which is bent by the inclined mirror 112 of the optical axis AXc, and the optical axis AXa of the projection units PLU, is set here to twice of the tilt angle θo on the design of the micro mirror Msa in the ON-state.

As shown in Equation (3) above, the diffraction angle θj of the diffraction light Idj of the order j is calculated by

$$sin θ j = sin θα - j ( λ / Pd ) , \qquad ( 3 )$$

where λ is the wavelength of the illumination light ILm, Pd is the array pitch in the X′ direction of the micro mirror Msa, and Ox is the incidence angle. The diffraction angle θj calculated by this equation is the angle of the projection unit PLU from the optical axis AXa, the diffraction light Idj is tilted counterclockwise from the optical axis AXa when the diffraction angle θj is positive, and the diffraction light Idj is tilted clockwise from the optical axis AXa when the diffraction angle θj is negative.

As shown in the example above, when the wavelength λ is 343.333 nm, the array pitch Pd is 5.4 μm, the incidence angle θα is 35.0°, and the error angle Δθd at the inclination of the micro mirror Msa is zero, the diffraction angle θ9 of the central ray of the 9^{th} order diffraction light Id9 for j=9 is approximately +0.078° (equivalent to the object-plane-side numerical aperture NAo, approximately 0.00135) according to Equation (3), and the 9^{th} order diffraction light Id9 becomes the 0^{th} order equivalent component. In addition, the diffraction angle θ8 of the central ray of the 8^{th} order diffraction light Id8, which is before the 9^{th}, is approximately +3.72° (equivalent to approximately 0.0649 in object-plane-side numerical aperture NAo), and the diffraction angle θ10 of the central ray of the 10^{th} order diffraction light Id10, which is after the 9^{th}, is approximately −3.57° (equivalent to approximately 0.0622 in object-plane-side numerical aperture NAo).

In addition, when the maximum numerical aperture NAi (max) on the image plane side of the projection units PLU is 0.3 and the projection magnification Mp is ⅙, the maximum numerical aperture NAo (max) on the object surface side (incidence side) of the projection units PLU is 0.05, and the maximum opening angle θpo (max) corresponding to the numerical aperture NAo (max) is approximately 2.87°.

Accordingly, the central ray of the 8^{th} order diffraction light Id8 and the central ray of the 10^{th} order diffraction light Id10 are both wider than the maximum opening angle θpo (max), so they do not enter the projection unit PLU. However, as described above in FIG. 23, the 8^{th} order diffraction light Id8 and the 10^{th} order diffraction light Id10 both have the distribution Hpb of a circular shape (or oval shape) whose size corresponds to the σ value of the illumination light ILm. For this reason, depending on the size of the σ value, part of the 8^{th} order diffraction light Id8 or the 10^{th} order diffraction light Id10 may enter the projection unit PLU.

In this way, when the error angle Δθd is zero, the light intensity of each of the 8^{th} to 10^{th} order diffraction lights Id8, Id9 and Id10 follows the point image intensity distribution lea, which is obtained by regarding a reflecting surface of a single micro mirror Msa as an infinitesimal rectangular opening, as described in FIG. 19 above. The light intensity Ie of the point image intensity distribution Iea is represented by Equation (1) above, and is described again below.

$$\begin{matrix}[ Math . 8 ] & \\ Ie = Io \cdot sin {c}^{2} ( {X}^{′} ) = Io \cdot {sin}^{2} ( {X}^{′} ) / {( {X}^{′} )}^{2} & ( 1 )\end{matrix}$$

In Equation (1), Io is the peak value of the actual light intensity, but in the following description, Io=1 (100%). In addition, when the error angle Δθd is zero (i.e., the tilt angle θd=θo) and the incidence angle θα of the illumination light ILm to the DMD 10 is set exactly to θα=2θd, X′ in Equation (1) represents the distance (length) in the X′ direction, with the optical axis AXa of the projection unit PLU as the origin (zero point).

Further, in Equation (1), when X′=π(3.1416), the light intensity Ie becomes zero, but its position satisfies the relationship X′=π=K (λ/Lms) due to the wavelength 2 of the illumination light ILm, the dimension Lms in the X′ direction of the reflecting surface of the micro mirror Msa, and a predetermined conversion coefficient K. However, when the micro mirror Msa in the ON-state is viewed from the side of the projection unit PLU, the dimension in the X′ direction of the reflecting surface of the micro mirror Msa appears to be reduced corresponding to the cosine of the tilt angle θd.

Accordingly, the conversion number K is represented as Equation (13) below.

$$K = π \cdot ( Lms \cdot cos θ d ) / λ \qquad ( 13 )$$

Here, when Lms·cosθd=Lms′, then the position of X′=π where Ie=0 corresponds to the diffraction angle βs of the first-order light, as determined by the following Equation (14).

$$sin β s = λ / {Lms}^{′} \qquad ( 14 )$$

Since a left side of Equation (14) represents the numerical aperture NAo of the diffraction angle βs on the object surface side (the side of the DMD 10) of the projection units PLU, the above-mentioned Equation (1) can be transformed into the following Equation (15) using the numerical aperture NAo as a variable.

$$Ie = {[ sin ( K \cdot NAo ) / ( K \cdot NAo ) ]}^{2} \\ Here , K = π \cdot {Lms}^{′} / λ \qquad ( 15 )$$

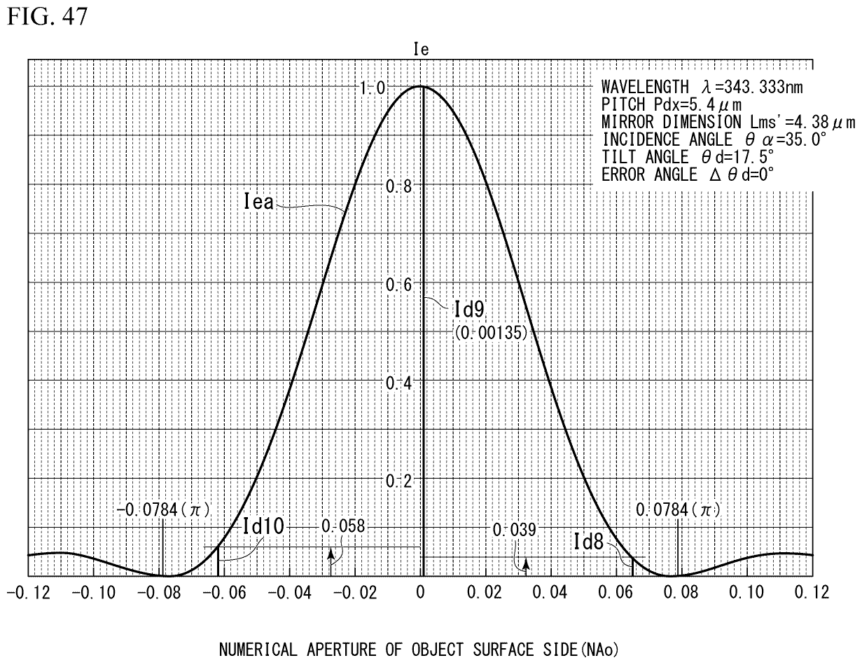

Here, as an example, FIG. 47 shows the point image intensity distribution lea and the distributions of the 8^{th} to 10^{th} order diffraction lights Id8, Id9 and Id10 that appear when the wavelength λ of the illumination light ILm is 343.333 nm, the array pitch Pdx of the micro mirror Ms is 5.4 μm, the dimension Lms in the X′ direction of the reflecting surface of the single micro mirror Ms is 4.6 μm (=85%·Pdx), the incidence angle θα of the illumination light ILm is 35.0°, and the error angle Δθd of the micro mirror Msa in the ON-state is zero.

In FIG. 47, a vertical axis represents the light intensity Ie with a maximum value of 1 (100%), and a horizontal axis represents the numerical aperture NAo of the object surface side. In addition, the error angle Δθd of the micro mirror Msa tilted in the ON-state is set to zero, and the incidence angle θα is set exactly to 35.0°, which is twice the tilt angle θd. Accordingly, the origin of the numerical aperture NAo=0 coincides with the optical axis AXa of the projection unit PLU in the X′Y′ plane. Further, although the numerical aperture NAo does not take negative values, here the positive range of the numerical aperture NAo is defined as the +X′ side of the optical axis AXa, and the negative range is defined as the −X′ side of the optical axis AXa.

The point image intensity distribution Iea in FIG. 47 is a simulation of the characteristics of Equation (15) above, and the effective dimension Lms' in the X′ direction of the reflecting surface of the micro mirror Msa is Lms. cosθd=4.6) μm·cos (17.5°≈ 4.38 μm. The numerical aperture NAo value (corresponding to X′=T) where the light intensity Ie first becomes 0 on the point image intensity distribution Iea is +0.0784. Further, when the object-plane-side numerical aperture NAo of the horizontal axis shown in FIG. 47 is represented by the image-plane-side numerical aperture NAi (the substrate P side), NAi=NAo/Mp can be obtained by using the projection magnification Mp (for example, Mp=⅙) of the projection units PLU.

Meanwhile, under the conditions of the error angle Δθd=θ, the incidence angle θd=35.0°, and the wavelength λ=343.333 nm, the central rays of the 8^{th} order diffraction light Id8, the 9^{th} order diffraction light Id9, and the 10^{th} order diffraction light Id10 calculated by Equation (3) above propagate toward the projection unit PLU with the diffraction angles θ8, θ9 and θ10, respectively. The numerical aperture NAo9 of the object surface side corresponding to the diffraction angle θ9 of the 9^{th} order diffraction light Id9 is the value (sinθ9) of the right hand side of Equation (3) calculated with the order j set to 9, which is approximately 0.00135. Similarly, the numerical aperture NAo8 on the object surface side corresponding to the diffraction angle θ8 of the 8^{th} order diffraction light Id8 is the value (sinθ8) of the right-hand side of Equation (3) calculated by setting the order j to 8, which is approximately 0.06493, and the numerical aperture NAo10 on the object surface side corresponding to the diffraction angle θ10 of the 10^{th} order diffraction light Id10 is the value (sinθ10) of the right-hand side of Equation (3) calculated by setting the order j to 10, which is approximately 0.06223.

The numerical aperture NAo9 (≈0.00135) on the object surface side of the central ray of the 9^{th} order diffraction light Id9 is extremely small, and the numerical aperture NAi9 on the image plane side when the projection magnification Mp is ⅙ is also approximately 0.0081, so there is no need to perform telecentric error correction to finely adjust the incidence angle θα of the illumination light ILm. Further, when the error angle Δθd=θ, the reflection light from the single micro mirror Msa is distributed within the pupil Ep of the projection unit PLU so that the point image intensity distribution Iea in FIG. 47 coincides with its origin (point 0) and the optical axis AXa.

Since the numerical aperture NAo9 of the object surface side of the 9^{th} order diffraction light Id9 is extremely small, the light intensity Ie of the 9^{th} order diffraction light Id9 calculated by Equation (15) is 0.99 or more (almost 100%). On the other hand, the light intensity Ie of the 8^{th} order diffraction light Id8 is 0.039 (3.9%), and the light intensity Ie of the 10^{th} order diffraction light Id10 is 0.058 (5.8%), which are significantly attenuated.

If the maximum numerical aperture NAi (max) on the image plane side of the projection units PLU is 0.3, the maximum numerical aperture NAo (max) on the object surface side is 0.05 when the projection magnification Mp is ⅙. For this reason, the central rays of the 8^{th} order diffraction light Id8 and the 10^{th} order diffraction light Id10 shown in FIG. 47 are outside the pupil Ep of the projection unit PLU, and are therefore not projected onto the substrate P.

From the above situation, when a certain error angle Δθd occurs on average in many of the micro mirrors Msa of the DMD 10 in the ON-state, the point image intensity distribution Iea shown in FIG. 47 will shift laterally overall. The point image intensity distribution Iea is the distribution generated by the reflected light from the reflecting surface of the single micro mirror Msa, and the principal ray of the reflected light entering the projection unit PLU is tilted from the optical axis AXa by double the error angle Δθd. For this reason, the point image intensity distribution lea generated within the pupil Ep of the projection units PLU is also shifted laterally in the X′ direction.

On the other hand, as is clear from Equation (3) above, the diffraction angle θ9 (and sinθ9) of the 9^{th} order diffraction light Id9 does not change because the wavelength 2 of the illumination light ILm, the incidence angle θg, and the pitch Pdx of the micro mirror Ms do not change. That is, as shown in FIG. 47, the value of the object-surface-side numerical aperture NAo of the central ray of each of the 9^{th} order diffraction light Id9, the 8^{th} order diffraction light Id8, and the 10^{th} order diffraction light Id10 does not change.

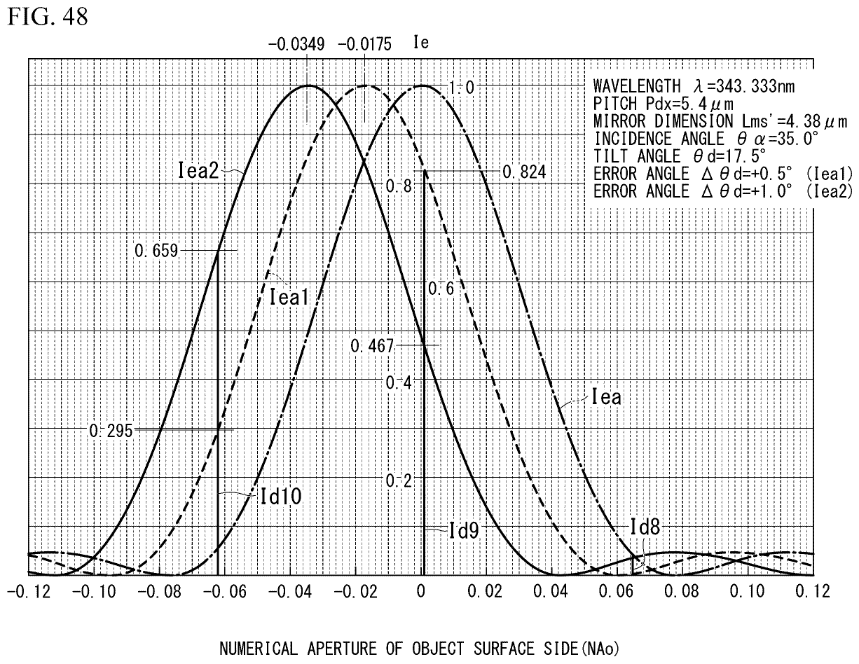

With respect to the characteristics shown in FIG. 47 above, FIG. 48 is a graph obtained by simulating the point image intensity distribution Iea1 when the tilt angle θd of the micro mirror Msa in the ON-state is changed from the designed tilt angle θ0) (17.5° by +0.5° as the error angle Δθd, and by simulating the point image intensity distribution Iea2 when the tilt angle θd of the micro mirror Msa in the ON-state is changed from the designed tilt angle θo) (17.5° by +1.0° as the error angle Δθd. The light intensity Ie on the vertical axis and the object-surface-side numerical aperture NAo on the horizontal axis of FIG. 48 are both shown on the same scale as the vertical and horizontal axes of FIG. 47. In addition, the values of the object-surface-side numerical aperture NAo of the central ray of each of the 8^{th} order diffraction light Id8, the 9^{th} order diffraction light Id9, and the 10^{th} order diffraction light Id10 in FIG. 48 are the same as those shown in FIG. 47.

In FIG. 48, when the error angle Δθd is +0.5°, the tilt angle θd of the micro mirror Msa is θd=θo) (17.5°+λθd=18°, with reference to FIG. 46 above. In addition, the central ray of the reflection light from the micro mirror Msa toward the projection unit PLU is tilted clockwise by 2·4θd=1.0° from the optical axis AXa. When converted to the object-plane-side numerical aperture NAo, angle2·Δθd=1.0° is approximately 0.0175 [sin (λ·Δθd)], and when the error angle Δθd is zero, the point image intensity distribution Iea shifts by 0.0175 in the negative direction (−X′ direction) on the object-plane-side numerical aperture NAo, as shown in the point image intensity distribution Iea1.

Similarly, when the error angle Δθd is +1.0°, the tilt angle θd of the micro mirror Msa is θd=θo) (17.5°+λθd=18.5°. In addition, the central ray of the reflection light from the micro mirror Msa toward the projection unit PLU is tilted clockwise by 2.4θd=2.0° from the optical axis AXa. When converted to the object-plane-side numerical aperture NAo, angle2·Δθd=2.0° is approximately 0.0349 [sin (λ·Δθd)], and when the error angle Δθd is zero, the point image intensity distribution Iea shifts by 0.0349 in the negative direction (−X′ direction) on the object-plane-side numerical aperture NAo, as shown in the point image intensity distribution Iea2.

Further, when the error angle Δθd becomes negative (when the tilt angle θd becomes smaller than the tilt angle θo on design), the point image intensity distribution Iea for the error angle Δθd=0 shifts overall in the positive direction (+X′ direction) on the object surface side of the numerical aperture NAo, corresponding to the double angle of the error angle Δθd.

When the error angle Δθd is +0.5°, the light intensity Ie of the 9^{th} order diffraction light Id9, which is the 0^{th} order light equivalent component generated from the number of micro mirrors Msa of the DMD 10 in the ON-state, follows the point image intensity distribution Iea1 and is approximately 0.824. When the error angle Δθd is zero, the light intensity Ie of the 9^{th} order diffraction light Id9 is 0.99 or more (almost 100%). However, when the error angle Δθd increases by only a small amount, i.e., +0.5°, the light intensity Ie of the 9^{th} order diffraction light Id9 decreases to approximately 82%. Similarly, when the error angle Δθd is +1.0°, the light intensity Ie of the 9^{th} order diffraction light Id9 generated from the DMD 10 follows the point image intensity distribution Iea2, so it is approximately 0.467. Accordingly, when the error angle Δθd is +1.0°, the light intensity Ie of the 9^{th} order diffraction light Id9 is reduced to about 47%.

Meanwhile, the light intensity Ie of the 8^{th} order diffraction light Id8 is approximately 0.028 (approximately 3%) when the error angle Δθd is +0.5° because it follows the point image intensity distribution Iea1, and is approximately 0.047 (approximately 5%) when the error angle Δθd is +1.0° because it follows the point image intensity distribution Iea2. Further, the light intensity Ie of the 10^{th} order diffraction light Id10 is approximately 0.295 (approximately 30%) when the error angle Δθd is +0.5° because it follows the point image intensity distribution Iea1, and is approximately 0.659 (approximately 66%) when the error angle Δθd is +1.0° because it follows the point image intensity distribution Iea2.

From the above, when a pattern is projected in which the micro mirrors Msa that are in the ON-state among the number of micro mirrors Ms of the DMD 10 are densely packed at the pitch Pdx, the light intensity of the high order diffraction light (here, the 9^{th} order diffraction light Id9), which is the 0^{th} order light equivalent component, is reduced according to the degree of the error angle Δθd of the micro mirror Msa. However, the telecentric error Δθt of the high order diffraction light (the 9^{th} order diffraction light Id9) does not change.

On the other hand, when the micro mirror Msa in the ON-state among the number of micro mirrors Ms of the DMD 10 is solely discretely distributed to project a pattern (isolated point image) in which substantial high order diffraction light is not generated, since it becomes a simple projection of a point image intensity distribution, there is almost no reduction in light intensity according to the degree of the error angle Δθd of the micro mirror Msa. However, the telecentric error Δθt, which corresponds to the double angle of the error angle Δθd, changes.

Since the DMD 10 and the substrate P are set in a conjugate (imaging) relationship by the projection units PLU, in the case of an isolated point image, even if the telecentric error Δθt changes due to a change in the error angle Δθd of the micro mirror Msa, the position of the reflection light from the micro mirror Msa projected onto the substrate P (the projection position of the point image) does not change. However, when a pattern (such as a large land pattern or a thick wiring pattern) in which the micro mirrors Msa in the ON-state are densely packed at the pitch Pdx is projected, the light intensity of the projection image, i.e., the exposure amount, can be significantly reduced depending on the degree of the error angle Δθd of the micro mirror Msa.

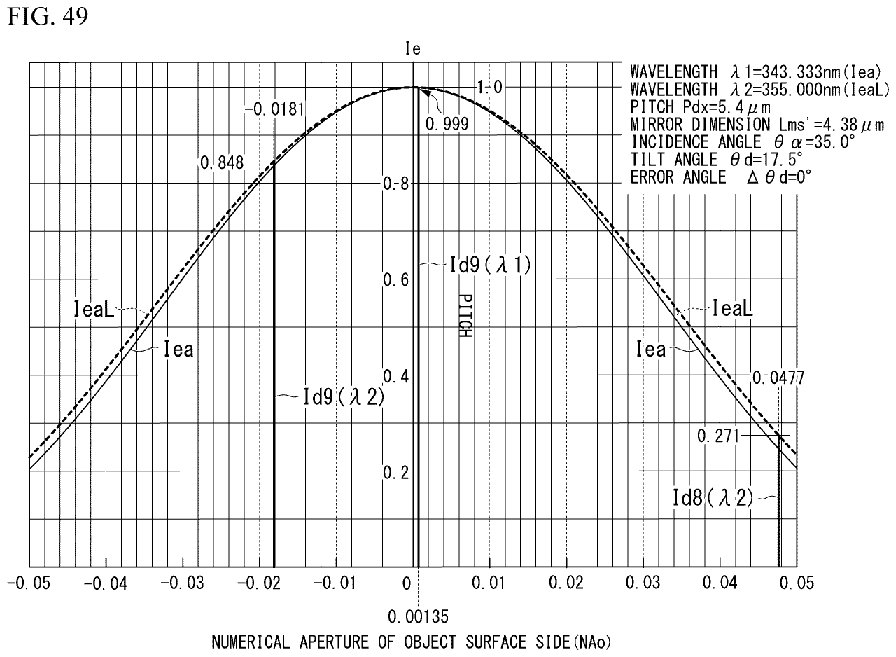

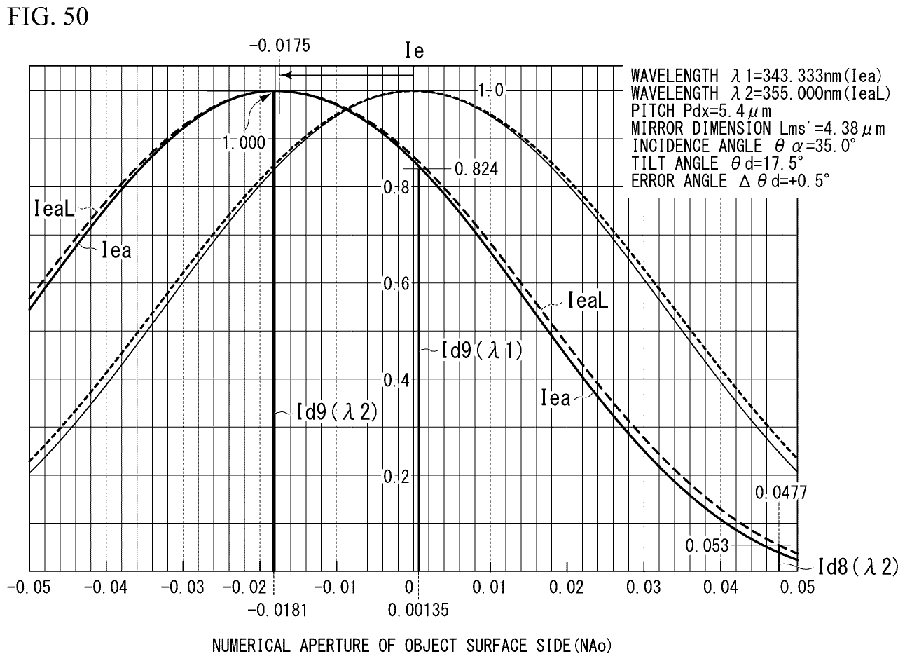

However, by using the illumination light ILm, which contains different wavelength components as described above, it is possible to mitigate the reduction in exposure amount (light intensity) caused by the error angle Δθd of the micro mirror Msa. This will be described with reference to FIG. 49 and FIG. 50. FIG. 49 shows the point image intensity distribution Iea when the wavelength λ1 of the illumination light ILm is 343.333 nm and the point image intensity distribution IeaL when the wavelength λ2 of the illumination light ILm is 355.000 nm, under the same incidence angle θα as in FIG. 48 and the DMD 10 and when the error angle Δθd of the micro mirror Msa in the ON-state is zero. FIG. 50 shows characteristics of the point image intensity distributions Iea and IeaL when the error angle Δθd of the micro mirror Msa in the ON-state is +0.5° in a state shown in FIG. 49.

In each of FIG. 49 and FIG. 50, while a vertical axis and a horizontal axis respectively represent the light intensity Ie and the object-plane-side numerical aperture NAo as in FIG. 48, since the maximum image-plane-side numerical aperture NAi of the projection units PLU is 0.3 and the projection magnification Mp is ⅙, the maximum value of the object-plane-side numerical aperture NAo is +0.05. As shown in FIG. 49, the point image intensity distribution Iea at the wavelength λ1=343.333 nm and the point image intensity distribution IeaL at the wavelength λ2=355.000 nm are defined by Equation (15) above, but there is no significant difference between them.

As in FIG. 48 above, the central ray of the 9^{th} order diffraction light Id9 (λ1) with the wavelength λ1=343.333 nm appears at the object-plane-side numerical aperture NAo=+0.00135, and the light intensity Ie is 0.999 (almost 100%). In addition, the central rays of the 8^{th} order diffraction light Id8 and the 10^{th} order diffraction light Id10 at the wavelength λ1=343.333 nm are located outside the maximum numerical aperture NAo=+0.05 on the object surface side.

Meanwhile, at the wavelength λ2=355.000 nm, the central ray of the 9^{th} order diffraction light Id9 (λ2), which is the 0^{th} order light equivalent component, appears at the object-plane-side numerical aperture NAo=−0.0181 according to Equation (3) above, and the central ray of the 8^{th} order diffraction light Id8 (λ2) appears at the object-plane-side numerical aperture NAo=+0.0477. The 10^{th} order diffraction light Id10 at the wavelength λ2=355.000 nm is located outside the maximum object-plane-side numerical aperture NAo=+0.05. Here, the light intensity Ie of the 9^{th} order diffraction light Id9 (λ2) calculated by Equation (15) is approximately 0.848, and the light intensity Ie of the 8^{th} order diffraction light Id8 (λ2) is approximately 0.271.

Here, assuming that the illuminance of the wavelength λ1=343.333 nm in the illumination light ILm is equal to the illuminance of the wavelength λ2=355.000 nm, the total light intensity (light intensity) of the 9^{th} order diffraction lights Id9 (λ1) and Id9 (λ2), which are the 0^{th} order light equivalent components entering the projection units PLU from the DMD 10, is 0.999+0.848=1.847 (approximately 185%). Next, the case where the error angle Δθd of the micro mirror Msa in the ON-state becomes +0.5° will be described with reference to FIG. 50.

As shown in FIG. 50, the point image intensity distribution Iea at the wavelength λ1 (343.333 nm) and the point image intensity distribution IeaL at the wavelength λ2 (355.000 nm) are both shifted by approximately −0.0175 from the position of the optical axis AXa (origin 0) of the object-plane-side numerical aperture NAo, as in FIG. 48 above. A change in the error angle Δθd individually does not change the diffraction angle of the central ray of each of the 9^{th} order diffraction lights Id9 (λ1) and Id9 (λ2) of the 0^{th} order light equivalent component, i.e., the position on the object-plane-side numerical aperture NAo. For this reason, the light intensity Ie of the 9^{th} order diffraction light Id9 (λ1) at the error angle Δθd=+0.5° is approximately 0.824, following the point image intensity distribution lea after the shift, and the light intensity Ie of the 9^{th} order diffraction light Id9 (λ2) at the error angle Δθd=+0.5° is approximately 1.000, following the point image intensity distribution IeaL after the shift. Accordingly, when the error angle Δθd changes from zero to +0.5°, the total light intensity (light intensity) of the 9^{th} order diffraction lights Id9 (λ1) and Id9 (λ2), which are the 0^{th} order light equivalent components entering the projection units PLU from the DMD 10, changes to 1.000+0.824=1.824 (approximately 182%).

Accordingly, when the error angle Δθd changes to +0.5°, the total light intensity (light intensity) only decreases by −1.2% [=(1.824-1.847)/1.847]. In this way, by including light of a plurality of different wavelength components as the illumination light ILm, it is possible to mitigate the reduction in illuminance (exposure amount) caused by the error angle Δθd of the micro mirror Msa in the ON-state.

However, in FIG. 50, the central ray of the 9^{th} order diffraction light Id9 (λ2) with the wavelength λ2 (355,000 nm) generates a telecentric error Δθt of approximately −0.0181 at the object-plane-side numerical aperture NAo and approximately −0.11 (=−0.0181/Mp) at the image-plane-side numerical aperture NAi. Here, it is advisable to perform telecentric error adjustment so that the central ray of the 9^{th} order diffraction light Id9 (λ1) with the wavelength λ1 (343.333 nm) and the central ray of the 9^{th} order diffraction light Id9 (λ2) with the wavelength λ2 (355.000 nm) are positioned almost symmetrically on either side of the optical axis AXa (origin 0 in FIG. 50) of the projection unit PLU.

Specifically, the incidence angle θα of the illumination light ILm, which contains the light of the wavelength λ1 and the light of the wavelength λ2 on the same axis, is finely adjusted from the initial value) (35.0°. As shown in FIG. 50, the position of the central ray of the 9^{th} order diffraction light Id9 (λ1) of the object-plane-side numerical aperture NAo is approximately 0.00135, and the position of the central ray of the 9^{th} order diffraction light Id9 (λ2) of the object-plane-side numerical aperture NAo is approximately −0.0181, so the average position of the object-plane-side numerical aperture NAo is approximately −0.0168. The object-plane-side numerical aperture NAo =−0.0168 is converted to an angle of approximately −0.96°, and the incidence angle θx of the illumination light ILm may be changed by half that, or approximately −0.48°, from its initial value) (35.0°. In this case, the center positions of the point image intensity distributions Iea and IeaL at NAo=−0.0175 shown in FIG. 50 also shift by approximately 0.0168 in the positive direction.

In FIG. 48 and FIG. 50, although the error angle Δθd of the micro mirror Msa in the ON-state was assumed to have changed in the positive direction, it can also change in the negative direction. For example, when the error angle Δθd is set to −0.5°, the center positions of each of the point image intensity distributions lea and IeaL shown in FIG. 50 will shift to +0.0175 on the object-plane-side numerical aperture NAo. For this reason, the light intensity Ie of both the 9^{th} order diffraction light Id9 (λ1) at the wavelength λ1 (343.333 nm) and the 9^{th} order diffraction light Id9 (λ2) at the wavelength 22 (355.000 nm) decreases. In particular, the light intensity Ie of the 9^{th} order diffraction light Id9 (λ2) is significantly reduced, and the light intensity of the 8^{th} order diffraction light Id8 (λ2) at the wavelength λ2 (355.000 nm) is greater than the light intensity of the 9^{th} order diffraction light Id9 (λ2).

When the error angle Δθd is −0.5°, i.e., when the center of the point image intensity distributions Iea and IeaL shown in FIG. 50 is +0.0175 on the object-plane-side numerical aperture NAo, the light intensity Ie of the 9^{th} order diffraction light Id9 (λ1) at the wavelength λ1 (343.333 nm) is approximately 0.869, the light intensity Ie of the 9^{th} order diffraction light Id9 (λ2) at the wavelength λ2 (355.000 nm) is approximately 0.507, and the light intensity Ie of the 8^{th} order diffraction light Id8 (λ2) at the wavelength λ2 (355.000 nm) is approximately 0.619.

Here, the illumination light ILm is configured to include a third wavelength λ3, which has a shorter wavelength of about 9 to 12 nm than the wavelength λ1=343.333 nm, which has a small telecentric error Δθt. As an example, the wavelength λ3 is changed to 333.6 nm, which is about 9.7 nm shorter than the wavelength λ1. In this case, when the point image intensity distribution at the wavelength λ3 is IeaH, the point image intensity distribution IeaH also shifts to the position of +0.0175 on the object-plane-side numerical aperture NAo even at the error angle Δθd=−0.5°, in the same as the point image intensity distributions lea and IeaL.

The diffraction angle of the 9^{th} order diffraction light Id9 (λ3) of the 0^{th} order light equivalent component from the DMD 10 (the array pitch 5.4 μm of the micro mirror

Ms, the incidence angle θα=) 35.0° when set as the wavelength λ3=333.6 nm is converted into the object-plane-side numerical aperture NAo to become approximately +0.0176, the diffraction angle of the 10^{th} order diffraction light Id10 (λ3) at the wavelength λ3=333.6 nm is converted into the object-plane-side numerical aperture NAo to become approximately −0.0442, the diffraction angle of the 8^{th} order diffraction light Id8 (λ3) at the wavelength λ3=333.6 nm is converted into the object-plane-side numerical aperture NAo to become approximately 0.0794 (0.05 or more of the maximum value), and the 9^{th} order diffraction light Id9(3) and the 10^{th} order diffraction light Id10 (λ3) enter the projection units PLU.

While the central ray of the 9^{th} order diffraction light Id9 (λ3) at the wavelength 23 appears at a position of approximately +0.0176 on the object-plane-side numerical aperture NAo, when the error angle Δθd of the micro mirror Msa in the ON-state becomes −0.5°, since the center of the point image intensity distribution IeaH shifts to a position of +0.0175 on the object-plane-side numerical aperture NAo, the light intensity Ie of the 9^{th} order diffraction light Id9 (λ3) increases to approximately 1.000 (100%).

As described above, by including three wavelength components in the illumination light ILm, namely, the wavelength λ1 which has the smallest telecentric error Δθt in the initial state, the wavelength λ2 which is longer than the wavelength λ1, and the wavelength λ3 which is shorter than the wavelength λ1, it is possible to mitigate the reduction in the exposure amount regardless of whether the error angle Δθd of the 5 micro mirror Msa in the ON-state changes to a positive or negative value. Further, although it depends on the array pitch Pdx of the micro mirror Ms, the tilt angle θo on the design of the micro mirror Msa in the ON-state, and the incidence angle θα of the illumination light ILm, in order to complement the increase and decrease in the exposure amount for each wavelength, it is recommended to set the difference between the wavelengths λ1 and λ2 (λ1<λ2) and the difference between the wavelengths λ1 and λ3 (λ1 >λ3) to a range of approximately 8 nm to 13 nm, or set the wavelengths λ2 and λ3 to within ±4% of the central wavelength λ1 where the telecentric error Δθt is smallest. In addition, it is recommended that the projection units PLU be chromatic aberration corrected in the bandwidth of the wavelengths λ1, λ2 and λ3 used.

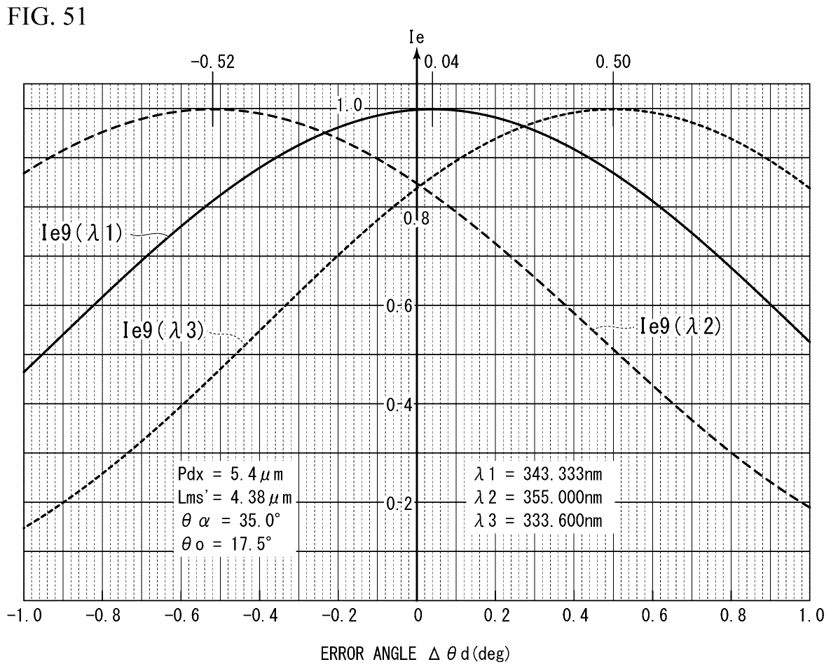

FIG. 51 is a graph obtained by simulating a change in light intensity according to the error angle Δθd of the 9^{th} order diffraction lights Id9 (λ1), Id9 (λ2) and Id9 (λ3) as the 0^{th} order light equivalent component generated below each of the wavelengths if each of the three of the wavelength λ1 (343.333 nm), the wavelength λ2 (355.0 nm), the wavelength λ3 (333.6 nm) is included in the illumination light ILm with the same light intensity.

In FIG. 51, a horizontal axis represents the error angle Δθd, and a vertical axis represents the relative light intensity Ie, where the maximum value of each light intensity of the 9^{th} order diffraction lights Id9 (λ1), Id9 (λ2) and Id9 (λ3) is set to 1.0 (100%). In the simulation, like FIG. 50 above, the array pitch Pdx of the micro mirror Ms is 5.4 μm, the effective dimension Lms' of the micro mirror Msa is 4.38 μm, the incidence angle θα of the illumination light ILm (including the wavelengths λ1, λ2, λ3) is 35.0°, and the initial (design) tilt angle θo of the micro mirror Msa in the ON-state is 17.5°.

The change characteristics of the light intensity Ie of each of the 9^{th} order diffraction lights Id9 (λ1), Id9 (λ2) and Id9 (λ3) follow the sinc² (X) function used to calculate the point image intensity distribution. Then, the condition in which the 9^{th} order diffraction light Id9 (λ1) is maximized is when the error angle Δθd is approximately +0.04° (to be precise,)+0.0389°, the condition in which the 9^{th} order diffraction light Id9 (λ2) is maximized is when the error angle Δθd is approximately −0.52° (to be precise,)−0.518°, and the condition in which the 9^{th} order diffraction light Id9 (λ3) is maximized is when the error angle Δθd is approximately +0.50° (to be precise,)+0.504°.

The error angle Δθd of approximately +0.04° at which the 9^{th} order diffraction light Id9 (λ1) is maximum corresponds to the numerical aperture NAo of approximately 0.00135 on the object surface side of the 9^{th} order diffraction light Id9 (λ1) shown in FIG. 47, FIG. 49 and FIG. 50, and the error angle Δθd of approximately −0.52° at which the 9^{th} order diffraction light Id9 (λ2) is maximum corresponds to the numerical aperture NAo of approximately −0.0181 on the object surface side of the 9^{th} order diffraction light Id9 (λ2) shown in FIG. 47, FIG. 49 and FIG. 50. Similarly, the error angle Δθd of approximately +0.50° at which the 9^{th} order diffraction light Id9 (λ3) is maximum corresponds to the numerical aperture NAo of approximately +0.0176 on the object surface side of the 9^{th} order diffraction light Id9 (λ3).

Further, while not shown in the graph of FIG. 51, the light intensities of the 8^{th} order diffraction light Id8 and the 10^{th} order diffraction light Id10 that appear before and after the 9^{th} order diffraction light Id9, which is the 0^{th} order light equivalent component, also change like a sinc² (X) function in response to changes in the error angle Δθd. For this reason, as the absolute value of the error angle Δθd becomes larger, the light intensity of the 8^{th} order diffraction light Id8 or the 10^{th} order diffraction light Id10 may become larger than the light intensity of the 9^{th} order diffraction light Id9.

### [Variant 7]

The error angle Δθd included in the tilt angle θd of each of the number of micro mirrors Ms of the DMD 10 tends to gradually change to either the positive or negative side over time. The error angle Δθd can be determined by measuring the telecentric error Δθt for each wavelength (λ1, λ2, λ3) of the point image projected by the projection units PLU, for example, when a single micro mirror Ms of the DMD 10 is turned on.

By performing similar measurements on each of the micro mirrors MSa that are individually in the ON-state, the average value of the error angle Δθd can be obtained.

As a result, based on the positive or negative change direction and degree of the measured error angle Δθd and the characteristics data of the point image intensity distributions Iea, IeaL (and IeaH) as shown in FIG. 50 above, the light intensity Ie of the 0^{th} order light equivalent component (the 9^{th} order diffraction light Id9) for each wavelength, as well as the total light intensity (exposure amount) thereof can be estimated. If the estimated total light intensity (exposure amount) is greater than or equal to a predetermined allowable value (for example, 90%), a normal exposure operation continues. If it is less than the allowable value, in order to prevent insufficient exposure amount, the illuminance of the beams from all laser light sources can be uniformly increased or each laser light source may be adjusted so that the illuminance balance of each beam of the wavelengths λ1, λ2, and λ3 changes.

In addition, the illumination light ILm may be broadband illumination light with a broad and continuous spectrum over a wavelength bandwidth of λ1=Δλ(Δλ≤λ1×4%) with the wavelength λ1 as the center wavelength, or may be multi-wavelength illumination light in which four or more isolated narrowband spectra (for example, wavelength width 1 nm or less) are discretely distributed within the wavelength bandwidth.

### [Variant 8]

In addition, when using a narrow-spectrum laser light source, the illumination light ILm may be used, which has only the two components, the wavelength λ2 (355.0 nm) and the wavelength λ3 (333.6 nm), as described in the embodiment or variant above. As described above, when the array pitch of the micro mirrors Ms is 5.4 μm and the incidence angle θα of the illumination light ILm is 35.0°, the central ray of the 9^{th} order diffraction light Id9 (λ2) generated under the illumination light with the wavelength λ2 (355.0 nm) appears as a telecentric error at the position of approximately −0.0181 on the object-plane-side numerical aperture NAo, and the light intensity Ie when the error angle Δθd is zero is approximately 0.848 (see FIG. 49).

Meanwhile, when the array pitch of the micro mirror Ms is 5.4 μm and the incidence angle θα of the illumination light ILm is 35.0°, the central ray of the 9^{th} order diffraction light Id9 (λ3) generated under the illumination light with the wavelength λ3 (333.6 nm) appears as a telecentric error at a position of approximately +0.0176 on the object-plane-side numerical aperture NAo according to Equation (3) above, and the light intensity Ie when the error angle Δθd is zero is approximately 0.837. Accordingly, when the error angle Δθd of the micro mirror Msa in the ON-state is zero, the sum of the light intensity of the 9^{th} order diffraction light Id9 (λ2) with the wavelength λ2 (355.0 nm) and the light intensity of the 9^{th} order diffraction light Id9 (λ3) with the wavelength λ3 (333.6 nm) is 1.685.

From that state, when the error angle Δθd changes to +0.5°, the light intensity Ie of the 9^{th} order diffraction light Id9 (λ2) with the wavelength λ2 (355.0 nm) increases from 0.848, as shown in FIG. 50 above. Meanwhile, the light intensity Ie of the 9^{th} order diffraction light Id9 (λ3) with the wavelength λ3 (333.6 nm) decreases from 0.837. Conversely, when the error angle Δθd changes to −0.5°, the light intensity Ie of the 9^{th} order diffraction light Id9 (λ2) with the wavelength λ2 (355.0 nm) decreases from 0.848, and the light intensity Ie of the 9^{th} order diffraction light Id9 (λ3) with the wavelength λ3 (333.6 nm) increases from 0.837.

In this way, by setting the wavelength difference so that the 9^{th} order diffraction lights Id9 (λ2) and Id9 (λ3) generated at the two wavelengths λ2 and λ3 have approximately equal telecentric errors in opposite directions, it is possible to change the light intensity of the 9^{th} order diffraction light Id9 (λ2) and the light intensity of the 9^{th} order diffraction light Id9 (λ3) complementarily in response to changes in the error angle Δθd of the micro mirror Msa.

Further, when the tilt angle θd of the micro mirror Msa in the ON-state of the DMD 10 is in the initial state (a state of the error angle Δθd=θ) that is equal to the designed tilt angle θ0, the wavelength λ1 (for example, 343.333 nm) of one of the illumination lights ILm is set so that the telecentric error Δθt of the high order diffraction light Idj (for example, j=9^{th}), which is the 0^{th} order light equivalent component, is minimized. In addition, the light with the wavelength λ2 (λ2>λ1) (for example, 22=355 nm) and the light with the wavelength λ3 (λ3<λ1) (for example, 23=333.6 nm) are included in the illumination light ILm at appropriate intensities.

Then, when the error angle Δθd of the DMD 10 shows a tendency to become larger than a predetermined allowable range (for example, +0.3°) and the error angle Δθd tends to increase in the positive direction, the intensity of the light with the wavelength 22 (λ2>λ1) contained in the illumination light ILm is set be increased and the intensity of the light with the wavelength λ3 (λ3<λ1) is set to be decreased. Conversely, when the error angle Δθd shows a tendency to become larger than the allowable range (for example,) ±0.3° and the error angle Δθd tends to increase in the negative direction, the intensity of the light with the wavelength λ3 contained in the illumination light ILm may be set to be increased and the intensity of the light with the wavelength λ2 may be set to be decreased.

### [Variant 9]

As described above in FIGS. 40, 42, and 43, when using the illumination unit ILU in which the incidence angle of each of the two illumination lights ILm1 and ILm2 with different wavelengths to the DMD 10 can be adjusted individually, the incidence angle of only the illumination light ILm2 with the wavelength λ2 that irradiates the DMD 10 is adjusted so that the telecentric error of the 9^{th} order diffraction light Id9 (λ2) with the wavelength λ2 (355.00 nm) shown in FIG. 50 is corrected. Accordingly, as the 9^{th} order diffraction light Id9 (λ2) shifts in the positive direction on the object-plane-side numerical aperture NAo, only the point image intensity distribution IeaL generated at the error angle Δθd (for example,)+0.5° of the micro mirror Msa in the ON-state shifts in the positive direction by the same amount on the object-plane-side numerical aperture NAo. Accordingly, by configuring as shown in FIG. 40, FIG. 42 and FIG. 43 above, not only the telecentric error Δθt caused by the difference in wavelength of the illumination light ILm can be corrected, but also a synergistic effect can be obtained in which the reduction in the light intensity Ie (exposure amount) caused by the error angle Δθd of the micro mirror Msa in the ON-state can be mitigated.

Hereinabove, according to the embodiment or each variant, by making the illumination light ILm multi-wavelength and making the wavelength distribution broadband, the light intensity of the high order diffraction light (for example, the 9^{th} order diffraction light Id9), which is the 0^{th} order light equivalent component generated from the number of micro mirrors Msa in the on-state of the DMD 10, is mitigated from being significantly reduced due to the error angle (tilt error) Δθd of the micro mirror Ms, and a good exposure amount can be secured. Accordingly, even if the error angle (tilt error) Δθd gradually increases from the initial value as the exposure device is operated for a certain period of time, accurate pattern exposure can be continued with a stable exposure amount.

1-38. (canceled)

39. An exposure device comprising:
a spatial light modulation element including micromirrors;
an illumination unit that irradiates the spatial light modulation element with first light with a peak wavelength λ1 and second light with a peak wavelength λ2 (λ2≈λ1), so that the first light is diffracted by ON-state micromirrors of the spatial light modulation element as first diffraction light and the second light is diffracted by the ON-state micromirror as second diffraction light; and
a projection unit,
wherein the first diffraction light and the second diffraction light enter the projection unit, so that the first diffraction light and the second diffraction light are distributed with an optical axis of the projection unit interposed therebetween.

40. The exposure device according to claim 39, further comprising an adjustment mechanism that adjusts an incidence angle of at least one of the first light and the second light so that the first diffraction light and the second diffraction light are distributed symmetrically with respect to the optical axis.

41. The exposure device according to claim 40, wherein an arrangement pitch Pd of the micromirrors, the incidence angle θα, a diffraction angle θj1 of the first diffraction light of the j1-th order and a diffraction angle θj2 of the second diffraction light of the j2-th order are set so as to meet relationships of:
$$sin θ j 1 = sin θα - j 1 ( λ1 / Pd ) , \\ and \\ sin θ j 2 = sin θα - j 2 ( λ2 / Pd ) .$$

42. The exposure device according to claim 40, wherein the illumination unit comprises:
an optical integrator to which the first light and the second light enter and which forms a surface light source at an emission surface side of the optical integrator; and
a condenser lens system whose optical axis is tilted by the incidence angle θα with respect to the optical axis of the projection unit and which performs Koehler illumination to the spatial light modulation element with the surface light source.

43. The exposure device according to claim 42, wherein the illumination unit further comprises:
a single or a plurality of optical fiber bundles to which both the first light and the second light enter, and
an input lens system which performs Koehler illumination or critical illumination with respect to an incidence surface of the optical integrator with the first light and the second light projected from an emission end of the optical fiber bundle,
wherein the adjustment mechanism includes any one of a mechanism that adjusts a relative position of the emission end of the optical fiber bundle and the input lens system within a plane perpendicular to an optical axis of the input lens system, a mechanism that adjusts an inclination of the first light and the second light projected to the incidence surface of the optical integrator, and a mechanism that adjusts a relative position of the surface light source, which is formed on the emission surface of the optical integrator, and the condenser lens system within a plane perpendicular to an optical axis of the condenser lens system.

44. The exposure device according to claim 39, wherein the micromirrors are two dimensionally arranged and selectively driven based on drawing data.

45. The exposure device according to claim 42, wherein the illumination unit comprises:
a dichroic optical member with wavelength selection characteristics in which one of the first light and the second light is transmitted and the other of the first light and the second light is reflected, by using a difference between the peak wavelength λ1 and the peak wavelength λ2; and
an input lens system which performs Koehler illumination or critical illumination with respect to the incidence surface of the optical integrator with the first light and the second light combined via the dichroic optical member.

46. The exposure device according to claim 45, wherein the illumination unit further comprises a first optical fiber bundle that emits the entered first light toward the dichroic optical member, and a second optical fiber bundle that emits the entered second light toward the dichroic optical member, and
the adjustment mechanism includes a mechanism that individually displaces each of the first light from an emission end of the first optical fiber bundle and the second light from an emission end of the second optical fiber bundle within the plane with respect to the optical axis.

47. The exposure device according to claim 42, wherein the adjustment mechanism adjusts so that a first surface light source formed in a circular shape at an emission surface side of the optical integrator by the first light, and a second surface light source formed in a circular shape at the emission surface side of the optical integrator by the second light, are positioned to shift by a predetermined interval in directions corresponding to advancing directions of the first diffraction light and the second diffraction light.

48. The exposure device according to claim 47, wherein the adjustment mechanism sets an amount of the shift so that a shape obtained by combining the first surface light source and the second surface light source which are shifted and formed on the emission surface side of the optical integrator has an oval shape in which a ratio between lengths in a long axis direction and a short axis direction corresponds to a cosine value of the incidence angle θα.

49. An exposure device comprising:
a spatial light modulation element including micromirrors;
an illumination unit that irradiates the spatial light modulation element with first light with a peak wavelength λ1 and second light with a peak wavelength λ2 (λ2≈λ1), so that the first light is diffracted by ON-state micromirrors of the spatial light modulation element as first diffraction light and the second light is diffracted by the ON-state micromirror as second diffraction light; and
a projection unit,
wherein the first diffraction light and the second diffraction light enter the projection unit,
wherein a difference between a first diffraction angle between an advancing direction of the first diffraction light and an optical axis of the projection unit and a second diffraction angle between an advancing direction of the second and the optical axis is within a predetermined allowable range.

50. The exposure device according to claim 49, wherein the peak wavelength λ1 and the peak wavelength λ2 are selected so that a tilt angle of the micromirror is set between the first diffraction angle θj1 and the second diffraction angle θj2.

51. The exposure device according to claim 49, wherein an allowable range of a difference angle between the first diffraction angle θj1 and the second diffraction angle θj2 is set to ⅕ or less of an angle corresponding to an maximum numerical aperture NAo (max) of the projection unit at a side of the spatial light modulation element.

52. The exposure device according to claim 51, wherein the allowable range is set to ⅛ or less of the angle corresponding to the maximum numerical aperture NAo (max).

53. The exposure device according to claim 49, wherein an arrangement pitch Pd of the micromirrors and an incidence angle θα of at least one of the first light and the second light, the first diffraction angle θj1 of the first diffraction light of the j1-th order and the second diffraction angle θj2 of the second diffraction light of the j2-th order are set so as to meet relationships of:
$$sin θ j 1 = sin θα - j 1 ( λ1 / Pd ) , \\ and \\ sin θ j 2 = sin θα - j 2 ( λ2 / Pd ) .$$

54. The exposure device according to claim 53, wherein a difference between the peak wavelength λ1 and the peak wavelength λ2 is set so that the order j1 and the order j2 are same as each other.

55. The exposure device according to claim 53, wherein a difference between the peak wavelength λ1 and the peak wavelength λ2 is set so that the order j1 and the order j2 are different from each other.

56. The exposure device according to claim 53, wherein the illumination unit comprises:
an optical integrator to which the first light and the second light enters and which forms a surface light source at an emission surface side of the optical integrator, and
a condenser lens system whose an optical axis is tilted by the incidence angle θα with respect to the optical axis of the projection units and which performs Koehler illumination to the spatial light modulation element with the surface light source.

57. The exposure device according to claim 56, wherein the illumination unit further comprises:
a single or a plurality of optical fiber bundles to which both the first light and the second light enter, and
an input lens system which performs Koehler illumination or critical illumination with respect to an incidence surface of the optical integrator with the first light and the second light projected from an emission end of the optical fiber bundle, or
wherein the illumination unit comprises:
a dichroic optical member with wavelength selection characteristics in which one of the first light and the second light is transmitted and the other of the first light and the second light is reflected, by using a difference between the peak wavelength λ1 and the peak wavelength λ2; and
an input lens system which performs Koehler illumination or critical illumination with respect to the incidence surface of the optical integrator with the first light and the second light combined via the dichroic optical member.

58. The exposure device according to claim 49, wherein the micromirrors are two dimensionally arranged and selectively driven based on drawing data.

59. An exposure device comprising:
a spatial light modulation element including micromirrors;
an illumination unit that irradiates the spatial light modulation element with first light with a peak wavelength λ1 and second light with a peak wavelength λ2 (λ2≈λ1), so that the first light is diffracted by ON-state micromirrors of the spatial light modulation element as first diffraction light and the second light is diffracted by the ON-state micromirror as second diffraction light; and
a projection unit,
wherein the first diffraction light and the second diffraction light enter the projection unit,
wherein a first diffraction angle between an advancing direction of the first diffraction light and an optical axis of the projection unit and a second diffraction angle between an advancing direction of the second diffraction light and the optical axis are distributed on one side with respect to the optical axis.

60. The exposure device according to claim 59, wherein an arrangement pitch Pd of the micromirrors, a first diffraction angle θj1 of the first diffraction light of the j1-th order and an second diffraction angle θj2 of the second diffraction light of the j2-th order are set so as to meet relationships of:
$$sin θ j 1 = sin θα - j 1 ( λ1 / Pd ) , \\ and \\ sin θ j 2 = sin θα - j 2 ( λ2 / Pd ) ,$$
wherein a designed incidence angle θα of at least one of the first light and the second light is θα>0° and the order j1 and the order j2 are each greater than 0, and the peak wavelengths λ1 and λ2 are set to satisfy any one of.
a first condition of λ1<Pd·sinθα/j1 and λ2<Pd·sinθα/j2, and
a second condition of λ1 >Pd·sinθα/j1 and λ2>Pd·sinθα/j2.

61. The exposure device according to claim 59, wherein the micromirrors are two dimensionally arranged and selectively driven based on drawing data.

62. The exposure device according to claim 61, wherein a difference between the peak wavelength λ1 and the peak wavelength λ2 is set so that either the first condition or the second condition is satisfied, and the order j1 and the order j2 are same as each other.

63. The exposure device according to claim 61, wherein a difference between the peak wavelength λ1 and the peak wavelength λ2 is set so that either the first condition or the second condition is satisfied and the order j1 and the order j2 are different from each other.

64. The exposure device according to claim 63, wherein the difference is set such that the order j1 and the order j2 satisfies a relationship of j1=j2−1, or j1=j2+1.

65. The exposure device according to claim 60, wherein the illumination unit further comprises:
an adjustment mechanism that changes an incidence angle of at least one of the first light and the second light from the designed incidence angle θα so that the first diffraction angle θj1 and the second diffraction angle θj2 are symmetrically distributed with respect to the optical axis.

66. The exposure device according to claim 60, wherein a difference between the peak wavelength λ1 and the peak wavelength λ2 is set so that a difference angle Δθj (1-2) between the first diffraction angle θj1 and the second diffraction angle θj2 is ⅕ or less of an angle corresponding to a maximum numerical aperture NAo (max) of the projection unit at a side of the spatial light modulation element.

67. The exposure device according to claim 66, wherein the difference is set so that the difference angle Δθj (1-2) is ⅛ or less of the angle corresponding to the maximum numerical aperture NAo (max).

68. A device manufacturing method comprising:
forming a photosensitive layer on a substrate on which an electronic device is to be formed;
preparing drawing data corresponding to a pattern for the electronic device;
putting the substrate on which the photosensitive layer is formed on a moving stage of the exposure device according to claim 39 and setting the drawing data to a driving controller of the spatial light modulation element of the exposure device; and
exposing the pattern to the photosensitive layer while synchronizing movement of the substrate by the moving stage and driving of the micromirrors between an ON-state and an OFF-state of the spatial light modulation element based on the drawing data.

69. An exposure device comprising:
a spatial light modulation element including micromirrors;
an illumination unit that irradiates the spatial light modulation element with light with a wavelength width±Δλ with respect to a center wavelength λo, so that first light with a peak wavelength λ1 that is λo+λ2 is diffracted by ON-state micromirrors of the spatial light modulation element as first diffraction light and second light with a peak wavelength λ2 that is λo-Δ2 is diffracted by the ON-state micromirror as second diffraction light; and
a projection unit,
wherein the first diffraction light and the second diffraction light enter the projection unit,
wherein a distribution shape where the first diffraction light and the second diffraction light are combined in a pupil of the projection unit is an isotropic shape.

70. The exposure device according to claim 69, wherein the illumination unit includes a condenser lens system to which a first beam of a peak wavelength λ1 emitted from a first light source device and a second beam of a peak wavelength λ2 emitted from a second light source device enter, and which obliquely illuminate the spatial light modulation element at an incidence angle θα with illumination light obtained by coaxially combining the first beam and the second beam,
wherein the ON-state micromirror is set so as to tilt at a designed tilt angle θ0 with respect to a neutral plane perpendicular to an optical axis of the projection unit, and the incidence angle θα is set to twice of the designed tilt angle θ0.

71. The exposure device according to claim 69, wherein the micromirrors are two dimensionally arranged and selectively driven based on drawing data.

72. The exposure device according to claim 70, wherein a first distribution shape of the first diffraction light in the pupil, the first diffraction light generated from the spatial light modulation element by an irradiation of the first beam, is an oval shape shrunk in a direction in which the micromirror is tilted,
a second distribution shape of the second diffraction light, the second diffraction light generated from the spatial light modulation element by an irradiation of the second beam, is an oval shape shrunk in a direction in which the micromirror is tilted, and
the first distribution shape and the second distribution shape are formed so as to be shifted in a direction in which the micromirror is tilted by a difference between the diffraction angle θj1 and the diffraction angle θj2 in the pupil.

73. The exposure device according to claim 69, wherein the illumination unit includes a condenser lens system to which a first beam of a peak wavelength λ1 emitted from a first light source device and a second beam of a peak wavelength λ2 emitted from a second light source device enters, and which obliquely illuminate the spatial light modulation element at an incidence angle with illumination light obtained by decentering and combining the first beam and the second beam.

74. The exposure device according to claim 73, wherein the illumination unit includes an optical member that sets an incidence angle of the first beam against the spatial light modulation element to a first incidence angle θα1 and to set an incidence angle of the second beam against the spatial light modulation element to a second incidence angle θα2, and
a difference between the incidence angle θα1 and the incidence angle θα2 is set to correspond to a difference between the peak wavelength λ1 and the peak wavelength λ2.

75. The exposure device according to claim 69, wherein illumination light-irradiated from the illumination unit against the spatial light modulation element is made as multispectral light in which multiple single narrow-wavelength spectra are discretely arranged over the wavelength width±λ2.

76. The exposure device according to claim 69, wherein the illumination light irradiated from the illumination unit against the spatial light modulation element is made as broadband illumination light in which spectrum is continuous broadly over the wavelength width±λ2.
